(19) United States
(12) Patent Application Publication
(10) Pub. No.: US 2026/0276844 A1
(43) Pub. Date: Sep. 17, 2026

(54) METHOD FOR CRYSTAL PROCESSING

(71) Applicant: BOYA ADVANCED MATERIALS CO., LTD., Meishan (CN)

(72) Inventors: Yu WANG, Meishan (CN); Weiming GUAN, Meishan (CN); Songlin HUANG, Meishan (CN)

(73) Assignee: BOYA ADVANCED MATERIALS CO., LTD., Meishan (CN)

(21) Appl. No.: 19/676,785

(22) Filed: May 13, 2026

Related U.S. Application Data
(63) Continuation of application No. PCT/CN2024/132407, filed on Nov. 15, 2024.

(30) Foreign Application Priority Data
Nov. 15, 2023 (CN) 202311526788.5
Aug. 26, 2024 (CN) 202411173676.0
Oct. 16, 2024 (CN) 202411448038.5
Oct. 16, 2024 (CN) 202422507317.6

(51) Int. Cl. G01T 1/202; B24B 1/00

(52) U.S. Cl. CPC G01T 1/202; B24B 1/00

(57) ABSTRACT

Embodiments of the present disclosure provide a method for crystal processing. The method for crystal processing includes: obtaining an initial crystal; determining a processing scheme for the initial crystal; and processing the initial crystal based on the processing scheme.

### CROSS-REFERENCE TO RELATED APPLICATIONS

This application is a Continuation of International Patent Application No. PCT/CN2024/132407, filed on Nov. 15, 2024, which claims: priority to Chinese Application No. 202311526788.5 filed on Nov. 15, 2023; priority to Chinese application No. 202411173676.0, filed on Aug. 26, 2024; priority to Chinese application No. 202411448038.5, filed on Oct. 16, 2024; and priority to Chinese application No. 202422507317.6, filed on Oct. 16, 2024, the entire contents of each of which are incorporated herein by reference.

### TECHNICAL FIELD

The present disclosure relates to crystal processing, and in particular, relates to a method for crystal processing and an apparatus for crystal inspection.

### BACKGROUND

A scintillator crystal refers to a crystal material that emits scintillation light such as visible light, ultraviolet light, or the like under the action of radiation or nuclear particles. The scintillator crystal is widely used in nuclear medicine, such as X-ray computed tomography (XCT) and positron emission tomography (PET), and nuclear detection technologies, such as industrial computed tomography (industrial CT), oil well exploration, nuclear physics, high-energy physics, environmental inspection, safety inspection, fire control of weapons, guidance, or the like. Initial crystals may be obtained through natural growth or artificial growth. However, dimensions of obtained initial crystals are inconsistent, and may have defects. Therefore, the obtained initial crystals cannot be directly applied to specific equipment.

Therefore, it is necessary to provide a method for crystal processing, which can more accurately and efficiently further process the initial crystals, to ensure that processed crystals satisfy requirements of different applications.

### SUMMARY

One or more embodiments of the present disclosure provide a method for crystal processing. The method comprises obtaining one or more initial crystals, determining a processing scheme for the one or more initial crystals, and processing the one or more initial crystals based on the processing scheme.

One or more embodiments of the present disclosure provide an apparatus for crystal inspection. The apparatus comprises a first movement assembly, including a moving member and a first picking member, wherein the first picking member is disposed on the moving member, the first picking member is configured to pick up one or more initial crystals, and the moving member is configured to adjust a position and/or an angle of the first picking member; a first detection assembly, including a first image acquisition device and a dimension measuring stage, wherein the dimension measuring stage carries the one or more initial crystals, the first image acquisition device photographs the one or more initial crystals on the dimension measuring stage to obtain at least one first image of the one or more initial crystals, and the at least one first image is used to determine dimension data of the one or more initial crystals; and a second detection assembly, including at least one second image acquisition device and at least one defect measuring stage, wherein the at least one defect measuring stage is configured to carry the one or more initial crystals, the at least one second image acquisition device is configured to photograph the one or more initial crystals on the at least one defect measuring stage to obtain at least one second image of the one or more initial crystals, and the at least one second image is used to determine defect data of the one or more initial crystals.

One or more embodiments of the present disclosure provide a system for optical output regulation of a crystal. The system comprises a controller and machining equipment. The controller is configured to obtain an initial optical output value of one or more initial crystals; and determine a target optical output value of the one or more initial crystals; the machining equipment is configured to: determine an optical adjustment scheme for the one or more initial crystals based on the initial optical output value and the target optical output value; and perform surface roughness modification on at least one outer surface of the one or more initial crystals based on the optical adjustment scheme, such that an actual optical output value of the one or more initial crystals changes from the initial optical output value to the target optical output value, wherein surface roughness Ra of the at least one outer surface after the surface roughness modification is within a range of 0.001 μm-10 μm.

One or more embodiments of the present disclosure provide a method for crystal assembly. The method comprises arranging a plurality of target crystals in an array to form a crystal array; wherein processing the plurality of target crystals includes: obtaining a plurality of initial crystals; determining an initial optical output value of each initial crystal in the plurality of initial crystals; determining a target optical output value corresponding to each initial crystal based on the initial optical output value of each initial crystal; determining an optical adjustment scheme for each initial crystal based on the initial optical output value and the target optical output value; and performing surface roughness modification on at least one outer surface of one or more initial crystals of the plurality of initial crystals based on the optical adjustment scheme, such that an actual optical output value of each initial crystal reaches the target optical output value corresponding to the initial crystal, thereby forming the plurality of target crystals.

One or more embodiments of the present disclosure provide a crystal array. The crystal array is assembled by the method for crystal assembly described in the foregoing embodiments.

### BRIEF DESCRIPTION OF THE DRAWINGS

The present disclosure will be further described by way of exemplary embodiments, and the exemplary embodiments will be described in detail with reference to the drawings. These embodiments are not limiting. In these embodiments, the same reference numerals denote the same structures, wherein:

FIG. 1 is a flowchart illustrating an exemplary process for crystal processing according to some embodiments of the present disclosure;

FIG. 2 is a flowchart illustrating an exemplary process for crystal assembly according to some embodiments of the present disclosure;

FIG. 3 is a schematic diagram illustrating crystal assembly according to some embodiments of the present disclosure;

FIG. 4 is a schematic diagram illustrating crystal assembly according to some embodiments of the present disclosure;

FIG. 5 is a schematic diagram illustrating an exemplary process for determining a crystal arrangement position according to some embodiments of the present disclosure;

FIG. 6 is a flowchart illustrating an exemplary process for optical output regulation of a crystal according to some embodiments of the present disclosure;

FIG. 7 is a schematic diagram illustrating an initial crystal according to some embodiments of the present disclosure;

FIG. 8 is a flowchart illustrating another exemplary process for crystal assembly according to some embodiments of the present disclosure;

FIG. 9 is a schematic diagram illustrating a process for obtaining a plurality of target crystals used for assembling a crystal array according to some embodiments of the present disclosure;

FIG. 10 is another schematic diagram illustrating crystal assembly according to some embodiments of the present disclosure;

FIG. 11 is a flowchart illustrating another exemplary process for crystal processing according to some embodiments of the present disclosure;

FIG. 12 is a flowchart illustrating an exemplary process for determining a cutting scheme for one or more initial crystals according to some embodiments of the present disclosure;

FIG. 13 is a flowchart illustrating another exemplary process for determining a cutting scheme for one or more initial crystals according to some embodiments of the present disclosure;

FIG. 14 is a flowchart illustrating an exemplary process for determining a first adjustment scheme for one or more initial crystals according to some embodiments of the present disclosure;

FIG. 15 is a flowchart illustrating an exemplary process for determining a second adjustment scheme for one or more initial crystals according to some embodiments of the present disclosure;

FIG. 16 is a flowchart illustrating an exemplary process for determining an image to be recognized according to some embodiments of the present disclosure;

FIG. 17 is a block diagram illustrating an exemplary apparatus for crystal inspection according to some embodiments of the present disclosure;

FIG. 18 is a schematic diagram illustrating a movement assembly according to some embodiments of the present disclosure;

FIG. 19 is a schematic diagram illustrating a first detection assembly according to some embodiments of the present disclosure;

FIG. 20 is a schematic diagram illustrating another first detection assembly according to some embodiments of the present disclosure;

FIG. 21 is a schematic diagram illustrating a second detection assembly according to some embodiments of the present disclosure;

FIG. 22A is a schematic diagram illustrating a first defect measuring stage according to some embodiments of the present disclosure;

FIG. 22B is a schematic diagram illustrating another first defect measuring stage according to some embodiments of the present disclosure; and

FIG. 23 is a schematic diagram illustrating a portion of a second detection assembly according to some embodiments of the present disclosure.

### DETAILED DESCRIPTION

To more clearly illustrate the technical solutions of the embodiments of the present disclosure, the drawings used in the description of the embodiments are briefly introduced below. Obviously, the drawings in the following description are merely some examples or embodiments of the present disclosure. For a person of ordinary skill in the art, the present disclosure may be applied to other similar scenarios based on these drawings without creative effort. Unless obviously obtained from the context or the context illustrates otherwise, the same numeral in the drawings refers to the same structure or operation.

It should be understood that the terms “system,” “device,” “unit,” and/or “module” used herein are a method for distinguishing different components, elements, parts, sections, or assemblies at different levels. However, if other words can achieve the same purpose, the words may be replaced by other expressions.

As shown in the present disclosure and the claims, unless the context clearly indicates an exception, the words “a,” “an,” “one,” and/or “the” are not limited to the singular and may also include the plural. Generally, the terms “include” and “comprise” only indicate that clearly identified operations and elements are included. The operations and elements do not constitute an exclusive list. A method or device may also include other operations or elements.

Flowcharts are used in the present disclosure to illustrate operations performed by a system according to embodiments of the present disclosure. It should be understood that preceding or following operations are not necessarily performed precisely in sequence. Conversely, each operation may be processed in reverse order or simultaneously. Meanwhile, other operations may be added to the processes, or one or more operations may be removed from the processes.

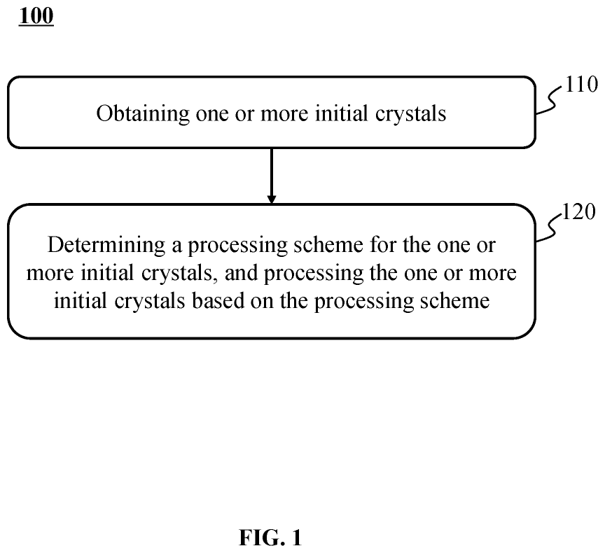

FIG. 1 is a flowchart illustrating an exemplary process for crystal processing according to some embodiments of the present disclosure. As shown in FIG. 1, a process 100 includes the following operations.

In 110, one or more initial crystals are obtained.

The one or more initial crystals (hereinafter referred to as initial crystal(s)) refer to crystals that need to be processed. Types of the initial crystals may include, but are not limited to, silicon carbide, single-crystal germanium, or the like.

The process for crystal processing includes, but is not limited to, at least one of assembling the one or more initial crystals, performing optical output regulation on the one or more initial crystals, cutting the one or more initial crystals, replacing the one or more initial crystals, or adjusting the one or more initial crystals. For example, the one or more initial crystals may be crystals in a natural state or an artificially grown state that have not undergone machining or forming treatment. The one or more initial crystals may be used for determining dimension data and defect data thereof, thereby determining a cutting scheme for the initial crystals. More descriptions regarding processing of the one or more initial crystals may be found in the related descriptions below.

The one or more initial crystals may be obtained in various ways. For example, the one or more initial crystals may be obtained through preset acquisition. As another example, the one or more initial crystals may be obtained by selecting from a plurality of crystal raw materials.

In 120, a processing scheme for the one or more initial crystals is determined, and the one or more initial crystals are processed based on the processing scheme.

The processing scheme refers to a scheme for processing the one or more initial crystals. A specific type of the processing scheme may be determined based on a type of processing to be performed on the one or more initial crystals.

For example, when it is necessary to assemble the one or more initial crystals, the processing scheme may include an assembly scheme for assembling a plurality of initial crystals into a crystal array. As another example, when it is necessary to adjust an optical output of the one or more initial crystals, the processing scheme may include an optical adjustment scheme. For a further example, the one or more initial crystals may be crystal units on a material tray, and the processing scheme may include a first adjustment scheme for adjusting the one or more initial crystals placed on the material tray. As yet another example, the one or more initial crystals may be the crystal array formed by a plurality of crystal units, and the processing scheme may include a second adjustment scheme for adjusting the crystal array.

In some embodiments, the processing scheme for the one or more initial crystals may be determined in various ways.

In some embodiments, the assembly scheme for assembling the one or more initial crystals into the crystal array may be determined. More descriptions regarding the foregoing embodiments may be found in the related descriptions below.

In some embodiments, relevant information of the one or more initial crystals may be determined; and the processing scheme may be determined based on the relevant information of the one or more initial crystals. For example, the relevant information of the one or more initial crystals includes an initial optical output value and a target optical output value of the one or more initial crystals, and surface roughness modification may be performed on at least one outer surface of the one or more initial crystals based on the initial optical output value and the target optical output value, such that an actual optical output value of the one or more initial crystals changes from the initial optical output value to the target optical output value. Surface roughness Ra of the at least one outer surface after the surface roughness modification is within a range of 0.001 μm-10 μm. As another example, the relevant information of the one or more initial crystals includes a recognition result of the one or more initial crystals, and the recognition result includes at least one of dimension data, position data, or defect data of the one or more initial crystals. An image to be recognized related to the one or more initial crystals may be obtained; image recognition may be performed on the image to be recognized to determine the recognition result of the one or more initial crystals; and the processing scheme for the one or more initial crystals may be determined based on the recognition result. The relevant information of the one or more initial crystals may be obtained by detecting the one or more initial crystals by an operator, and also may be obtained by detecting the one or more initial crystals by related equipment (e.g., an apparatus for crystal inspection). More descriptions regarding the foregoing examples may be found in the related descriptions below.

In some embodiments, the one or more initial crystals may be processed based on the processing scheme. For example, when the processing scheme includes the assembly scheme for assembling the plurality of initial crystals into the crystal array, correspondingly, after the assembly scheme is determined, the plurality of initial crystals are preprocessed based on the assembly scheme to obtain a plurality of target crystals; and the plurality of target crystals are assembled into the crystal array, where a reflective structure is provided between at least two adjacent target crystals of the crystal array. In some embodiments, when the processing scheme includes the cutting scheme for cutting the one or more initial crystals, correspondingly, after the foregoing assembly scheme is determined, the one or more initial crystals may be cut based on the cutting scheme. In some embodiments, when the processing scheme includes the optical adjustment scheme, the surface roughness modification may be performed on at least one outer surface of the one or more initial crystals based on the optical adjustment scheme, such that the actual optical output value of the one or more initial crystals changes from the initial optical output value to the target optical output value, wherein the surface roughness Ra of the at least one outer surface after the surface roughness modification is within a range of 0.001 μm-10 μm. In some embodiments, when the processing scheme includes the first adjustment scheme for adjusting the one or more initial crystals placed on the material tray, the one or more initial crystals placed on the material tray may be adjusted based on the first adjustment scheme. In some embodiments, when the processing scheme includes the second adjustment scheme for adjusting at least one of the crystal units or the reflective structure in the one or more initial crystals, at least one of the crystal units or the reflective structure in the one or more initial crystals may be adjusted based on the second adjustment scheme. More descriptions regarding the foregoing embodiments may be found in the related descriptions below.

Some embodiments of the present disclosure determine the processing scheme for the one or more initial crystals, and the one or more initial crystals are processed based on the processing scheme, such that processing of the one or more initial crystals is more accurate and efficient, and processed initial crystals satisfy requirements of different applications.

Related descriptions regarding assembling the one or more initial crystals will be described below. Correspondingly, the method for crystal processing may include a method for crystal assembly.

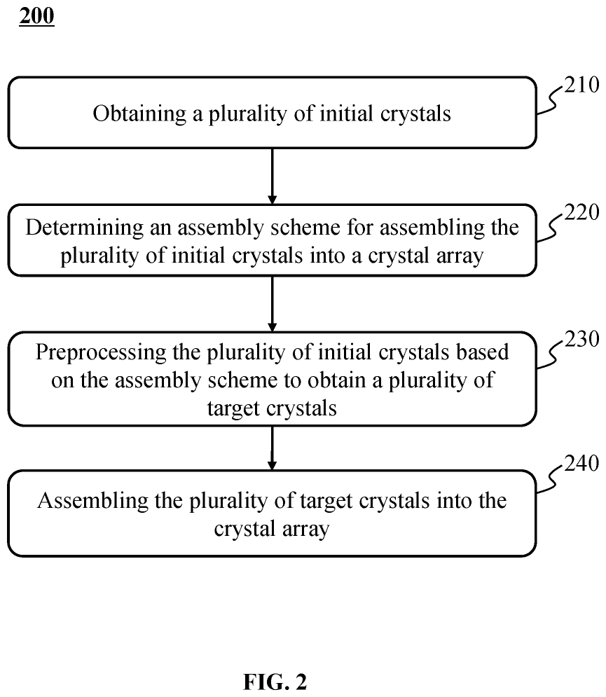

FIG. 2 is a flowchart illustrating an exemplary process for crystal assembly according to some embodiments of the present disclosure.

In some embodiments, one or more operations in a process 200 may be performed by an operator, or may be performed by machining equipment for crystal production and processing (e.g., a grinder, a polishing machine, or the like), or crystal performance inspection equipment. As shown in FIG. 2, the process 200 includes the following operations.

In 210, a plurality of initial crystals are obtained.

The plurality of initial crystals may include materials formed after crystal raw materials used for assembling a crystal array are cut. The crystal raw materials refer to crystal ingots grown in crystal growth equipment, or other shaped crystal raw materials. The initial crystals may have various shapes. For example, the plurality of initial crystals may be crystal strips, crystal blocks, crystal rods, or other shaped crystals.

The plurality of initial crystals may include, but are not limited to, cerium bromide crystals, cerium-doped lanthanum bromide crystals, cerium-doped lanthanum chloride crystals, silicate scintillator crystals, garnet scintillator crystals, or the like, or any combination thereof.

In some embodiments, the crystal raw materials may be selected. For example, crystal raw materials satisfying index conditions may be selected based on performance indices such as optical output performance, decay time, energy resolution, or the like of the crystal raw materials.

In some embodiments, an index condition corresponding to the optical output performance may be higher than 23000 ph/MeV. An index condition corresponding to the decay time may be less than 42 ns. An index condition corresponding to the energy resolution may be 5%-22%. Correspondingly, a crystal ingot or other shaped crystal having optical output performance higher than 23000 ph/MeV, decay time less than 42 ns, and energy resolution of 5%-22% may be selected as the crystal raw materials. In some embodiments, the optical output performance of the crystal may be detected according to a measurement method in related industry standards. For example, in combination with “GAGG Crystal and Wafer Array Performance Measurement Method”, measurement may be performed using a full absorption peak technique and a Compton edge technique. The measurement principle includes: when monoenergetic y radiation is incident on a scintillation detector, an output pulse amplitude distribution mainly consists of spectral segments such as a Compton distribution and a full absorption peak (except for a scintillator having a low atomic number), and the full absorption peak technique and the Compton edge technique respectively use a full absorption peak amplitude or a Compton distribution edge amplitude as a metric for determining scintillator optical output. As another example, in combination with “Measurement Method for Characteristic Parameters of Lutetium Silicate and Lutetium Yttrium Silicate Scintillator Single Crystals”, an intrinsic amplitude resolution (i.e., an energy resolution) of a scintillator under test may be obtained by measuring a pulse amplitude resolution of a scintillation detector and subtracting an inherent resolution contribution of a photomultiplier tube. As yet another example, in combination with “Measurement Method for Characteristic Parameters of Lutetium Silicate and Lutetium Yttrium Silicate Scintillator Single Crystals”, decay time may be measured using a direct oscilloscope technique. The measurement principle includes: after coupling a scintillator with a photomultiplier tube, a photon flux incident on a photocathode of the photomultiplier tube has a linear relationship with a photon emission rate of the scintillator; in a linear working state of the photomultiplier tube, an output current of the photomultiplier tube has a linear relationship with the photon flux incident on the photocathode; by measuring a distribution of the output current of the photomultiplier tube over time after single excitation of the scintillator, a photon distribution curve of the scintillator is obtained; and decay time t is obtained based on the photon distribution curve.

In some embodiments, a cutting treatment performed on the crystal raw materials may be a processing operation for changing the shape and dimension, etc., of the crystal raw materials. In some embodiments, the cutting treatment may include one or more of inner circular cutting, multi-wire cutting, and single-wire cutting.

In some embodiments, through the cutting treatment, the crystal raw materials may be cut into crystal strips as the initial crystals, and dimensions of the crystal strips may be (0.53 mm to 6.3 mm)×(0.53 mm to 6.3 mm)× (0.5 mm to 60 mm). In some embodiments, a cross-sectional shape of each crystal strip perpendicular to a length direction may be rectangular. In some embodiments, the dimensions of the crystal strips may be at least one of 0.53 mm×0.53 mm×5.3 mm, 0.53 mm×0.53 mm×10 mm, 0.53 mm×0.53 mm×30 mm, 0.53 mm×0.53 mm×60 mm, 2 mm×2 mm×10 mm, 2 mm×2 mm×30 mm, 2 mm×2 mm×60 mm, 4 mm×4 mm×10 mm, 4 mm×4 mm×20 mm, 4 mm×4 mm×30 mm, and 4 mm×4 mm×60 mm, and the dimensions of the crystal strips may be set based on specific requirements and are not limited herein.

In some embodiments, through the cutting treatment, the crystal raw materials may be cut into crystal cylinders as the initial crystals, and dimensions of the crystal cylinders may be (Ø30 mm to Ø125 mm)×(1 mm to 60 mm). In some embodiments, a cross-sectional shape of each crystal cylinder perpendicular to the length direction may be circular. In some embodiments, the dimensions of the crystal cylinders may be at least one of Ø30 mm×1 mm, Ø30 mm×10 mm, Ø30 mm×30 mm, Ø30 mm×60 mm, Ø50 mm×1 mm, Ø50 mm×10 mm, Ø50 mm×30 mm, Ø50 mm×60 mm, Ø100 mm×1 mm, Ø100 mm×10 mm, Ø100 mm×30 mm, Ø100 mm×60 mm, Ø125 mm×10 mm, Ø125 mm×30 mm, and Ø125 mm×60 mm, and the dimensions of the crystal cylinders may be set based on specific requirements and are not limited herein.

In some embodiments, through the cutting treatment, the crystal raw materials may be cut into crystal blocks as the initial crystals, and dimensions of the crystal blocks may be (1 mm to 125 mm)×(1 mm to 125 mm)× (1 mm to 280 mm). In some embodiments, a cross-sectional shape of each crystal block perpendicular to the length direction may be rectangular. In some embodiments, the dimensions of the crystal blocks may be at least one of 1 mm×1 mm×1 mm, 1 mm×1 mm×10 mm, 1 mm×1 mm×50 mm, 5 mm×5 mm×5 mm, 5 mm×5 mm×10 mm, 5 mm×5 mm×50 mm, 5 mm×5 mm×100 mm, 5 mm×5 mm×200 mm, 5 mm×5 mm×280 mm, 10 mm×10 mm×10 mm, 20 mm×20 mm×20 mm, 30 mm×30 mm×30 mm, 20 mm×20 mm×50 mm, 20 mm×20 mm×100 mm, 20 mm×20 mm×200 mm, 20 mm×20 mm×280 mm, 60 mm×60 mm×60 mm, 60 mm×60 mm×100 mm, 60 mm×60 mm×200 mm, 60 mm×60 mm×280 mm, 100 mm×100 mm×60 mm, 100 mm×100 mm×100 mm, 100 mm×100 mm×200 mm, 100 mm×100 mm×280 mm, 125 mm×125 mm×60 mm, 125 mm×125 mm×100 mm, 125 mm×125 mm×200 mm, and 125 mm×125 mm×280 mm, and the dimensions of the crystal blocks may be set based on specific requirements and are not limited herein.

It should be noted that the cross-sectional shape of the initial crystal obtained by the cutting treatment are described merely by way of example, and may be other shapes. For example, the cross-sectional shape may be triangular, hexagonal, elliptical, or the like. The length direction may be an axial direction of the initial crystal or a direction having a maximum dimension among three orthogonal directions of the initial crystal.

In some embodiments, an angle deviation between a first angle and a first preset angle is not greater than 0.5°. The first angle refers to an actual angle between a cutting surface of the initial crystal and a first preset surface. The first preset angle refers to an angle value expected to be achieved between the cutting surface and the first preset surface. In some embodiments, the first preset surface may be a side surface adjacent to the cutting surface. Correspondingly, the first preset angle between the cutting surface and the first preset surface may be in a range of 89.5° to 90.5°. For example, the first preset angle may be 89.5°, 89.6°, 89.7°, 89.8°, 89.9°, 90°, 90.1°, 90.2°, 90.3°, 90.4°, or 90.5°, and the first preset angle may be set based on specific requirements and is not limited herein. In some embodiments, the first preset surface may be a surface opposite to the cutting surface. Correspondingly, the first preset angle between the cutting surface and the first preset surface may be in a range of 0° to 3°. For example, the first preset angle may be 0°, 1°, 2°, or 3°, and the first preset angle may be set based on specific requirements and is not limited herein.

In some embodiments, the angle deviation between the first angle and the first preset angle is not greater than 0.4°. In some embodiments, the angle deviation between the first angle and the first preset angle is not greater than 0.3°. In some embodiments, the angle deviation between the first angle and the first preset angle is not greater than 0.2°.

In 220, an assembly scheme for assembling the plurality of initial crystals into the crystal array is determined.

The assembly scheme refers to a scheme for assembling the plurality of initial crystals into the crystal array. The assembly scheme may include, but is not limited to, at least one of a count of the plurality of target crystals in the crystal array, dimensions of the plurality of target crystals, surface roughness of the plurality of target crystals, arrangement positions of the plurality of target crystals, etc. The target crystals refer to crystal units that are processed and are used for assembling the crystal array.

The assembly scheme may be determined in various ways. In some embodiments, the assembly scheme may be preset by the operator. For example, the surface roughness of the target crystals may be preset by the operator. In some embodiments, the assembly scheme may be determined after analyzing and processing the target crystals. For example, the optical output performance of the plurality of target crystals may be detected; and the arrangement positions of the plurality of target crystals may be determined based on the optical output performance. More descriptions regarding the foregoing example may be found in the related descriptions below.

It should be noted that the assembly scheme may be determined a plurality of times. For example, a crystal assembly device may first determine the surface roughness of the plurality of target crystals in the assembly scheme, and preprocess the plurality of initial crystals to obtain the plurality of target crystals, and then detect the optical output performance of the plurality of target crystals; and determine the arrangement positions of the plurality of target crystals in the assembly scheme based on the optical output performance. More descriptions regarding preprocessing the plurality of initial crystals and determining the arrangement positions of the plurality of target crystals may be found in the related descriptions below.

In 230, the plurality of initial crystals are preprocessed based on the assembly scheme to obtain the plurality of target crystals.

In some embodiments, the plurality of initial crystals may be preprocessed based on the assembly scheme to obtain the plurality of target crystals, and the plurality of target crystals satisfy requirements of the assembly scheme.

The preprocessing includes at least one of a grinding treatment or a polishing treatment, and the plurality of target crystals obtained after the preprocessing satisfy a requirement on surface roughness of the crystal units in the assembly scheme.

In some embodiments, the surface roughness of the one or more initial crystals may be adjusted through the grinding treatment. A surface obtained after the grinding treatment is referred to as a grinding surface. In some embodiments, the grinding treatment may be performed on one or two end surfaces of the one or more initial crystals to obtain the grinding surface. The end surfaces refer to planar surfaces at two ends of the one or more initial crystals along the length direction. In some embodiments, the grin The grinding treatment may be a processing operation for performing finishing machining on the surface of the one or more initial crystals by coating or press-embedding abrasive particles on a grinding tool and causing relative movement between the grinding tool and the one or more initial crystals under a certain pressure.

ding treatment may be performed on all surfaces of the one or more initial crystals to obtain the grinding surface. For example, when the one or more initial crystals are cuboids, the grinding treatment may be performed on six surfaces of the one or more initial crystals.

In some embodiments, the grinding treatment may include at least one of single-side grinding, double-sided grinding, or the like. For example, a 6B-16B grinder may be used to perform single-side grinding or double-side grinding on the one or more initial crystals.

In some embodiments, the surface roughness Ra of the grinding surface may be in a range of 0.1 μm to 1.5 μm. In some embodiments, the surface roughness Ra of the grinding surface may be in a range of 0.1 μm to 1 μm. In some embodiments, the surface roughness Ra of the grinding surface may be in a range of 0.1 μm to 0.5 μm. In some embodiments, the surface roughness Ra of the grinding surface may be in a range of 0.5 μm to 1.5 μm. In some embodiments, the surface roughness Ra of the grinding surface may be in a range of 0.5 μm to 1 μm. In some embodiments, the surface roughness Ra of the grinding surface may be 0.1 μm, 0.2 μm, 0.3 μm, 0.4 μm, 0.5 μm, 0.8 μm, 1 μm, 1.1 μm, 1.2 μm, 1.3 μm, 1.4 μm, or 1.5 μm, and the surface roughness Ra of the grinding surface may be set based on specific requirements and is not limited herein.

In some embodiments, an angle deviation between a second angle and a second preset angle is not greater than 0.5°. The second angle refers to an actual angle between the grinding surface and a second preset surface. The second preset angle refers to an angle value expected to be achieved between the grinding surface and the second preset surface. In some embodiments, the second preset surface may be a side surface adjacent to the grinding surface. Correspondingly, the second preset angle between the grinding surface and the second preset surface may be in a range of 89.5° to 90.5°. For example, the second preset angle may be 89.5°, 89.6°, 89.7°, 89.8°, 89.9°, 90°, 90.1°, 90.2°, 90.3°, 90.4°, or 90.5°, and the second preset angle may be set based on specific requirements and is not limited herein. In some embodiments, the second preset surface may be an end surface opposite to the grinding surface. Correspondingly, the second preset angle between the grinding surface and the second preset surface may be in a range of 0° to 3°. For example, the second preset angle may be 0°, 1°, or 2°, and the second preset angle may be set based on specific requirements and is not limited herein.

In some embodiments, the angle deviation between the second angle and the second preset angle is not greater than 0.4°. In some embodiments, the angle deviation between the second angle between and the second preset angle is not greater than 0.3°. In some embodiments, the angle deviation between the second angle and the second preset angle is not greater than 0.2°.

In some embodiments, the polishing treatment may be a processing operation of processing the surface of the one or more initial crystals using a mechanical manner, a chemical manner, or an electrochemical manner, such that the surface roughness of the surface of the one or more initial crystals is reduced, thereby obtaining a bright and flat surface. In some embodiments, the polishing treatment may be performed on at least one surface of the one or more initial crystals. For example, the polishing treatment may be performed on one or two end surfaces of the one or more initial crystals or a cutting body.

A surface obtained after the polishing treatment is referred to as a polishing surface. In some embodiments, the polishing treatment may be performed on the grinding surface to obtain the polishing surface. In some embodiments, the polishing treatment may be performed on a non-grinding surface to obtain the polishing surface. In some embodiments, the polishing treatment may be performed on the end surfaces to obtain the polishing surface.

In some embodiments, the dimensions of the crystal strips after the polishing treatment may be (0.5 mm to 6 mm)× (0.5 mm to 6 mm)× (0.5 mm to 59.5 mm). In some embodiments, the dimensions of the crystal cylinders after the polishing treatment may be (Ø15 mm to Ø200 mm)× (0.9 mm to 280 mm). In some embodiments, dimensions of square crystal columns after the polishing treatment may be (0.5 mm to 150 mm)×(0.5 mm to 150 mm)×(0.5 mm to 279 mm).

In some embodiments, a finish grade of the polishing surface is not greater than 60/40 (where 60 limits a scratch size, and 40 limits a pit size). In some embodiments, the finish grade of the polishing surface obtained by the polishing treatment is not greater than 40/20. In some embodiments, the surface roughness Ra of the polishing surface obtained by the polishing treatment is in a range of 0.001 μm to 0.08 μm.

In some embodiments, an angle deviation between a third angle and a third preset angle is not greater than 0.5°. The third angle refers to an actual angle between the polishing surface and a third preset surface. The third preset angle refers to an angle value expected to be achieved between the polishing surface and the third preset surface. In some embodiments, the third preset surface may be a side surface adjacent to the polishing surface. In some embodiments, the third preset surface may be an end surface opposite to the polishing surface. The third preset angle is similar to the first preset angle and the second preset angle, and more descriptions may be found in the related descriptions above.

In some embodiments, the angle deviation between the third angle and the third preset angle is not greater than 0.4°. In some embodiments, the angle deviation between the third angle and the third preset angle is not greater than 0.3°. In some embodiments, the angle deviation between the third angle and the third preset angle is not greater than 0.2°.

In some embodiments, a dimension of chipping of the polishing surface is less than 1.5 mm×1.5 mm×1.5 mm. In some embodiments, the dimension of chipping of the polishing surface is less than 1.3 mm×1.3 mm×1.3 mm. In some embodiments, the dimension of chipping of the polishing surface is less than 1.2 mm×1.2 mm×1.2 mm. In some embodiments, the dimension of chipping of the polishing surface is less than 1.1 mm×1.1 mm×1.1 mm. In some embodiments, the dimension of chipping of the polishing surface is less than 1 mm×1 mm×1 mm. The chipping of the polishing surface may be a notch in the polishing surface or the like. The dimension of chipping may be a maximum dimension among a length, a width, and a depth of the notch.

Through at least one of the grinding treatment or the polishing treatment, the plurality of target crystals having smooth surfaces, smaller surface roughness, and smaller angle deviations may be obtained, thereby improving a utilization rate of crystals and preparing for subsequent array arrangement, to improve a qualification rate and resolution of the crystal array.

In some embodiments, quality inspection may be performed on a processed piece obtained by the preprocessing, and the processed piece satisfying a quality inspection standard is determined as a target crystal. For example, the processed piece may be a crystal strip after at least one of the grinding treatment or the polishing treatment.

In some embodiments, the quality inspection includes sampling inspection or full inspection of performance and appearance. In some embodiments, a quality inspection standard for appearance includes: the surface roughness Ra of the grinding surface being in a range of 0.08 μm to 1.5 μm; the angle deviation between the second angle and the second preset angle being not greater than 0.5°; the surface roughness Ra of the polishing surface being not greater than 0.08 μm; the angle deviation between the third angle and the third preset angle being not greater than 0.5°; or the dimension of chipping of the polishing surface being less than 1.5 mm×1.5 mm×1.5 mm. In some embodiments, a quality inspection standard for performance includes at least one of: the optical output performance being higher than 23000 Ph/MeV; decay time being less than 42 ns; or energy resolution being greater than 5%.

In 240, the plurality of target crystals are assembled into the crystal array.

The crystal array refers to an array obtained by combining the plurality of target crystals.

In some embodiments, the plurality of target crystals may be assembled into the crystal array through optical coupling. For example, the plurality of target crystals may be assembled into the crystal array through one or more of direct coupling, optical fiber coupling, prism coupling, waveguide coupling, or the like.

In some embodiments, the plurality of target crystals may be bonded and assembled into the crystal array. More descriptions regarding bonding and assembling may be found in the related descriptions below.

In some embodiments, a reflective structure is provided between at least two adjacent target crystals of the crystal array.

The reflective structure refers to a structure having a light reflection capability inside the crystal array. In some embodiments, the reflective structure may be provided between each two target crystals.

In some embodiments, the reflective structure includes at least one of a reflective filling material or a reflective film. In some embodiments, the reflective structure may enhance optical performance of the crystal array and prevent optical crosstalk between the target crystals.

The reflective filling material refers to a structure filled between the target crystals in the crystal array. In some embodiments, the reflective filling material may be filled between the target crystals to bond the target crystals. In some embodiments, the reflective filling material may reduce or prevent optical crosstalk between any two adjacent target crystals, thereby improving an anti-crosstalk effect.

The reflective film refers to a light-impermeable reflective medium layer. In some embodiments, a reflectivity of the reflective film to visible light is greater than 92%, and a thickness of the reflective film is less than 0.3 mm. In some embodiments, the thickness of the reflective film is not greater than 0.5 mm.

In some embodiments, the reflective film may be at least one of an enhanced specular reflector (ESR) film, a polytetrafluoroethylene tape, aluminum foil paper, a white polyester reflective film, a white polypropylene reflective film, a silver-plated mirror reflective film, an E60 reflective film, or the like.

In some embodiments, at least one layer of reflective film is used when forming the crystal array. In some embodiments, the reflective film may be filled between the crystal rows (or crystal columns) in the crystal array. In some embodiments, the reflective film may increase optical performance of the crystal array and prevent optical crosstalk between the crystal rows (or the crystal columns). More descriptions regarding the crystal rows and assembling the crystal array using the reflective film may be found in the related descriptions below.

In some embodiments, the reflective filling material includes a compound. The compound is at least one of a barium compound, a titanium compound, or a mixture of the barium compound and the titanium compound.

The titanium compound and the barium compound may be used as fillers of a reflective layer. The titanium compound and the barium compound have respective advantages and characteristics in different optical applications and electronic applications. When selecting fillers, factors such as a wavelength range required by the reflective layer, reflection performance, transparency, mechanical strength, and environmental stability are considered. Different filler materials have different advantages and limitations, therefore, an appropriate material may be selected based on requirements of a specific application. A typical reflective layer is usually a multilayer structure, including stacking of a plurality of different materials, to achieve specific reflection performance and transmission performance. Merely by way of example, the barium compound may be at least one of barium sulfate (BaSO₄), barium titanate (BaTiO₃), barium carbonate (BaCO₃), or barium chloride (BaCl₂). The titanium compound may be at least one of titanium dioxide (TiO₂), indium tin oxide (ITO), titanium nitride (TiN), or the like. BaSO₄ has high opacity and high reflectivity in visible light and infrared spectral ranges. TiO₂ has a high refractive index and high reflectivity, and has excellent performance particularly in an ultraviolet spectral range. BaTiO₃ has excellent photorefractive performance and has a high beam coupling gain, and is capable of operating at visible light and near-infrared wavelengths. ITO is a material having transparent conductivity, and has good corrosion resistance and stability. TiN has high hardness, heat resistance, wear resistance, and corrosion resistance, and has a higher transmittance in a visible light range. Using the compounds as optical materials for fillers of the reflective layer may improve reflection performance of the reflective layer and consider high transparency, thereby effectively ensuring the optical output performance of the crystal array.

In some embodiments, the reflective filling material is prepared from glue, water, and the compound according to an ingredient ratio of (1~3):(0~2):(5~7). The glue is a fluid glue. For example, the glue may be polyvinyl alcohol (PVAL) or the like. The water may be pure water, ordinary tap water, deionized water, distilled water, or the like.

In some embodiments, a volume of a solid particle in the reflective filling material is less than 0.2 mm³. The solid particle in the reflective filling material includes at least one of the titanium compound or the barium compound.

In some embodiments, surface roughness Ra of the reflective structure formed by the reflective filling material is less than 100 μm. In some embodiments, the surface roughness Ra of the reflective structure formed by the reflective filling material is less than 90 μm. In some embodiments, the surface roughness Ra of the reflective structure formed by the reflective filling material is less than 80 μm. In some embodiments, the surface roughness Ra of the reflective structure formed by the reflective filling material is less than 70 μm. In some embodiments, the surface roughness Ra of the reflective structure formed by the reflective filling material is less than 60 μm. In some embodiments, the surface roughness Ra of the reflective structure formed by the reflective filling material is less than 50 μm. In some embodiments, the surface roughness Ra of the reflective structure formed by the reflective filling material is less than 40 μm. In some embodiments, the surface roughness Ra of the reflective structure formed by the reflective filling material is less than 30 μm. In some embodiments, the surface roughness Ra of the reflective structure formed by the reflective filling material is less than 20 μm. In some embodiments, the surface roughness Ra of the reflective structure formed by the reflective filling material is less than 10 μm. In some embodiments, the surface roughness Ra of the reflective structure formed by the reflective filling material is 100 μm, 95 μm, 90 μm, 85 μm, 80 μm, 75 μm, 70 μm, 60 μm, 50 μm, 40 μm, 30 μm, 20 μm, or 10 μm, and the surface roughness Ra of the reflective structure formed by the reflective filling material may be set based on specific requirements and is not limited herein. If the surface roughness of the reflective structure is too high, stability performance during bonding and assembling decreases. By controlling the surface roughness of the reflective structure, the stability of bonding and assembling is ensured at least.

In some embodiments, a preparation process of the reflective filling material includes: determining a first mass of the glue, a second mass of the water, and a third mass of the compound according to the ingredient ratio; placing the first mass of the glue into a preparation container, placing the second mass of the water into the preparation container, and performing stirring; adding a preset mass of the compound into the preparation container at each preset time interval, and performing stirring at a preset stirring rate, wherein the preset mass is less than or equal to the third mass; and after all the third mass of the compound has been placed into the preparation container, continuing stirring for a preset time to obtain the reflective filling material.

In some embodiments, the first mass, the second mass, and the third mass may be determined in a plurality of manners. For example, the first mass may be preset first, and the second mass and the third mass are determined according to the ingredient ratio. As another example, the second mass may be preset first, and the first mass and the third mass are determined according to the ingredient ratio.

In some embodiments, the preparation container may be a cleaned stainless steel container, a plastic container, or the like, and may be set based on actual requirements.

In some embodiments, the first mass of the glue may first be placed into the preparation container and stirred, and while stirring, the second mass of the water is placed into the preparation container, with the stirring continued. In some embodiments, after the first mass of the glue and the second mass of the water are simultaneously placed into the preparation container, the stirring is performed.

In some embodiments, after the stirring is performed for a specific time, the preset mass of the compound is added into the preparation container at each preset time interval.

The preset mass refers to at least a portion of the third mass of the compound. The preset mass is less than or equal to the third mass. After the stirring is performed for the specific time, the glue and the water may be considered to be uniformly mixed. For example, the third mass is 1 kilogram, and the preset mass may be 10 grams to 500 grams. For example, the specific time is 20 minutes to 40 minutes, and the preset time interval is 10 minutes to 20 minutes. The specific time, the preset time interval, and the preset mass may each be an experience value, a manually preset value, or a combination of the experience value and the manually preset value, and may be set based on actual requirements. The present disclosure is not limited thereto.

In some embodiments, when the compound is a mixture of the barium compound and the titanium compound, before the compound is added into the preparation container, the mixture of the barium compound and the titanium compound may be stirred in advance, such that the barium compound and the titanium compound are uniformly mixed.

In some embodiments, the preset stirring rate may be 1 rpm to 200 rpm. In some embodiments, the preset stirring rate may be 1 rpm to 180 rpm. In some embodiments, the preset stirring rate may be 1 rpm to 150 rpm. In some embodiments, the preset stirring rate may be 1 rpm to 100 rpm. In some embodiments, the preset stirring rate may be 10 rpm, 20 rpm, 40 rpm, 50 rpm, 60 rpm, 80 rpm, 100 rpm, 120 rpm, 150 rpm, 180 rpm, 200 rpm, etc. The preset stirring rate may be set according to specific requirements, and is not limited herein.

In some embodiments, after all the third mass of the compound has been placed into the preparation container, the stirring is continued for the preset time to obtain the reflective filling material. In some embodiments, the preset time may be 0.5 hours to 2 hours. In some embodiments, the preset time may be 0.5 hours to 1.5 hours. In some embodiments, the preset time may be 0.5 hours to 1 hour. In some embodiments, the preset time may be 1 hour to 2 hours. In some embodiments, the preset time may be 1 hour to 1.5 hours. In some embodiments, the preset time may be 0.5 hours, 1 hour, 1.5 hours, 2 hours, etc. The preset time may be set according to specific requirements, and is not limited herein.

In some embodiments, the prepared reflective filling material may be stored under constant temperature and humidity conditions. The constant temperature and humidity conditions include a temperature not higher than 30° C. and a humidity greater than 60%.

In some embodiments of the present disclosure, the barium compound, the titanium compound, or the mixture of the barium compound and the titanium compound, and the glue and the water are prepared according to a certain ratio, such that the reflective filling material having certain fluidity, low abrasiveness, high glossiness, stable color, low cohesiveness, no heavy metal contamination, and no toxicity (e.g., rubber toxic gas) is obtained. When the reflective filling material is used for bonding and assembling, optical crosstalk between crystals in the crystal array during assembling is effectively prevented. Meanwhile, the thickness of the reflective filling material after drying is relatively small, cracks are not likely to be generated, the reflection performance for light is better, and the optical output performance is effectively ensured.

The bonding and assembling refers to an operation of arranging and combining the plurality of target crystals into the crystal array.

In some embodiments, partitioning and tray arrangement may be performed on the plurality of target crystals to obtain a plurality of crystal combinations. Each crystal combination may be bonded and assembled into one crystal array according to the arrangement positions. It should be noted that, the partitioning and tray arrangement on all the target crystals may be performed based on uniform test conditions.

The partitioning and tray arrangement refers to an operation of dividing crystals capable of being assembled to form the same crystal array as one crystal combination.

In some embodiments, the partitioning and tray arrangement includes: dividing a plurality of target crystals having close performance into one crystal combination. In some embodiments, close performance may mean that differences among the optical output performance, decay time, and/or energy resolution of the target crystals are less than corresponding difference thresholds. The difference thresholds may each be an experience value, a manually preset value, or a combination of the experience value and the manually preset value.

In some embodiments, the optical output performance of the target crystal may include light energy output by the target crystal (also referred to as an optical output value). In some embodiments, close optical output performance may include that a difference in light energy among the plurality of target crystals is less than a corresponding difference threshold.

In some embodiments, the optical output performance of the target crystal may further include a light yield of the target crystal.

In some embodiments, the close optical output performance may include that the light yields of two target crystals are close. In some embodiments, the light yield of the target crystal may be measured by an area of a full-energy peak corresponding to a channel address value of the target crystal. In some embodiments, when a relative light yield difference between two target crystals is less than a corresponding difference threshold, the light yields of the two target crystals may be considered to be close. In some embodiments, the relative light yield difference may be characterized by a difference between areas of full-energy peaks corresponding to channel address values of the two target crystals.

When high-energy particles such as X-rays (or y-rays) interact with a crystal, the high-energy particles deposit energy in the crystal, causing atoms of the crystal to enter an excited state, and fluorescence photons are emitted during de-excitation. The fluorescence photons are converted into photoelectrons through a photoelectric device. For example, a photoelectric effect is generated by the fluorescence photons at a photocathode of a photomultiplier tube (PMT), and the fluorescence photons are converted into photoelectrons. Then, pulse signals are formed after multiplication amplification and digital-to-analog conversion processing by the photoelectric device. A count of pulses corresponds to a count of incident particles, and a pulse amplitude of the pulse signals is proportional to a count of fluorescence photons generated by the crystal, and is proportional to energy deposited by the incident particles in the crystal. Therefore, a difference between areas of full-energy peak corresponding to channel address values of the two target crystals may be used to characterize the relative light yield difference. The channel address values are obtained by an analyzer converting the pulse signals into digits corresponding to amplitudes of the pulse signals.

In some embodiments, the relative light yield difference between any two target crystals in the crystal array is not greater than 3600 Ph/MeV. In some embodiments, the relative light yield difference between any two target crystals in the crystal array is not greater than 3400 Ph/MeV. In some embodiments, the relative light yield difference between any two target crystals in the crystal array is not greater than 3200 Ph/MeV. In some embodiments, the relative light yield difference between any two target crystals in the crystal array is not greater than 3000 Ph/MeV. In some embodiments, the relative light yield difference between any two target crystals in the crystal array is not greater than 2800 Ph/MeV. In some embodiments, the relative light yield difference between any two target crystals in the crystal array may be 3600 Ph/MeV, 3500 Ph/MeV, 3400 Ph/MeV, 3300 Ph/MeV, 3200 Ph/MeV, 3100 Ph/MeV, 3000 Ph/MeV, etc., which may be set according to specific requirements and is not limited herein.

In some embodiments, the partitioning and tray arrangement includes: dividing a plurality of target crystals having close dimensions into one crystal combination. In some embodiments, close dimensions may mean that dimension deviations of the target crystals are less than corresponding dimension deviation thresholds (e.g., 0.1 mm). For example, when a length deviation, a width deviation, and a height deviation of the plurality of target crystals are respectively less than corresponding dimension deviation thresholds, the dimensions of the plurality of target crystals may be considered to be close.

In some embodiments, partitioning and tray arrangement includes: dividing a plurality of target crystals in which a perpendicularity deviation between any two surfaces is less than a perpendicularity deviation threshold into one crystal combination. The perpendicularity deviation threshold may be an experience value, a manually preset value, or a combination of the experience value and the manually preset value.

In some embodiments of the present disclosure, partitioning and tray arrangement is performed on the target crystals according to performance of the target crystals (e.g., the optical output performance, decay time, energy resolution, and/or channel address values), such that the target crystals having the close optical output performance, decay time, and/or energy resolution and a relatively small difference in the channel address values are divided into one crystal combination, thereby facilitating subsequent assembling of the crystal array, effectively ensuring performance similarity of crystals in the crystal array, and improving a qualification rate of the crystal array.

In some embodiments, the arrangement positions may be determined based on the optical output performance of the plurality of target crystals in the crystal combination. More descriptions regarding the arrangement positions may be found in the related descriptions above.

In some embodiments, the bonding and assembling may be performed manually, or may be performed automatically by a machine.

In some embodiments, the bonding and assembling includes: bonding the plurality of target crystals using the reflective filling material to form an initial crystal array, wherein a thickness of the reflective filling material is less than 1.5 mm. In some embodiments, the bonding and assembling includes: bonding the plurality of target crystals using the reflective film or the reflective filling material to form the initial crystal array, with the thickness of the reflective film or the reflective filling material less than 0.5 mm.

The initial crystal array refers to an array obtained after the bonding and assembling. The initial crystal array has not undergone post-processing operations.

Merely by way of example, the reflective filling material may be used to bond two target crystals in the plurality of target crystals to obtain a first array, the first array being a 1×2 array; the reflective filling material may be used to bond two first arrays to obtain a second array, the second array being a 2×2 array; the reflective filling material may be used to bond four second arrays to obtain a third array, the third array being a 4×4 array; the reflective filling material may be used to bond four third arrays to obtain a fourth array, the fourth array being an 8×8 array; and by analogy, the initial target array is obtained, the initial target array being an N&N array. Nis the wrap count of the crystal array, and Nis a multiple of 2. Correspondingly, N is a count of target crystals included in each row or each column of the crystal array.

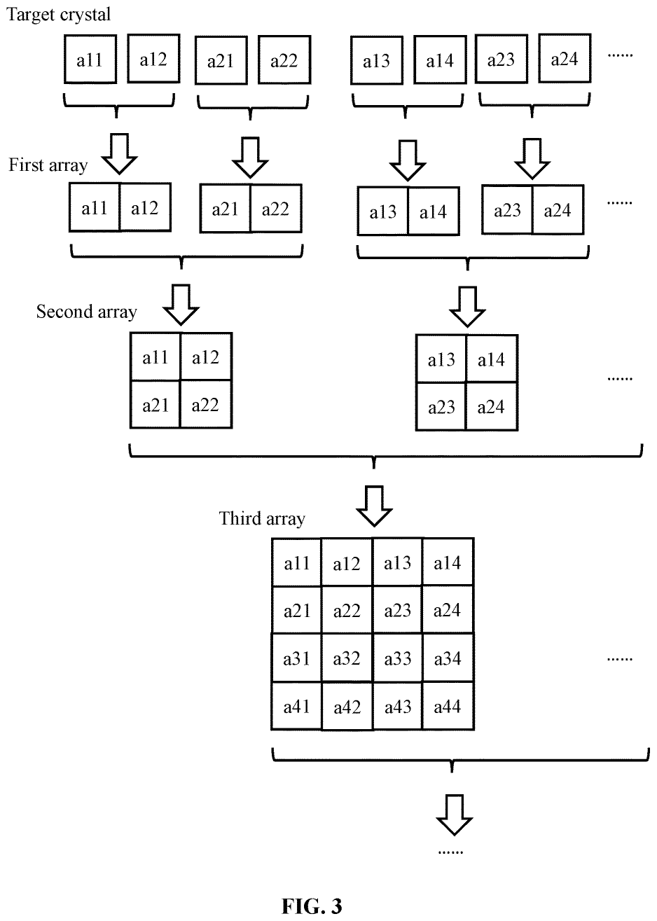

Referring to FIG. 3, a target crystal a11 and a target crystal a12 may be bonded to obtain a first array (a11, a12), a target crystal a21 and a target crystal a22 may be bonded to obtain a first array (a21, a22), a target crystal a13 and a target crystal a14 may be bonded to obtain a first array (a13, a14), and a target crystal a23 and a target crystal a24 may be bonded to obtain a first array (a23, a24). Further, the first array (a11, a12) and the first array (a21, a22) may be bonded to obtain a second array (a11, a12; a21, a22), and the first array (a13, a14) and the first array (a23, a24) may be bonded to obtain a second array (a13, a14; a23, a24). Further, the second array (a11, a12; a21, a22), the second array (a13, a14; a23, a24), and a second array (a31, a32; a41, a42) and a second array (a33, a34; a43, a44) which are not shown in FIG. 3, may be bonded to obtain a third array (a11, a12, a13, a14; a21, a22, a23, a24; a31, a32, a33, a34; a41, a42, a43, a44), and by analogy, the N×N crystal array may be obtained.

In some embodiments, when a first array is assembled, the reflective filling material may be applied on one side surface of one of two target crystals, and after standing and drying for 5 s to 20 s, the side surfaces coated with the reflective filling material of two target crystals are bonded according to a 1×2 array structure, an abutting angle is adjusted and pressing is performed until the dimension of the reflective filling material in the first array satisfy a requirement (i.e., the thickness of the reflective filling material is less than 1.5 mm), thereby obtaining the first array. In some embodiments, the side surface of the target crystal coated with the reflective filling material may be a surface other than the end surfaces of the target crystal. In some embodiments, each two adjacent target crystals may be assembled according to the arrangement positions to obtain a plurality of first arrays.

In some embodiments, when a second array is assembled, the reflective filling material may be applied on one larger surface of one of two first arrays, and the larger surfaces coated with the reflective filling material of two first arrays are bonded according to a 2×2 array structure, thereby obtaining the second array. In some embodiments, the larger surfaces coated with the reflective filling material of two first arrays may be bonded by aligning seam lines and perpendicularity. In some embodiments, the larger surface of the first array may be a larger side surface other than the end surfaces of the first array. For example, the larger surface may be a larger surface formed after two target crystals are bonded. In some embodiments, each two adjacent first arrays may be assembled according to the arrangement positions to obtain a plurality of second arrays. It should be noted that, the operation of assembling the second array is similar to that of the first array. For example, the second array is obtained through an operation including standing and drying, abutting, adjusting an abutting angle, and pressing.

In some embodiments, when a third array is assembled, the reflective filling material may be applied on two adjacent side surfaces of each second array in four second arrays, and the side surfaces coated with the reflective filling material of the four second arrays are bonded one by one according to a 4×4 array structure, thereby obtaining the third array. In some embodiments, each four adjacent second arrays may be assembled according to the arrangement positions to obtain a plurality of third arrays. It should be noted that, the operation of assembling the third array is similar to that of the first array, and details are not described herein again.

By performing the assembling operation a plurality of times, the N×N crystal array may be obtained.

As another example, the reflective filling material may be used to bond two target crystals in the plurality of target crystals according to a 1×2 structure (1 being a row count, and 2 being a column count), to obtain at least one 1×2 array; the reflective filling material may be used to bond two first arrays in the at least one 1×2 array according to a 2×2 structure (2 being a row count, and 2 being a column count), to obtain a 2×2 array; the reflective filling material may be used to bond three first arrays in the at least one first array according to a 1×6 structure (1 being a row count, and 6 being a column count), a 6×1 structure (6 being a row count, and 1 being a column count), a 3×2 structure (3 being a row count, and 2 being a column count), or a 2×3 structure (2 being a row count, and 3 being a column count), to obtain an array having a corresponding structure; and by analogy, the initial target array is obtained, the initial target array being a K×M array, where the wrap count of the crystal array is (K, M), K indicates a count of target crystals included in each row, and M indicates a count of target crystals included in each column.

In some embodiments, during assembling, it is required to ensure that a thickness of each layer of the reflective structure (e.g., the reflective filling material) is less than 1.5 mm, a height deviation between end surfaces of any two target crystals in the initial crystal array is less than 0.5 mm, and a misalignment distance of seam lines is less than 0.2 mm. In some embodiments, during assembling, it is required to ensure that the thickness of each layer of the reflective structure (e.g., the reflective filling material) is less than 0.5 mm, the height deviation between end surfaces of any two target crystals in the initial crystal array is less than 0.5 mm, and the misalignment distance of seam lines is less than 0.2 mm. The height deviation of the end surfaces of the initial crystal array refers to a height difference between a highest end surface and a lowest end surface among the end surfaces of the plurality of target crystals forming the initial crystal array in a direction perpendicular to the end surfaces. The highest end surface and the lowest end surface are respectively a highest plane and a lowest plane in the direction perpendicular to the end surfaces. The misalignment distance of the seam lines refers to a deviation value of seam lines between different target crystals.

In some embodiments of the present disclosure, through the assembling process from 1-wrap to N-wrap, the misalignment distance of seam lines may be reduced as much as possible, such that, when an accumulated deviation of the N-wrap crystal array is consistent with a dimension deviation of 1-wrap, the external dimensions of the crystal array are optimal.

In some embodiments, the bonding and assembling includes: an arrangement operation; a laminating operation; and a bonding operation. The arrangement operation includes arranging a plurality of the target crystals into a row to form a crystal row. The laminating operation includes applying glue on the crystal row, such that one side surface of the reflective film is attached to one side surface of the crystal row, and the reflective film covers each target crystal in the crystal row. The bonding operation includes applying glue on the other side surface of the reflective film and attaching another crystal row to the other side surface of the reflective film.

In some embodiments, the bonding and assembling further includes: repeating the laminating operation and the bonding operation to form the initial crystal array. For example, by repeating the laminating operation M times and repeating the bonding operation M times, an initial crystal array including M+1 crystal rows is obtained. The crystal row refers to a structure formed by arranging at least two target crystals into one row.

In some embodiments, after the arrangement operation or the laminating operation is performed, one or more of the cutting treatment, the grinding treatment, or the polishing treatment may be performed on the target crystals again. For example, the target crystals may be further cut to obtain crystal strips having sheet structures, and the grinding treatment and/or the polishing treatment may be performed on the crystal strips having the sheet structures after further cutting.

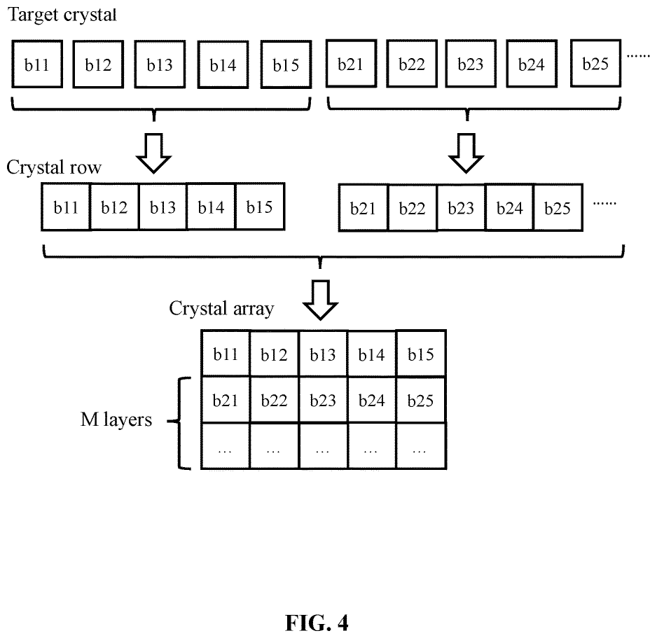

Referring to FIG. 4, target crystals b11, b12, b13, b14, and b15 may be arranged into a row to form a crystal row (b11, b12, b13, b14, b15), and target crystals b21, b22, b23, b24, and b25 may be arranged into a row to form a crystal row (b21, b22, b23, b24, b25). Further, the crystal row (b11, b12, b13, b14, b15) and the crystal row (b21, b22, b23, b24, b25) may first be bonded using the reflective film, and the crystal row (b21, b22, b23, b24, b25) may then be bonded to other crystal rows using the reflective film. By analogy, the initial crystal array including M+1 crystal rows may be obtained through M laminating operations and M bonding operations.

In some embodiments, when the crystal row is assembled, the reflective filling material may be applied on one side surface of one of each two target crystals, and side surfaces coated with the reflective filling material of two target crystals are bonded, to obtain a plurality of 1×2 arrays. Further, the reflective filling material may be applied on one small surface of one of each two 1×2 arrays, and small surfaces coated with the reflective filling material of two 1×2 arrays are bonded according to a 1×4 array structure, to obtain a plurality of 1×4 arrays. By analogy, a 1×S crystal row may be obtained, and S is a count of target crystals included in the crystal row.

In some embodiments, when the crystal row is assembled, two target crystals may first be bonded using the reflective filling material, and then another target crystal may be bonded to the bonded body formed by the first two target crystals using the reflective filling material. By analogy, the 1×S crystal row may be obtained, and S is a count of target crystals included in the crystal row.

In some embodiments, the process for bonding the reflective film to the crystal row includes: applying a particular type of glue on one large side surface of the crystal row (the particular type of glue is at least one of a photosensitive curing glue, a heat-sensitive curing glue, a resin glue, a flowable self-drying glue, or the like); bonding the reflective film to the large side surface coated with the particular type of glue; pressing the reflective film such that the reflective film is attached to the large side surface of the crystal row, discharging bubbles between the reflective film and the crystal row, performing curing using an ultraviolet lamp; and finally adjusting the dimension and flatness of the reflective film. The large side surface of the crystal row refers to a large plane formed by combining the side surfaces of the plurality of target crystals. In some embodiments, the reflective film completely covers a corresponding side surface of each target crystal in the crystal row. For example, when the reflective film is bonded to one large side surface of the crystal row, the reflective film completely covers the corresponding side surface of each target crystal in the large side surface. In other embodiments, the reflective film partially covers the corresponding side surface of at least one target crystal in the crystal row. This means that, for some target crystals, the reflective film may cover only a portion of the corresponding side surface of the target crystals. The corresponding side surface of the target crystal may be a surface of the target crystal other than a light-exiting surface. With such a configuration, by adjusting a ratio of an area of the reflective film between two adjacent target crystals in two adjacent columns to an area of the corresponding side surface, propagation of light between the corresponding two target crystals may be adjusted, thereby adjusting optical output of the entire crystal array.

In some embodiments, when the glue is applied on one large side surface of the crystal row, at least one continuous strip of the particular type of glue may be applied on the large side surface of the crystal row. An application direction of the glue may be the same as a long-side direction of the crystal row.

In some embodiments, when curing is performed using the ultraviolet lamp, the reflective film may first be irradiated with the ultraviolet lamp for a period of time (e.g., 3 seconds to 25 seconds), a thickness of the glue and a position of the reflective film are then adjusted through pressing and/or stretching, and the reflective film is then continuously irradiated with the ultraviolet lamp for a period of time (e.g., 5 seconds to 25 seconds) until curing of the glue is completed.

In some embodiments, adjusting the dimension of the reflective film includes: adjusting the dimension of the reflective film to be consistent with the dimension of the large side surface of the crystal row. In some embodiments, adjusting the flatness of the reflective film includes: adjusting the flatness of the reflective film to be less than 0.5 mm. The process for adjusting the dimension and the flatness includes cutting, grinding, or the like.

In some embodiments, the process for bonding the crystal row to the reflective film includes: applying the glue on the reflective film; attaching the large side surface of another crystal row to the reflective film through a right-angle tool; discharging bubbles between the another crystal row and the reflective film; adjusting a position of the another crystal row; and finally performing curing using the ultraviolet lamp.

As technology advances, scintillator crystal arrays are increasingly miniaturized, requirements for multiple pixel increase, the dimension of crystal strips become smaller, crystal strip breakage may occur during assembly of the crystal strips, and assembly of the crystal array becomes increasingly difficult. In some embodiments of the present disclosure, by first assembling the plurality of target crystals into a plurality of crystal rows and then assembling the plurality of crystal rows into the initial crystal array, assembly efficiency of the crystal array and a yield rate of the crystal array can be effectively improved.

In some embodiments, after the initial crystal array is obtained, the bonding and assembling further includes: performing at least one of the grinding treatment or the polishing treatment on a first surface and a second surface of the initial crystal array, wherein at least one of the first surface or the second surface is a light-exiting surface, and the first surface and the second surface are opposite surfaces; coating other side surfaces with the reflective filling material to form a reflective layer wrapping the other side surfaces of the initial crystal array,
wherein the other side surfaces are side surfaces of the initial crystal array other than the first surface and the second surface; and wrapping at least one protective layer around side surfaces of the initial crystal array other than the light-exiting surface to obtain the crystal array.

In some embodiments, one end surface of the initial crystal array may serve as the first surface, and another opposite end surface may serve as the second surface. In some embodiments, the end surfaces of the initial crystal array may include concave points and convex points having a height difference not greater than 0.08 mm. The height difference between the concave points and the convex points refers to a height difference between a deepest concave point and a highest convex point.

In some embodiments, the first surface and the second surface may both be the light-exiting surfaces. In some embodiments, the first surface or the second surface may be the light-exiting surface.

In some embodiments, a dry grinding method may be used to perform the grinding treatment on the first surface and the second surface of the initial crystal array, or the grinding treatment may be performed only on the first surface. In some embodiments, the grinding treatment may also be performed using any other feasible grinding method, which is not limited in the present disclosure.

In some embodiments, after the grinding treatment, an angle deviation between an actual angle and a preset angle is less than 1°, and the flatness is less than 0.05 mm. The actual angle refers to an angle between the first surface and/or the second surface and a preset surface. In some embodiments, after the grinding treatment, an angle deviation between a fourth angle and a fourth preset angle is less than 0.5°, and the flatness is less than 0.05 mm. The fourth angle refers to an actual angle between the first surface and/or the second surface and a fourth preset surface. The fourth preset angle refers to an angle value expected to be achieved between the first surface and/or the second surface and the fourth preset surface. In some embodiments, the fourth preset surface may be a side surface adjacent to the first surface and/or the second surface. In some embodiments, the first surface and the second surface may serve as each other's fourth preset surface, i.e., the second surface may be the fourth preset surface corresponding to the first surface, and the first surface may be the fourth preset surface corresponding to the second surface. The fourth preset angle is similar to the first preset angle and the second preset angle. More descriptions may be found in the related descriptions above.

In some embodiments, a single-sided wet polishing method may be used to perform the polishing treatment on the first surface and the second surface of the initial crystal array, or only on the first surface. In some embodiments, the polishing treatment may also be performed using any other feasible polishing method, which is not limited in the present disclosure. In some embodiments, after the polishing treatment, an angle deviation of the first surface and/or the second surface is less than 0.5°, and the surface roughness Ra of the first surface and/or the second surface is less than 0.1 μm. In some embodiments, after the polishing treatment, the angle deviation of the first surface and/or the second surface is less than 1°, the finish grade of the first surface after the polishing treatment is not greater than T3, and the finish grade of the second surface after the polishing treatment is not greater than T3-H. In some embodiments, after the polishing treatment, the height difference between concave points and convex points in the first surface and/or the second surface is not greater than 0.08 μm.

In some embodiments, the dry grinding method may first be used for the grinding treatment, and the single-sided wet polishing method may then be used for the polishing treatment.

During assembling, the end surfaces of the target crystals may be misaligned, causing unevenness of the end surfaces of the initial crystal array and an excessively large angle deviation between the end surfaces and the side surfaces. By re-grinding and polishing the light-exiting surface of the initial crystal array and a surface opposite to the light-exiting surface, the flatness and height deviation of the end surfaces of the initial crystal array may be effectively adjusted.

In some embodiments, the reflective filling material may be uniformly coated on the other side surfaces of the initial crystal array, to form the reflective layer wrapping the other side surfaces of the initial crystal array. In some embodiments, after coating is completed, the reflective layer may be subjected to operations such as standing and drying, grinding, and passing through a right-angle tool. In some embodiments, by uniformly coating the reflective filling material, flatness of the reflective layer may be less than a preset flatness threshold. In some embodiments, the preset flatness threshold may be in a range of 0.001 μm to 0.5 mm. In some embodiments, the preset flatness threshold may be in a range of 0.001 μm to 0.3 mm. In some embodiments, the preset flatness threshold may be in a range of 0.001 μm to 0.2 mm. In some embodiments, the preset flatness threshold may be in a range of 0.2001 mm to 0.5 mm. In some embodiments, the preset flatness threshold may be in a range of 0.2001 mm to 0.3 mm. In some embodiments, the preset flatness threshold may be in a range of 0.3001 mm to 0.5 mm. In some embodiments, the preset flatness threshold may be 0.5 mm, 0.4 mm, 0.3 mm, 0.2 mm, 0.1 mm, etc. Passing through a right-angle tool may refer to processing the reflective layer using a right-angle tool for right-angle machining or the like. Exemplary right-angle tools include, but are not limited to, a vise, a right-angle stop block, or the like.

In some embodiments, a thickness of the reflective layer is in a range of 0.01 mm to 2 mm. In some embodiments, the thickness of the reflective layer is in a range of 0.01 mm to 1.5 mm. In some embodiments, the thickness of the reflective layer is in a range of 0.01 mm to 1 mm. In some embodiments, the thickness of the reflective layer is in a range of 0.01 mm to 0.5 mm. In some embodiments, the thickness of the reflective layer is in a range of 0.1 mm to 2 mm. In some embodiments, the thickness of the reflective layer is in a range of 0.1 mm to 1.5 mm. In some embodiments, the thickness of the reflective layer is in a range of 0.1 mm to 1 mm. In some embodiments, the thickness of the reflective layer is in a range of 0.1 mm to 0.5 mm. In some embodiments, the thickness of the reflective layer is in a range of 0.5 mm to 2 mm. In some embodiments, the thickness of the reflective layer is in a range of 0.5 mm to 1.5 mm. In some embodiments, the thickness of the reflective layer is in a range of 0.5 mm to 1 mm.

In some embodiments, at least one protective layer may be wrapped around side surfaces of the initial crystal array other than the light-exiting surface, to obtain the crystal array. For example, when the first surface and the second surface are both the light-exiting surfaces, at least one protective layer may be wrapped around the other side surfaces, to obtain the crystal array. As another example, when the light-exiting surface includes only the first surface, at least one protective layer may be wrapped around the second surface and the other side surfaces, to obtain the crystal array. In some embodiments, the protective layer may be aluminum foil. The absorptivity of aluminum is low, and the aluminum foil may ensure that the crystal array has a lower absorptivity and may also ensure that the crystal array is not deformed. In some embodiments, the protective layer may also be any other feasible material, which is not limited herein.

It should be noted that, during the entire assembling and machining process, no foreign matter contamination visible to naked eyes is allowed to occur, and each item needs to be checked, wiped, and confirmed before use.

In some embodiments of the present disclosure, according to indexes such as the optical output performance, decay time, and energy resolution of crystals, the one or more initial crystals satisfying index conditions are preliminarily screened out, such that optical output uniformity, energy resolution consistency, and decay time consistency of single crystals in one array are improved, which helps ensure excellent performance of the target array constituting the crystal array, and ensures that a deviation between a peak position of a standard array model and a peak position value of a single crystal at a corresponding position is smaller; and the crystal array is obtained by the bonding and assembling the preprocessed the one or more initial crystals, such that preparation difficulty of the crystal array can be effectively reduced, a production cycle can be shortened, and production efficiency can be improved. Furthermore, by preprocessing such as the cutting treatment, the grinding treatment, and the polishing treatment on the one or more initial crystals, a plurality of target crystals having smooth surfaces, smaller surface roughness, and smaller angle deviations may be obtained, thereby improving a utilization rate of crystals and preparing for subsequent array arrangement, to improve a qualification rate and resolution of the crystal array. Using the reflective structure prepared from barium compounds and/or the titanium compounds to assemble the plurality of target crystals into the crystal array can optimize light reflection between the target crystals, reduce a degree of unevenness of the optical output performance and the misalignment distance of seam lines, form the crystal array having high strength and being not prone to cracking, effectively improve a yield rate of the crystal array, and ensure the optical output performance of the crystal array. According to the particular bonding and assembling manner, a packaging structure of the crystal array may be optimized, generation of bubbles may be avoided, friction and displacement of crystal strips during curing of the glue may be avoided, assembly efficiency of the crystal array may be improved, and the crystal array having a compact structure, no light leakage, and no optical crosstalk may be ensured.

In some embodiments, optical output performance 510 of a plurality of target crystals may be detected; and arrangement positions 540 of the plurality of target crystals may be determined based on the optical output performance 510. The operation of determining the arrangement positions 540 of the plurality of target crystals may be performed by the operator, or may be automatically performed by equipment.

In some embodiments, the optical output performance of the target crystals includes the light yield and the relative light yield difference.

In some embodiments, performance of the target crystals may further include a refractive index, a reflectivity, an emission range, a decay time, an energy resolution, an emission wavelength, an anti-damage energy, or the like.

In some embodiments, the optical output performance of the target crystals may be detected by a detection instrument. Exemplary detection instruments include, but are not limited to, a spectrometer, a spectrophotometer, or a plug-in energy spectrum analyzer.

The arrangement position refers to a position where a target crystal is disposed in the crystal array. For example, the arrangement position of a target crystal may correspond to a position of the target crystal in a row of the crystal array.

The arrangement positions may be determined in various ways. In some embodiments, the plurality of target crystals in the crystal combination constituting the crystal array may be randomly arranged and combined, to obtain the arrangement positions of the plurality of target crystals. In some embodiments, the plurality of target crystals in the crystal combination having consistent performance or smaller performance deviations may be placed at one crystal row, and the plurality of crystal rows may be randomly arranged and combined, to obtain the arrangement positions of the plurality of target crystals.

In some embodiments, a result of the random arrangement and combination may be determined as the initial arrangement position, and the initial arrangement position is adjusted based on the optical output performance of the target crystal, to determine a final arrangement position.

In some embodiments, a light yield of any target crystal within an edge region of the crystal array is equal to or higher than an average light yield of the target crystals within an interior region. Accordingly, the target crystals having higher light yields may be disposed at the arrangement positions corresponding to the edge region of the crystal array. For example, the target crystals having higher light yields in the interior region may be exchanged with target crystals having lower light yields in the edge region. The edge region refers to a region of outermost target crystals in the crystal array. The interior region refers to a region of the crystal array other than the edge region.

In some embodiments of the present disclosure, by disposing the target crystals having higher light yields within the edge region of the crystal array, the target crystals having better the optical output performance may be placed at an outermost periphery of the crystal array, thereby effectively avoiding edge light leakage and reducing an impact on overall performance of the crystal array.

In some embodiments, on the basis of the initial arrangement position, the target crystals having close optical output performance may be placed at adjacent positions, to obtain the final arrangement position. The adjacent positions may be adjacent row positions and/or adjacent column positions. By placing the target crystals having close optical output performance at adjacent positions, optical output consistency of the crystal array may be effectively ensured.

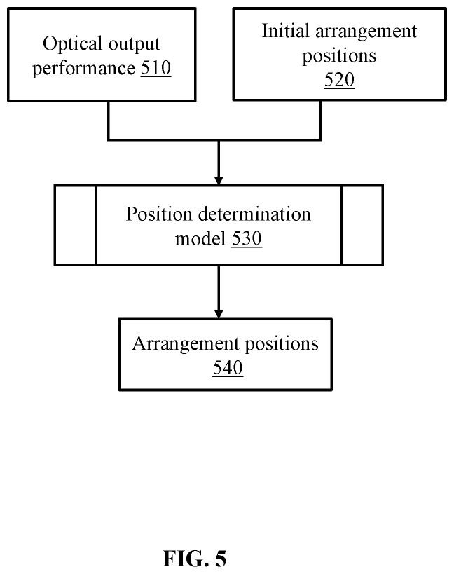

FIG. 5 is a schematic diagram illustrating an exemplary process for determining a crystal arrangement position according to some embodiments of the present disclosure.

Referring to FIG. 5, in some embodiments, initial arrangement positions 520 of a plurality of target crystals may be determined; and arrangement positions 540 may be determined through a position determination model 530 based on the initial arrangement positions 520 and the optical output performance 510. The operation of determining the arrangement positions based on the initial arrangement positions and the optical output performance may be performed by equipment (e.g., equipment for assisting arrangement of crystals).

The initial arrangement position refers to a preliminarily determined arrangement position of a target crystal. In some embodiments, a plurality of random arrangements and combinations may be performed on the plurality of target crystals in the crystal combination, to obtain a plurality of initial arrangement positions. In some embodiments, after the plurality of target crystals in the crystal combination are randomly arranged and combined, positions of a portion of the target crystals may be exchanged, to obtain a plurality of initial arrangement positions.

The position determination model may be configured to determine the arrangement positions of the plurality of target crystals constituting the crystal array. In some embodiments, the position determination model may be a machine learning model. In some embodiments, the position determination model may include any one or a combination of various feasible models such as a recurrent neural network (RNN) model, a deep neural network (DNN) model, a convolutional neural network (CNN) model, or the like.

In some embodiments, input of the position determination model may include the optical output performance and the initial arrangement positions of the plurality of target crystals in the crystal combination, and output of the position determination model is the arrangement positions of the plurality of target crystals.

In some embodiments, a plurality of first training samples with first labels may be used for training the position determination model through various manners, so as to update model parameters and then obtain a trained position determination model. For example, the training may be performed based on gradient descent. Merely by way of example, the plurality of first training samples with first labels may be input into an initial position determination model, a loss function is constructed based on the first labels and results of the initial position determination model, and parameters of the initial position determination model are iteratively updated based on the loss function. When the loss function of the initial position determination model satisfies a preset condition, model training is completed, and the trained position determination model is obtained. The preset condition may be that the loss function converges, an iteration count reaches a threshold, or the like.

In some embodiments, the first training samples may include optical output performance and initial arrangement positions of a plurality of target crystals in a sample crystal combination, and the first labels are arrangement positions of the plurality of target crystals in the sample crystal combination. In some embodiments, the first training samples may be obtained based on historical data. The first labels corresponding to the first training samples may be obtained through manual annotation.

In some embodiments of the present disclosure, by determining the arrangement positions of the plurality of target crystals constituting the crystal array, a utilization rate of crystals and a qualification rate of the crystal array may be effectively improved; and by processing the optical output performance and the initial arrangement position of the plurality of target crystals through the position determination model, a self-learning capability of the machine learning model may be utilized to find patterns from a large amount of data, obtain an association relationship among the optical output performance, the initial arrangement positions, and the arrangement positions, improve accuracy and efficiency of determining the arrangement positions, and ensure that edge pixel points in one array are clearer and positions of the pixel points are more uniform.

The following takes bonding and assembling of crystal strips having a dimension of 3.15×3.15×20 as an example for exemplary illustration. The bonding and assembling includes following operations.

Operation 1, partitioning and tray arrangement: performance of the crystal strips is detected by a performance inspection workshop, and partitioning and tray arrangement is performed according to performance intervals. Crystal performance data from the tray arrangement is read, placement positions of the crystal strips are simulated, array performance parameters are predicted, and an optimal arrangement position and a unique array identification number of each crystal strip (e.g., a code indicating the position of the crystal strip in the crystal array) are output.

Operation 2, bonding and assembling: assembling is started by assemblers according to the arrangement positions. The reflective filling material is applied on one or two crystal strips of the 1×1 crystal strips on the same side surface, standing and drying is performed for 15 seconds, and then the two crystal strips are bonded, gently extruded, and the dimension is measured until the appearance dimension of the 1×2 array satisfies 30.5×6.8×20. The reflective filling material is applied on a large surface of the 1×2 array, and the 2×2 array is assembled. The remaining 1×2 arrays are continuously assembled into 2×2 arrays. The 4×4 array, . . . , and the N×N array are assembled in the same manner, to obtain the initial crystal array. During assembling, attention is paid to the flatness of upper and lower end surfaces, and the height difference is less than 0.2 mm. One or more N×N arrays are continuously completed in the foregoing manner.

Operation 3, grinding treatment: the dry grinding method is used to grind the light-exiting surface of the initial crystal array and a surface opposite to the light-exiting surface, an angle deviation between an actual angle between the light-exiting surface and the surface opposite to the light-exiting surface and a corresponding preset angle is less than 0.6°, flatness of the end surfaces is less than 0.05 mm, and an overall height of the crystal array is 20 mm.

Operation 4, polishing treatment: the single-sided wet polishing method is used to polish the light-exiting surface of the initial crystal array and the surface opposite to the light-exiting surface. The surface roughness Ra of the light-exiting surface is not greater than 0.08 μm, the surface roughness Ra of the surface opposite to the light-exiting surface is not greater than 2 μm, and the angle deviation between the actual angle between the light-exiting surface and the surface opposite to the light-exiting surface and the corresponding preset angle is less than 0.5°.

apped around an outer periphery of the crystal array other than the light-exiting surface, and assembly of the crystal array is completed.

Operation 7, performance rechecking: actual detected data of the crystal array (e.g., the optical output performance, the finish grade of the light-exiting surface, or the like) and standard data are obtained and compared, and the compared data are stored in a robot system for analysis.

In the foregoing embodiments, the optical operation 5, peripheral packaging: other side surfaces are coated with the reflective filling material other than the light-exiting surface, to form the reflective layer wrapping the other side surfaces of the initial crystal array, the reflective layer is polished with 1000-grit to 2500-grit sandpaper after standing and drying, and passes through the right-angle tool. The peripheral packaging wrapping layer is to be uniform, a thickness of the peripheral packaging wrapping layer is not greater than 5 mm, and flatness of the peripheral packaging wrapping layer is less than 0.5 mm.

Operation 6, protective layer wrapping: one layer of aluminum foil is wrutput performance of the crystal array obtained by assembling the crystal strips is greater than 23000 Ph/MeV, the relative light yield difference of each crystal strip in the crystal array under the same condition is not greater than 3600 Ph/MeV, the array assembly efficiency is improved by 20%, and the array yield rate is improved by 15%. Embodiments of the present disclosure are not limited by the above embodiments. Any other changes, modifications, substitutions, combinations, and simplifications made without departing from the spirit, essence, and principle of the present disclosure shall be regarded as equivalent replacements and shall fall within the protection scope of the present disclosure.

In some embodiments, the relevant information of the one or more initial crystals includes an initial optical output value and a target optical output value of the one or more initial crystals, and the processing scheme includes an optical adjustment scheme for adjusting an optical output value of the one or more initial crystals. Correspondingly, determining the processing scheme for the one or more initial crystals based on the relevant information of the one or more initial crystals may include: determining the optical adjustment scheme for the one or more initial crystals based on the initial optical output value and the target optical output value of the one or more initial crystals.

Related descriptions regarding adjusting the optical output value of the one or more initial crystals will be described below.

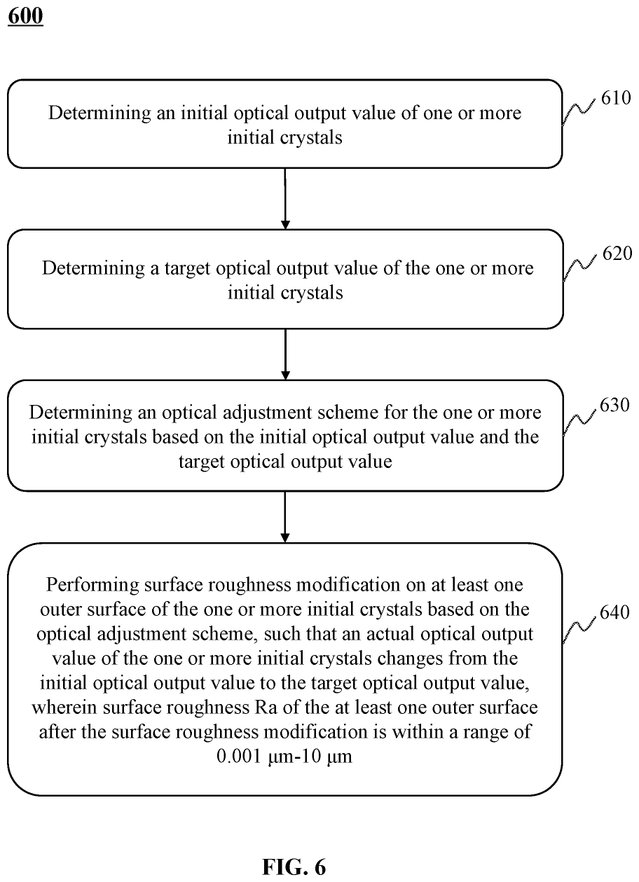

FIG. 6 is a flowchart illustrating an exemplary process for optical output regulation of a crystal according to some embodiments of the present disclosure.

In some embodiments, one or more operations in a process 600 may be performed by an operator, or may be performed by machining equipment for crystal production and processing (e.g., a grinder, a polishing machine, or the like), crystal performance inspection equipment, or the like. As shown in FIG. 6, the process 600 includes the following operations.

In 610, an initial optical output value of one or more initial crystals is determined.

The one or more initial crystals may include original crystals prepared by crystal growth equipment. For example, the one or more initial crystals may be crystals obtained after cutting treatment is performed on the original crystals prepared by the crystal growth equipment. The original crystals refer to crystal ingots grown in the crystal growth equipment, or other shaped crystal raw materials.

The one or more initial crystals are the scintillator crystals. For example, the one or more initial crystals may be one or a combination of cerium bromide crystals, cerium-doped lanthanum bromide crystals, cerium-doped lanthanum chloride crystals, bismuth germanate (BGO) crystals, copper bromide crystals, sodium iodide crystals, cesium iodide crystals, perovskite (CsPbBr3) crystals, silicate scintillator crystals, garnet scintillator crystals, or the like. As another example, the one or more initial crystals may include at least two of elements such as Lu (lutetium), Si (silicon), Y (yttrium), Ca (calcium), Mg (magnesium), Al (aluminum), Ga (gallium), Sc (scandium), In (indium), La (lanthanum), Br (bromine), Ba (barium), S (sulfur), Sn (tin), Zn (zinc), Zr (zirconium), Hf (hafnium), Cd (cadmium), Pb (lead), Eu (europium), Ce (cerium), Bi (bismuth), Ge (germanium), I (iodine), Na (sodium), Cs (cesium), or Cu (copper). That is, the one or more initial crystals are scintillator crystals including at least two of Lu, Si, Y, Ca, Mg, Al, Ga, Sc, In, La, Br, Ba, S, Sn, Zn, Zr, Hf, Cd, Pb, Eu, Ce, Bi, Ge, I, Na, Cs, or Cu.

In some embodiments, before the cutting treatment is performed on the original crystals, quality inspection may first be performed on the original crystals, and the cutting treatment is performed on original crystals satisfying a quality inspection. In some embodiments, the quality inspection includes sampling inspection or full inspection on performance. Merely by way of example, a quality inspection standard for performance may include that the optical output value is greater than 1500 channels.

The inventors have found that, when the original crystals are prepared, by doping the crystals with trivalent Ce element (i.e., Ce³⁺) and/or tetravalent Ce element (i.e., Ce⁴⁺), the optical output value of the original crystals may be adjusted, thereby adjusting the optical output value of the one or more initial crystals. For example, when the original crystals are prepared, the optical output value of the original crystals may be adjusted by adjusting contents of Ce³⁺ and/or Ce⁴⁺ doped in the crystals. Understandably, a luminescence center in the crystals is Ce³⁺. If a doping concentration of Ce³⁺ is excessively low, a concentration of activated ions may be excessively low, a count of luminescence centers may be relatively small, and luminescence intensity may be relatively low. If the doping concentration of Ce³⁺ is excessively high, concentration quenching or the like may be caused, thereby reducing luminescence efficiency. Therefore, in some embodiments of the present disclosure, the doping concentration of Ce³⁺ and/or Ce⁴⁺ may be properly controlled to obtain an optimal luminescence effect.

Taking LYSO crystals as an example, an important physical parameter of LYSO is the light yield (i.e., an optical output value). The light yield has a direct relationship with contents of Ce³⁺ ions and Ce⁴⁺ ions doped in LYSO. An analysis is as follows: when radiation enters a crystal, energy is lost to excite electron transition, and then electrons transition from a conduction band or an excitation band to a valence band, such that de-excitation occurs and photons are emitted. When radiation enters a LYSO crystal, another non-radiative de-excitation process also exists, and de-excitation occurs through emission of phonons. Because a pure crystal (i.e., a crystal not doped with other elements) generally has relatively low self-absorption luminescence efficiency, one or more activators (e.g., Ce³⁺ ions and Ce⁴⁺ ions) need to be doped, such that the one or more activators become luminescence centers, thereby effectively preventing self-absorption and improving luminescence efficiency. The electron-hole pairs generated by ionizing radiation release energy in two manners.

Manner one, a self-trapped exciton (STE) is formed, energy is then transferred to the perturbed

$${Ce}_{per}^{3 +} ,$$

and de-excitation occurs to emit photons at 340 nm. The process is as follows:

$${Ce}^{3 +} + e \to {Ce}^{2 +}$$

$$2 {F}^{-} + h \to {( {F}_{2} )}^{-}$$

$${Ce}^{2 +} + {( {F}_{2} )}^{-} \to STE \to ( {Ce}_{per}^{3 +} ) \to {Ce}_{per}^{3 +} + hv ( 340 nm )$$

where e is an electron, h is a hole, F⁻ is an ion, Traps are photon trapping centers in the crystal, and

$${( {Ce}_{per}^{3 +} )}^{*}$$

is an excited state of

$${Ce}_{per}^{3 +} .$$

Manner two, a Ce-trapped exciton CeTE is formed, i.e., an excited state (Ce3+)*P1 of Ce³⁺ at a normal lattice site, de-exciting to emit scintillation photons at 300 nm (286 nm and 305 nm). The process is as follows:

$${Ce}^{3 +} + e + h \to Ce TE \to {Ce}^{3 +} + h ν ( 286 nm , 305 nm )$$

where e is an electron, h is a hole, and CeTE is an excited state of the Ce-trapped exciton.

The foregoing manners in which the electron-hole pairs generated by ionizing radiation release energy indicate that the content of Ce³⁺ doped in the crystal affects the optical output value of the crystal.

In a LYSO crystal, the luminescence behavior may be divided into a line spectrum of an fn configuration and a broadband spectrum of an f→d transition. A transition within a 4fn configuration is a result of odd-term perturbation of crystal field action. When Ce is excited by external light, after an electron in a ground state transitions to an excited state, during the de-excitation process, a portion of energy is released in a form of photons, a portion of energy is transferred to surrounding crystal lattice vibration in a form of heat energy without emitting light, and a portion of energy is in a metastable state of the excited state. Furthermore, the inventors have found that introduction of Ce⁴⁺ ions causes electrons on the conduction band to be more easily captured by the Ce⁴⁺ ions, energy quenching caused by crystal lattice defects or other impurities in energy level splitting of Ce³⁺ ions in the matrix due to crystal field action may be transferred through the Ce⁴⁺ ions to electrons of Ce³⁺ in an excited metastable state, such that photons are released while excited-state Ce³⁺ is formed, and finally metastable-state Ce³⁺ is combined with holes on the valence band and returns to ground-state Ce⁴⁺, thereby completing one fluorescence process. The ground-state Ce³⁺ captures holes to form transient-state Ce⁴⁺, then electrons on the conduction band are combined to form excited-state Ce³⁺, and the excited-state Ce³⁺ returns to the ground state through radiating photons, thereby completing one fluorescence process. Compared with the Ce³⁺ ions, the Ce⁴⁺ ions may capture electrons and radiate photons more quickly, thereby reducing a probability of electron trap capture. The process for capturing holes is a non-radiative process, which does not cause an afterglow phenomenon of the scintillator crystal, such that the optical output of the crystal may be effectively improved, decay time may be shortened, and afterglow may be weakened.

In some embodiments, during preparation of the raw crystals, elements such as Ca/Mg/Sn/Cl may further be doped in the crystals, to reduce afterglow of the crystals and reduce the decay time.

The inventors have found through numerous experiments (i.e., verification experiments in which adjustment of the surface roughness of the crystals causes changes in the optical output value of the crystals) that the optical output value of the crystals may also be related to factors such as the surface roughness of the crystals. In some embodiments, the optical output value of the crystals is positively correlated with the surface roughness of the crystals, that is, the rougher the surface of the crystal (i.e., the greater the surface roughness), the greater the optical output value of the crystal. For example, after all surfaces of the crystals are polished, the optical output of the crystals is reduced, and the decay time is also increased. This is because when surfaces of the crystals are very smooth, the surfaces of the crystals are equivalent to a plane mirror, photons escape through the surfaces, thereby reducing a count of photons emitted from the interior of the crystals and causing brightness to decrease. Meanwhile, the photons reflected back may reach the end surfaces of the crystals and be received by the photoelectric device only after undergoing numerous reflections inside the crystals, the light path becomes longer, and thus the light decay time of the crystals becomes longer. As another example, when the surfaces of the crystals have different concave points and convex points, when light is transmitted to the surfaces of the crystals, more photons are reflected back to the crystals by the concave points and the convex points at different angles, and a photoelectric conversion device on the light-exiting surfaces of the crystals receives more photons within the same time, that is, the optical output value of the crystals increases. Furthermore, because surfaces of the crystals have concave points and convex points of different degrees, light scattering increases and the scattering angle is larger, and surface scattering may introduce additional photon paths, prolong propagation time of photons inside the crystals, thereby increasing the decay time, causing time for the photons to be emitted from the end surfaces of the crystals to become shorter, and thus causing the optical output to decrease. For the same crystal under different surface roughness conditions, a difference range of optical output changes in a range of 10 channels to 300 channels, and a difference of decay time changes in a range of 1 picosecond to 8 picoseconds. That is, the change in the surface roughness of the crystals affects propagation and escape of photons inside the crystals, and further affects changes in the optical output and the decay time.

In verification experiments in which adjustment of the surface roughness of the crystals causes the change in optical output value, 10 crystal strips are selected. Dimensions of the 10 crystal strips are close, and the surface roughness of the light-exiting surface is not greater than 0.03 μm. In the verification experiments, by performing machining operations for modifying the surface roughness (also referred to as surface roughness modification) of the crystals three times, and measuring optical output values and decay time of the crystals after each change of the surface roughness of the crystals, experimental data shown in Tables 1-5 below are obtained. Table 1 includes measurement data of average surface roughness of the 10 crystal strips before machining (i.e., an average of surface roughness of various surfaces), an optical output value, and a decay time. Table 2 includes measurement data of average surface roughness, an optical output value, and a decay time of the 10 crystal strips after a first surface roughness change, and measurement data of an optical output difference and a decay time difference before and after the first surface roughness change. Table 3 includes measurement data of average surface roughness, an average optical output value, and an average decay time of the 10 crystal strips after a second surface roughness change, and measurement data of an optical output difference and a decay time difference before and after the second surface roughness change. Table 4 includes measurement data of average surface roughness, an average optical output value, and an average decay time of the 10 crystal strips after a third surface roughness change, and measurement data of an optical output difference and a decay time difference before and after the third surface roughness change. Table 5 includes measurement data of average surface roughness, an average optical output value, and an average decay time of the 10 crystal strips before machining, after the first surface roughness change, after the second surface roughness change, and after the third surface roughness change, and measurement data of an optical output difference and a decay time difference before and after each surface roughness change.

TABLE 1

| | Length * | Average | | Optical |
|---|---|---|---|---|
| | Width * Height | Surface | Decay | Output |
| | of Crystal | Roughness | Time | Value |
| No. | (Unit: mm) | (Unit: μm) | (Unit: ns) | (Unit: Channel) |
| 1 | 3.956*5.294*24 | 0.041 | 41.3 | 1824 |
| 2 | 3.957*5.293*24 | 0.030 | 40.6 | 1841 |
| 3 | 3.957*5.297*24 | 0.031 | 40.5 | 1823 |
| 4 | 3.957*5.297*24 | 0.040 | 40.1 | 1833 |
| 5 | 3.955*5.297*24 | 0.031 | 40.5 | 1829 |
| 6 | 3.956*5.294*24 | 0.037 | 40.4 | 1820 |
| 7 | 3.955*5.297*24 | 0.027 | 40.9 | 1819 |
| 8 | 3.956*5.294*24 | 0.026 | 41.5 | 1845 |
| 9 | 3.956*5.294*24 | 0.031 | 39.6 | 1841 |
| 10 | 3.957*5.293*24 | 0.027 | 41.4 | 1802 |

TABLE 2

| | | | | | Optical | Optical |
|---|---|---|---|---|---|---|
| | | Average | | | Output | Output |
| | | Surface | Decay | Decay Time | Value | Difference |
| | Length*Width*Height | Roughness | Time | Difference | (Unit: | (Unit: |
| No. | of Crystal (Unit: mm) | (Unit: μm) | (Unit: ns) | (Unit: ns) | Channel) | Channel) |
| 1 | 3.945*5.283*24 | 0.073 | 36.6 | 4.7 | 2117 | 293 |
| 2 | 3.947*5.283*24 | 0.079 | 26.5 | 4.1 | 2093 | 252 |
| 3 | 3.946*5.283*24 | 0.087 | 36.3 | 4.2 | 2100 | 277 |
| 4 | 3.946*5.283*24 | 0.070 | 35.8 | 4.3 | 2095 | 262 |
| 5 | 3.945*5.283*24 | 0.070 | 36.2 | 4.3 | 2088 | 259 |
| 6 | 3.947*5.285*24 | 0.077 | 36.0 | 4.4 | 2161 | 341 |
| 7 | 3.947*5.285*24 | 0.074 | 36.1 | 4.8 | 2126 | 307 |
| 8 | 3.946*5.283*24 | 0.074 | 36.7 | 4.9 | 2162 | 317 |
| 9 | 3.948*5.285*24 | 0.088 | 36.0 | 3.5 | 2104 | 263 |
| 10 | 3.947*5.286*24 | 0.083 | 36.7 | 4.7 | 2098 | 296 |

TABLE 3

| | | | | | Optical | Optical |
|---|---|---|---|---|---|---|
| | | Average | | | Output | Output |
| | | Surface | Decay | Decay Time | Value | Difference |
| | Length*Width*Height | Roughness | Time | Difference | (Unit: | (Unit: |
| No. | of Crystal (Unit: mm) | (Unit: μm) | (Unit: ns) | (Unit: ns) | Channel) | Channel) |
| 1 | 3.944*5.283*24 | 0.051 | 37.2 | 4.1 | 2021 | 197 |
| 2 | 3.945*5.282*24 | 0.046 | 36.9 | 3.7 | 1987 | 146 |
| 3 | 3.944*5.280*24 | 0.052 | 36.5 | 4.0 | 1961 | 138 |
| 4 | 3.943*5.280*24 | 0.046 | 36.9 | 3.2 | 1922 | 89 |
| 5 | 3.944*5.281*24 | 0.046 | 37.8 | 2.7 | 1975 | 146 |
| 6 | 3.945*5.281*24 | 0.050 | 37.9 | 2.5 | 1991 | 171 |
| 7 | 3.945*5.282*24 | 0.050 | 36.7 | 4.2 | 1996 | 177 |
| 8 | 3.944*5.281*24 | 0.049 | 36.9 | 4.7 | 2047 | 202 |
| 9 | 3.945*5.281*24 | 0.042 | 38.4 | 1.2 | 2043 | 202 |
| 10 | 3.944*5.282*24 | 0.056 | 36.9 | 4.5 | 2023 | 221 |

TABLE 4

| | | | | | Optical | Optical |
|---|---|---|---|---|---|---|
| | | Average | | | Output | Output |
| | | Surface | Decay | Decay Time | Value | Difference |
| | Length*Width*Height | Roughness | Time | Difference | (Unit: | (Unit: |
| No. | of Crystal (Unit: mm) | (Unit: μm) | (Unit: ns) | (Unit: ns) | Channel) | Channel) |
| 1 | 3.944*5.280*24 | 0.048 | 38.0 | 3.3 | 1993 | 169 |
| 2 | 3.943*5.279*24 | 0.042 | 37.6 | 3.0 | 1984 | 143 |
| 3 | 3.942*5.278*24 | 0.038 | 37.4 | 3.1 | 1929 | 106 |
| 4 | 3.941*5.277*24 | 0.040 | 37.3 | 2.9 | 1905 | 72 |
| 5 | 3.942*5.278*24 | 0.040 | 38.3 | 2.3 | 1952 | 123 |
| 6 | 3.944*5.278*24 | 0.040 | 38.5 | 1.9 | 1954 | 134 |
| 7 | 3.943*5.279*24 | 0.042 | 37.2 | 3.7 | 1948 | 129 |
| 8 | 3.943*5.279*24 | 0.046 | 37.6 | 4.0 | 1984 | 139 |
| 9 | 3.944*5.279*24 | 0.041 | 39.1 | 0.5 | 2002 | 161 |
| 10 | 3.943*5.279*24 | 0.052 | 37.6 | 3.7 | 1964 | 162 |

TABLE 5

| | | | | | Average | Average |
|---|---|---|---|---|---|---|
| | Average Length* | | | | Optical | Optical |
| | Average Width* | Average | Average | Average | Output | Output |
| | Average Height of | Surface | Decay | Decay Time | Value | Difference |
| | Crystals | Roughness | Time | Difference | (Unit: | (Unit: |
| No. | (Unit: mm) | (Unit: μm) | (Unit: ns) | (Unit: ns) | channel) | channel) |
| Before | 3.956*5.295*24 | 0.032 | 40.681 | | 1827.700 | |
| Processing | | | | | | |
| First | 3.946*5.284*24 | 0.078 | 36.297 | −4.384 | 2114.400 | 286.700 |
| Surface | | | | | | |
| Roughness | | | | | | |
| Change | | | | | | |
| Second | 3.944*5.281*24 | 0.049 | 37.202 | −3.479 | 1996.600 | 168.900 |
| Surface | | | | | | |
| Roughness | | | | | | |
| Change | | | | | | |
| Third | 3.943*5.279*24 | 0.043 | 37.846 | −2.835 | 1961.500 | 133.800 |
| Surface | | | | | | |
| Roughness | | | | | | |
| Change | | | | | | |

It can be seen from the measurement data in Tables 1-5 that, when the surface roughness of the crystal strips increases, the optical output of the crystal strips becomes higher, and the decay time becomes lower.

In some embodiments, machining operation may be performed on the one or more initial crystals, to adjust the surface roughness of the one or more initial crystals, and further adjust the optical output value of the one or more initial crystals, thereby obtaining initial crystals having an optical output value satisfying requirements. The machining operation refers to a machining operation for modifying the surface roughness. More descriptions regarding the machining operation for modifying the surface roughness may be found in 640 and related descriptions thereof.

In some embodiments, the one or more initial crystals may be obtained by preprocessing the original crystals. The preprocessing refers to a processing operation for adjusting the dimension of the crystals. In some embodiments, the preprocessing may include the cutting treatment, the grinding treatment, the polishing treatment, or the like performed on the original crystals. It should be noted that the grinding treatment and the polishing treatment in a process of preprocessing the original crystals are performed to cause cut crystals (i.e., crystals obtained after the cutting treatment is performed on the original crystals) to achieve a desired dimension. It can be understood that, because cutting precision is relatively low, the dimensions of the cut crystals may be finely adjusted through the grinding treatment and the polishing treatment, thereby obtaining the desired dimension.

In some embodiments, the cutting treatment may be a processing operation for changing the shape, the dimension, or the like of the crystals. In some embodiments, the cutting treatment may include one or more of inner circular cutting, multi-wire cutting, and single-wire cutting.

In some embodiments, by performing the cutting treatment on the original crystals, crystal strips are obtained as the one or more initial crystals. A cross-sectional shape of each crystal strip perpendicular to a length direction of the crystal strip may be rectangular or square. In some embodiments, a dimension range of the crystal strip may be: length (0.2 mm-6 mm)×width (0.2 mm-6 mm)× height (3 mm-100 mm). In some embodiments, the dimension of the crystal strip may be 0.2*0.2*10 mm, 0.2*0.2*50 mm, 0.2*0.2*100 mm, 2*2*10 mm, 2*2*50 mm, 2*2*100 mm, 4*4*10 mm, 4*4*20 mm, 4*4*50 mm, 4*4*100 mm, etc., which may be set based on specific requirements and not limited herein.

It should be noted that the cross-sectional shape of the initial crystal obtained by the cutting treatment is described merely by way of example, and the cross-sectional shape may be other shapes. For example, the cross-sectional shape may be triangular, hexagonal, elliptical, or the like. The length direction may be an axial direction of the initial crystal or a direction having a maximum dimension among three orthogonal directions of the initial crystal.

In some embodiments, the grinding treatment may be a processing operation for performing finishing machining on the surface of the crystals by coating or press-embedding abrasive particles on a grinding tool and causing relative movement between the grinding tool and the crystals under a certain pressure. In some embodiments, the grinding treatment may include one or more of single-side grinding, double-side grinding, or the like.

In some embodiments, the polishing treatment may be a processing operation of processing surfaces of the one or more initial crystals using one or more of a mechanical manner, a chemical manner, or an electrochemical manner, such that the surface roughness of the one or more initial crystals is reduced, to obtain bright and flat surfaces.

In some embodiments, taking the crystal strip as the initial crystal as an example, the original crystals may be processed through the following Operations S1-S9, to obtain strip-shaped initial crystals.

In S1, a crystal rod is cut using a cutting machine, to obtain a plurality of crystal segments satisfying a height requirement. A height deviation between any two crystal segments in the plurality of crystal segments is not greater than 0.1 mm. In some embodiments, cutting precision of the cutting machine may be in a range of 0.03 mm to 1 mm. In some embodiments, when a height of a crystal segment does not satisfy the height requirement, the height of the crystal segments may be adjusted through the grinding treatment, such that the height satisfies the height requirement. In some embodiments, the height requirement may include: the height of the crystal segment being in a range of 3 mm to 100 mm.

In S2, the crystal segments are cut from a height direction of the crystal segments using the cutting machine, to obtain a plurality of crystal sheets satisfying a thickness requirement. A thickness deviation between any two crystal sheets in the plurality of crystal sheets is not greater than 0.1 mm. In some embodiments, when a thickness of a crystal sheet does not satisfy the thickness requirement, the thickness of the crystal sheet may be adjusted through the grinding treatment, such that the thickness satisfies the thickness requirement. In some embodiments, the thickness requirement may include: the thickness of the crystal sheet or bonded sheet being in a range of 0.2 mm to 6 mm.

Through the height requirement and thickness requirement, the crystal sheets having a width in a range of 0.2 mm to 6 mm and a height in a range of 3 mm to 100 mm are obtained.

The height requirement and the thickness requirement in the foregoing embodiments may be set based on actual production requirements, and the embodiments of the present disclosure are not limited thereto.

In some embodiments, a process of performing the grinding treatment on the crystal segment or the crystal sheet may include: the crystal segment or the crystal sheet is placed in a planetary wheel, such that the planetary wheel rotates together with a grinding disk. The grinding disk include an upper plate and a lower plate, with sand leakage grooves of 0.3 mm to 0.5 mm on plate surfaces, spaced at intervals of 10 mm to 50 mm. The upper plate and the lower plate are in a forward-reverse rotation relationship, and double-side grinding is performed on the crystal segment or the crystal sheet through reverse rotation of the upper plate and the lower plate. A grit number of the grinding sand, a grinding rotational speed, a grinding pressure, etc., may be determined based on experience. For example, the grinding sand is less than 500 mesh, the grinding rotational speed is less than 30 revolutions per minute, a positive grinding pressure is not greater than 0.08 MPa, and a reverse pressure is not greater than 0.15 MPa.

In some embodiments, during the grinding process, the height of the crystal segment or the thickness of the crystal sheet may be measured and recorded a plurality of times until the height of the crystal segment satisfies the height requirement or the thickness of the crystal sheet satisfies the thickness requirement. For example, the height of the crystal segment or the thickness of the crystal sheet may be measured and recorded once every 5 grinding cycles.

During the grinding process, it is necessary to observe whether the crystal segment or the crystal sheet has scratches. If scratches on the surfaces of the crystal segment or the crystal sheet are detected during the grinding process, the grinding equipment needs to be cleaned in time, and the abrasive needs to be replaced.

In some embodiments, after the grinding is completed, a plurality of crystal sheets having a thickness satisfying the thickness requirement may be used as preliminarily qualified crystal sheets, and subsequent processing operations (e.g., operation S3) are performed on the preliminarily qualified crystal sheets.

In some embodiments, after the grinding is completed, the surface roughness of each surface of the crystal sheet may further be measured, crystal sheets whose surface roughness of each surface is not greater than 1.5 μm are selected as the preliminarily qualified crystal sheets, and subsequent processing operations (e.g., operation S3) are performed on the preliminarily qualified crystal sheets.

In S3, large surfaces of the preliminarily qualified crystal sheets are subjected to the polishing treatment, to obtain crystal sheets satisfying a polishing requirement. The large surfaces refer to two opposite surfaces having the largest area on each crystal sheet.

In some embodiments, the polishing requirement may be that the surface roughness of the large surfaces of the crystal sheets is not greater than 1.5 μm. The polishing requirement in the foregoing embodiments may be set based on actual production requirements, and the embodiments of the present disclosure are not limited thereto.

In some embodiments, a polishing pad material may be determined according to polishing requirements of different materials and different precision requirements. The polishing pad material includes polyurethane, non-woven fabric, a composite material, epoxy resin, sulfonated polyisoprene, a rayon polishing pad, a wool textile polishing pad, a polyurethane resin polishing pad, etc. The selection of the material of the polishing pad may depend on specific requirements of a polishing process, such as physical characteristics including hardness, a compression ratio, a retention amount, the surface roughness, and density.

In some embodiments, a particle size of a polishing abrasive, a polishing rotational speed, a polishing pressure, or the like may be set based on experience. For example, the particle size of the polishing abrasive is less than 10 μm, the polishing rotational speed is less than 30 revolutions per minute, a positive polishing pressure is not greater than 0.08 MPa, and a reverse pressure is not greater than 0.15 MPa.

In some embodiments, if scratches on surfaces of the crystal sheets are detected during the polishing process, the equipment needs to be cleaned in time and the abrasive needs to be replaced.

In some embodiments, after the polishing is completed, the surface roughness of the large surfaces of the crystal sheets may further be measured, crystal sheets whose surface roughness of the large surfaces is not greater than 0.1 μm are selected as qualified crystal sheets, and subsequent processing operations (e.g., operation S4) are performed on the qualified crystal sheets.

In S4, a plurality of qualified crystal sheets are bonded using a glue, and the end surfaces of the plurality of qualified crystal sheets are aligned, to obtain a bonded block. During bonding, a count of the qualified crystal sheets is not less than 5, and protective media may be bonded to the large surfaces. The bonded block refers to a block-shaped crystal obtained by stacking and bonding the plurality of qualified crystal sheets along a thickness direction of the qualified crystal sheets.

In S5, the end surfaces of the bonded block are subjected to the grinding treatment and the polishing treatment. When the surface roughness of the end surfaces of the bonded block is less than 0.04 μm, a first intermediate product is obtained, and subsequent operations (e.g., operation S6) are entered. The end surfaces of the bonded block refer to planar surfaces at two ends of the bonded block along a length direction of the bonded block.

In S6, protective glass is bonded to the end surfaces of the first intermediate product, to obtain a second intermediate product.

In S7, the second intermediate product is cut along a length direction of the second intermediate product, to obtain a third intermediate product. The third intermediate product includes a plurality of crystal strips stacked and bonded together along a thickness direction or a length direction of the third intermediate product.

In S8, after the thickness of the third intermediate product satisfies the thickness requirement, the cutting surface is subjected to the grinding treatment, to obtain a fourth intermediate product. More descriptions regarding the thickness requirement may be found in the related descriptions above.

In S9, the fourth intermediate product is subjected to a glue-dissolving treatment, to obtain a plurality of crystal strips as the initial crystals.

In some embodiments, the initial crystals processed through operations S1-S9 may be used for assembling the crystal array. For example, the plurality of initial crystals having close optical output may be selected from a large quantity of initial crystals processed through operations S1-S9, for assembling the same crystal array.

In other embodiments, a machining operation may further be performed on the initial crystals processed through operations S1-S9, to adjust the optical output value of the initial crystals by changing the surface roughness of the initial crystals, and a plurality of further processed initial crystals are assembled into a crystal array. More descriptions regarding the embodiments may be found in the related descriptions below.

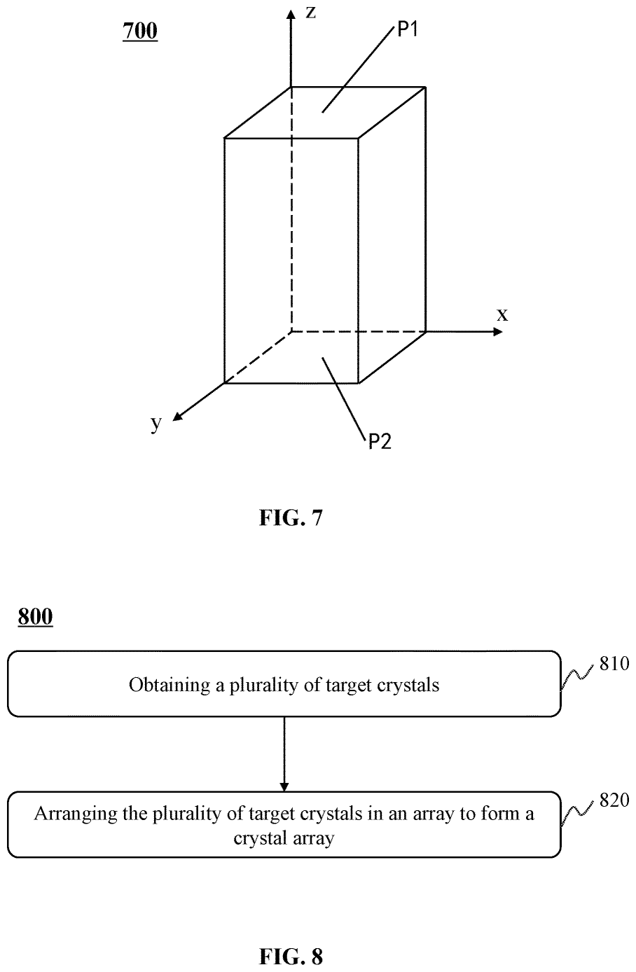

FIG. 7 is a schematic diagram illustrating an initial crystal according to some embodiments of the present disclosure.

In some embodiments, as shown in FIG. 7, outer surfaces of an initial crystal 700 include a first end surface P1 and a second end surface P2 disposed opposite to each other, and side surfaces located between the first end surface P1 and the second end surface P2. At least one of the first end surface P1 or the second end surface P2 is a light-exiting surface.

The end surface refers to a light-exiting surface of a crystal or a surface opposite to the light-exiting surface. Taking the crystal strip shown in FIG. 7 as an example, the end surfaces of the crystal strip may be planar surfaces at two ends of the crystal strip along a length direction. The length direction may be an axial direction of the crystal strip or a direction having a maximum dimension among three orthogonal directions of the crystal strip. For example, as shown in FIG. 7, the z direction is the axial direction of the initial crystal or the direction having a maximum dimension among three orthogonal directions of the initial crystal.

The light-exiting surface refers to a plane from which photons in the initial crystal are mainly emitted.

An initial optical output value refers to optical output performance of the initial crystal before machining operations related to optical output regulation are performed on the initial crystal. More descriptions regarding the “machining operations related to optical output regulation” may be found in 640 and related descriptions thereof.

In some embodiments, the initial optical output value of the initial crystal may be detected according to a measurement method in related industry standards. For example, in combination with “GAGG Crystal and Wafer Array Performance Measurement Method”, the initial optical output value may be measured using a full absorption peak technique and a Compton edge technique. The measurement principle includes: when monoenergetic y radiation is incident on a scintillation detector, an output pulse amplitude distribution main consists of spectral segments such as a Compton distribution and a full absorption peak (except for a scintillator having a low atomic number), and the full absorption peak technique and the Compton edge technique respectively use a full absorption peak amplitude or a Compton distribution edge amplitude as a metric for determining scintillator optical output.

In 620, a target optical output value of the one or more initial crystal is determined.

The target optical output value refers to an optical output value expected to be achieved by the initial crystal after machining operations related to optical output regulation are performed on the initial crystal.

The target optical output value may be determined in various ways. In some embodiments, the target optical output value may be determined based on prior knowledge or may be determined by manual input. For example, the target optical output value may be set and input manually based on actual production requirements. In some embodiments, the optical output value of the crystal may be measured by a full-energy peak area corresponding to channel data of the crystal. When high-energy particles such as X-rays (or y-rays) interact with the crystal, the high-energy particles deposit energy in the crystal, atoms of the crystal enter an excited state, and fluorescence photons are emitted during de-excitation. The fluorescence photons are converted into photoelectrons through a photoelectric device (e.g., a photoelectric effect is generated by the fluorescence photons at a photocathode of a photomultiplier tube (PMT), and the fluorescence photons are converted into photoelectrons), and pulse signals are formed after multiplication amplification and digital-to-analog conversion processing are performed through the photoelectric device. The channel is obtained by an analyzer converting the pulse signals into digits corresponding to amplitudes of the pulse signals.

In some embodiments, the target optical output value of the initial crystal may be determined according to related parameters of the crystal array constituted by the initial crystal. More descriptions regarding the embodiments may be found in the related descriptions below.

In 630, an optical adjustment scheme for the one or more initial crystals is determined based on the initial optical output value and the target optical output value.

The optical adjustment scheme is a scheme for adjusting the optical output value of the initial crystal from the initial optical output value to the target optical output value.

Because the optical output value of the crystal is related to the surface roughness of the crystal, the optical adjustment scheme may include target surface roughness of at least one outer surface of the initial crystal. The target surface roughness may be the surface roughness that causes the actual optical output value of the initial crystal to reach the target optical output value.

In some embodiments, the initial optical output value and the target optical output value of the initial crystal may be analyzed and processed, to determine the target surface roughness of at least one outer surface of the initial crystal. For example, the initial optical output value and the target optical output value of the initial crystal may be analyzed and processed according to a preset relationship table, to determine the target surface roughness of at least one outer surface of the initial crystal. Because the optical output value of the crystal is positively correlated with the surface roughness of the crystal, in some embodiments, in response to the target optical output value being greater than the initial optical output value, the optical adjustment scheme is determined to include performing a machining operation to increase surface roughness of the one or more side surfaces of the initial crystal; and in response to the target optical output value being less than the initial optical output value, the optical adjustment scheme is determined to include performing a machining operation to decrease the surface roughness of the one or more side surfaces of the initial crystal.

The at least one outer surface of the initial crystal may include the one or more side surfaces and the end surfaces. Correspondingly, the optical adjustment scheme may include machining surface roughness of each of the one or more side surfaces of the initial crystal to the target surface roughness for that the side surface. In some embodiments, the target surface roughness of the one or more side surfaces of the initial crystal may be determined based on the initial optical output value and the target optical output value.

In some embodiments, the target surface roughness for each of the one or more side surfaces of the initial crystal may be determined based on at least one of the target optical output value, the initial optical output value, the dimension, the composition, or initial surface roughness of each of the one or more side surfaces, of the initial crystal, and the surface roughness of each of the one or more side surfaces of the initial crystal is machined to the target surface roughness, such that an actual optical output value of the initial crystal changes from the initial optical output value to the target optical output value. The initial surface roughness and the target surface roughness of different side surfaces of the initial crystal may be the same or may be different.

The initial surface roughness refers to surface roughness corresponding to the side surfaces of the initial crystal before machining operations for optical output regulation are performed on the initial crystal. The initial surface roughness may be measured and obtained by a roughness tester, a profilometer, a laser interferometer, or the like.

In some embodiments, the target surface roughness of the side surfaces may be determined in various ways. For example, the target surface roughness for each side surface of the initial crystal may be determined by querying a preset table based on at least one of the target optical output value of the initial crystal, the initial optical output value of the initial crystal, the dimension of the initial crystal, the composition of the initial crystal, or the initial surface roughness of each side surface of the initial crystal. In some embodiments, the preset table includes a correspondence relationship between a combination of the target optical output value, the initial optical output value, the dimension, composition, and the initial surface roughness of a plurality of side surfaces of a reference crystal, and reference surface roughness corresponding to the plurality of side surfaces. The reference crystal may be a class of crystals having consistent composition and dimension. In some embodiments, the preset table may include correspondence relationships between combinations of the target optical output value, the initial optical output value, the dimension, the composition, the initial surface roughness of the plurality of side surfaces of a plurality of reference crystals, and the reference surface roughness corresponding to the plurality of side surfaces of the plurality of reference crystals. In some embodiments, the preset table may be preset based on historical data or prior knowledge.

In some embodiments, the target optical output value, the initial optical output value, the dimension, the composition, and the initial surface roughness of each side surface of the o initial crystal may further be processed through a roughness determination model, to determine the target surface roughness of each side surface of the initial crystal.

In some embodiments, the roughness determination model may be a machine learning model. In some embodiments, the roughness determination model may include any one or a combination of, various feasible models such as a recurrent neural network (RNN) model, a deep neural network (DNN) model, a convolutional neural network (CNN) model, etc.

In some embodiments, the roughness determination model may be trained based on a plurality of second training samples with second labels through various methods, and model parameters are updated. For example, training may be performed based on gradient descent. Merely by way of example, a plurality of second training samples with the second labels are input into an initial roughness determination model, a loss function is constructed based on the second labels and output results of the initial roughness determination model, and parameters of the initial roughness determination model are iteratively updated based on the loss function. When the loss function of the initial roughness determination model satisfies a preset condition, model training is completed, and the trained roughness determination model is obtained. The preset condition may be that the loss function converges, an iteration count reaches a threshold, etc.

In some embodiments, the second training samples may include a target optical output value, an initial optical output value, a dimension, a composition, and initial surface roughness of each side surface of a sample initial crystal. The second label corresponding to the second training sample may include target surface roughness of each side surface of the sample initial crystal. In some embodiments, the second training samples may be obtained based on historical data. The second labels corresponding to the second training samples may be obtained through manual annotation. In some embodiments, the second training samples and corresponding second labels thereof may be determined according to historical data of optical output regulation performed on different historical initial crystals. For example, a target optical output value, an initial optical output value, a dimension, a composition, and initial surface roughness of each side surface of a historical initial crystal in the historical data may be used as the second training sample, and target surface roughness of each side surface of the historical initial crystal in the historical data may be used as the second label corresponding to the second training sample.

By determining the target surface roughness of each side surface of the initial crystal through the roughness determination model, a self-learning capability of the machine learning model may be utilized to find patterns from a large amount of historical data, obtain association relationships among data, and improve accuracy and efficiency of determining the target surface roughness of each side surface of the initial crystal.

In 640, surface roughness modification is performed on at least one outer surface of the one or more initial crystals based on the optical adjustment scheme, such that the actual optical output value of the one or more initial crystals changes from the initial optical output value to the target optical output value, wherein the surface roughness Ra of the at least one outer surface after the surface roughness modification is within a range of 0.001 μm-10 μm.

In some embodiments, the surface roughness modification may include a grinding operation and/or a polishing operation. More descriptions regarding the grinding operation and the polishing operation may be found in operation 610 and related descriptions thereof.

In some embodiments, based on the optical adjustment scheme, the surface roughness modification may be performed on one or more side surfaces, the first end surface, and/or the second end surface of the initial crystal, such that the surface roughness of each side surface of the initial crystal after the surface roughness modification is within a range of 0.01 μm to 10 μm. In some embodiments, the surface roughness Ra of at least one outer surface after the surface roughness modification is within a range of 0.001 μm to 0.1 μm. That is, based on the optical adjustment scheme, the surface roughness modification is performed on the one or more side surfaces, the first end surface, and/or the second end surface of the initial crystal, such that the surface roughness of each side surface of the initial crystal after the surface roughness modification is within a range of 0.01 μm to 0.1 μm. When the surface roughness of any side surface of the initial crystal after the surface roughness modification exceeds the range of 0.01 μm to 0.1 μm, an influence of the surface roughness of the crystal on photon propagation inside the crystal may be effectively reduced, and quality of the initial crystal is ensured. Preferably, the surface roughness of each side surface of the initial crystal after the surface roughness modification may be within one of ranges such as 0.01 μm to 0.09 μm, 0.01 μm to 0.08 μm, 0.01 μm to 0.07 μm, 0.01 μm to 0.06 μm, 0.01 μm to 0.05 μm, 0.01 μm to 0.04 μm, or the like, to further ensure quality of the initial crystal.

In some embodiments, based on the optical adjustment scheme, the surface roughness modification may further be performed on the one or more side surfaces, the first end surface, and/or the second end surface of the initial crystal, such that the surface roughness of each side surface of the initial crystal after the surface roughness modification is within a range of 0.01 μm to 1.5 μm.

When the surface roughness of any side surface of the initial crystal after the surface roughness modification exceeds a range of 0.01 μm to 1.5 μm, photon transmission inside the initial crystal is very slightly affected by the surface roughness of the crystal, and in this case, regulating optical output by adjusting the surface roughness loses significance. In some embodiments of the present disclosure, by limiting the surface roughness of the side surfaces of the initial crystal after the surface roughness modification, a relatively large influence on photon propagation inside the initial crystal caused by excessively large or excessively small surface roughness may be avoided, and quality of the initial crystal is ensured.

In some embodiments, the grinding operation and/or the polishing operation may be performed on the one or more side surfaces of the initial surface, to regulate the actual optical output value of the initial crystal. In some embodiments, during the grinding operation and/or the polishing operation, a change in the actual optical output value of the initial crystal may be monitored, and when the actual optical output value of the initial crystal reaches the target optical output value, the grinding operation and/or the polishing operation is stopped. For example, the actual optical output value of the initial crystal may be detected after each grinding cycle or polishing cycle; when the actual optical output value of the initial crystal does not reach the target optical output value, the grinding operation and/or the polishing operation is continued; and when the actual optical output value of the initial crystal reaches the target optical output value, the grinding operation and/or the polishing operation is stopped.

In some embodiments, when the optical adjustment scheme includes increasing the surface roughness of at least one outer surface of the initial crystal, the machining operation for increasing the surface roughness may include: changing morphology of the side surfaces of the initial crystal through mechanical machining such as grinding, polishing, or the like, thereby increasing the surface roughness of the side surfaces.

In some embodiments, when the optical adjustment scheme includes decreasing the surface roughness of at least one outer surface of the initial crystal, the machining operation for decreasing the surface roughness may include: reducing the surface roughness of the side surfaces through manners such as ultraprecision cutting, low-roughness grinding, honing, or superfinishing. A particle size of the abrasive or the abrasive material of the grinding head used is in a range of 0.1 μm to 800 μm.

The foregoing manners for increasing or decreasing the surface roughness may be performed in any feasible manner, which is not limited herein.

In some embodiments, based on the optical adjustment scheme, the surface roughness of the one or more side surfaces of the initial crystal may be adjusted through the machining operation (i.e., surface roughness modification), such that the surface roughness of the one or more side surfaces of the initial crystal reaches corresponding target surface roughness.

In some embodiments, actual surface roughness of each side surface of the initial crystal may be measured and recorded during machining. When the actual surface roughness reaches the target surface roughness, the machining is completed, and the initial crystal after the machining is obtained.

In some embodiments of the present disclosure, by determining the target surface roughness of each side surface of the initial crystal, and causing the actual surface roughness of each side surface of the initial crystal to reach the target surface roughness through machining, the actual optical output value of the initial crystal after the machining is closer to the target optical output value.

In some embodiments of the present disclosure, by performing the surface roughness modification on the side surfaces of the initial crystal, optical output of the crystal may be effectively regulated, reflection paths of photons may be increased, an objective of increasing or decreasing the optical output may be achieved, and the optical output at different positions of the same crystal may be made uniform.

Applications of the scintillator crystals may include constructing a scintillator detector by connecting single crystal strips having small dimensions into a large-wrap-count array and using the large-wrap-count array in cooperation with a photomultiplier tube. The scintillator detector is widely applied to related fields such as nuclear medicine (positron emission tomography (PET)), X-ray security inspection, nuclear radiation detection, high-energy physics, space physics, environmental monitoring, and geological exploration.

When performance of the plurality of crystal strips constituting the crystal array is different, or when processing of the plurality of crystal strips is different, optical output of the plurality of crystal strips constituting the crystal array is inconsistent, thereby reducing optical output consistency of the crystal array. The optical output consistency of the crystal array is one of important performance indexes of the crystal array, and the optical output consistency of the crystal array directly affects overall performance of the crystal array. However, the optical output consistency of the crystal array is affected by a plurality of factors such as processing quality of the crystals, defects and impurities inside the crystals, and optical characteristics of the crystals. How to ensure optical output consistency of the crystal strips in the crystal array is not only greatly related to performance of the crystal strips themselves, but also greatly related to tray arrangement of the crystal strips, an assembly coupling manner of the crystal strips, a reflective medium between the crystal strips, peripheral packaging, light extraction, silicon wafer coupling, and coupling of the photomultiplier tube.

One or more embodiments of the present disclosure further disclose a method for crystal assembly, such that optical output uniformity, energy resolution consistency, and decay time consistency of single crystals in one array are improved, which helps ensure excellent performance of the constituted crystal array. More descriptions regarding the method for crystal assembly may be found in FIG. 8 and related descriptions thereof.

FIG. 8 is a flowchart illustrating another exemplary process for crystal assembly according to some embodiments of the present disclosure.

In some embodiments, one or more operations in a process 800 may be performed by an operator, or may be performed by machining equipment for crystal production and processing (e.g., a grinder, a polishing machine, etc.), crystal performance inspection equipment, or the like. As shown in FIG. 8, the process 800 includes the following operations.

In 810, a plurality of target crystals are obtained.

The target crystals refer to crystal materials used for assembling a crystal array after surface roughness modification is performed. For example, the target crystals may be crystals obtained after the surface roughness modification is performed on the one or more initial crystals described above or below. More descriptions regarding the surface roughness modification may be found in 640 and related descriptions thereof.

It should be noted that, because the target crystals used for constituting the crystal array are obtained after the surface roughness modification is performed on the initial crystals, the crystal type, element composition, etc., of the target crystals may be the same as the crystal type and element composition of the initial crystals.

In some embodiments, in at least two target crystals of the plurality of target crystals used for constituting the crystal array, a ratio of contents of trivalent Ce element (i.e., Ce³⁺) to tetravalent Ce element (i.e., Ce⁴⁺) is different. That is, the crystal array may be constituted using at least two target crystals including the trivalent Ce element and the tetravalent Ce element in different ratios. It should be noted that, when the ratio of contents of the trivalent Ce element to the tetravalent Ce element is different in the at least two target crystals, in order to ensure that optical output of the target crystals in the crystal array is close (e.g., a difference in optical output values is within a range of −10% to +10%, or the like), the surface roughness of at least one set of corresponding side surfaces of the at least two target crystals is different. One set of corresponding side surfaces refers to surfaces, in the two target crystals, facing the same side. More descriptions regarding contents of the trivalent Ce element and the tetravalent Ce element may be found in FIG. 6 and related descriptions thereof.

In some embodiments, a difference in surface roughness Ra between any two side surfaces of any target crystal of the plurality of target crystals used for constituting the crystal array is less than 0.15 μm.

In some embodiments, the difference in the surface roughness Ra between any two side surfaces of any target crystal among the plurality of target crystals used for constituting the crystal array may be less than 0.99 μm, 0.89 μm, 0.59 μm, 0.25 μm, 0.1 μm, 0.09 μm, 0.08 μm, 0.07 μm, 0.06 μm, 0.05 μm, 0.04 μm, 0.03 μm, 0.02 μm, 0.01 μm, 0.008 μm, 0.005 μm, 0.001 μm, or the like. More descriptions regarding the side surfaces may be found in FIG. 6 and related descriptions thereof.

In some embodiments, surface roughness Ra of a light-exiting surface of any target crystal among the plurality of target crystals used for constituting the crystal array may be less than 0.04 μm. In some embodiments, the surface roughness Ra of the light-exiting surface of any target crystal among the plurality of target crystals used for constituting the crystal array may be less than 0.05 μm, 0.06 μm, 0.07 μm, 0.08 μm, 0.03 μm, 0.02 μm, 0.01 μm, or the like.

In some embodiments, the surface roughness Ra of any side surface of any target crystal among the plurality of target crystals used for constituting the crystal array may be in a range of 0.01 μm to 1.5 μm. In some embodiments, the surface roughness Ra of any side surface of any target crystal among the plurality of target crystals used for constituting the crystal array may further be within one of ranges such as 0.01 μm to 1.4 μm, 0.01 μm to 1.3 μm, 0.01 μm to 1.2 μm, 0.01 μm to 1.1 μm, 0.01 μm to 1.0 μm, 0.01 μm to 0.9 μm, 0.01 μm to 0.8 μm, 0.01 μm to 0.7 μm, 0.01 μm to 0.6 μm, or the like.

In some embodiments of the present disclosure, by controlling the surface roughness Ra of any two side surfaces of any target crystal among the plurality of target crystals used for constituting the crystal array, and controlling the difference in the surface roughness Ra between any two side surfaces of any target crystal among the plurality of target crystals used for constituting the crystal array to satisfy a certain requirement (e.g., the difference is less than 0.05 μm), overall optical output performance of the crystal array is improved.

In some embodiments, the difference between target optical output values corresponding to any two initial crystals among the plurality of initial crystals used for constituting the crystal array is less than 10% of the target optical output value of any one of the two initial crystals. More descriptions regarding the target optical output value may be found in FIG. 6 and related descriptions thereof. It should be noted that, when the machining operation for changing the surface roughness (surface roughness modification) is performed on the initial crystal, the objective is to cause the actual optical output value of the initial crystal to reach the target optical output value of the initial crystal. Therefore, when the initial crystal reaches the target optical output value after the surface roughness modification is performed, the initial crystal reaching the target optical output value may be referred to as the target crystal. That is, the target optical output value of the initial crystal is equal to the actual optical output value of the target crystal.

In some embodiments, a difference between target optical output values corresponding to any two initial crystals among the plurality of initial crystals used for constituting the crystal array may be less than 9%, 8%, 7%, 6%, 5%, 4%, 3%, 2%, or 1% of the target optical output value of any one of the two initial crystals. In some embodiments, the difference between target optical output values corresponding to any two initial crystals among the plurality of initial crystals used for constituting the crystal array may be less than 15%, 14%, 13%, 12%, or 11% of the target optical output value of any one of the two initial crystals.

In some embodiments of the present disclosure, by limiting the difference between target optical output values corresponding to any two initial crystals to be less than a certain proportion of the target optical output value of any one of the two initial crystals, a difference between the target optical output values of the plurality of initial crystals constituting the same crystal array may be reduced, such that the optical output of the plurality of target crystals constituting the crystal array is close, and optical output consistency of the crystal array is improved.

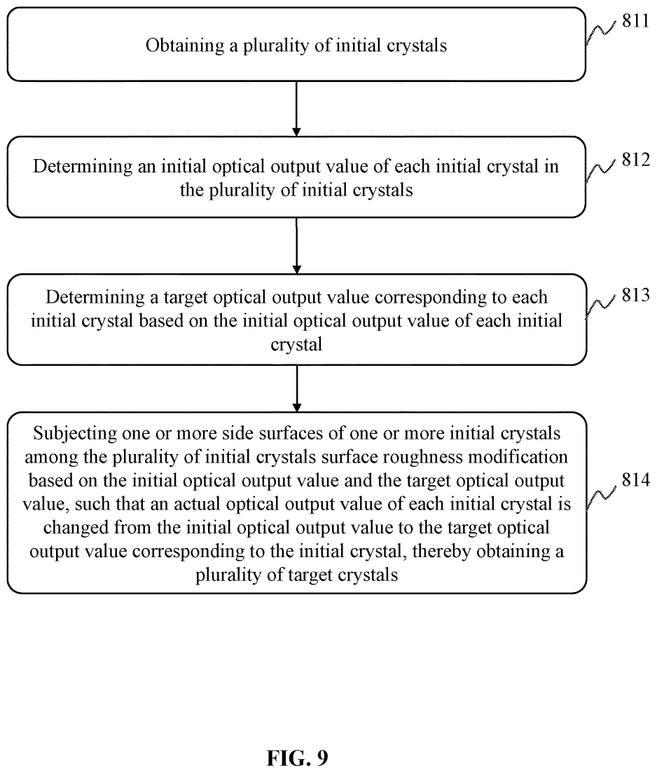

In some embodiments, the plurality of target crystals may be obtained by machining the plurality of initial crystals. As shown in FIG. 9, a method for obtaining a plurality of target crystals used for assembling a crystal array is described below through operations 811-814. FIG. 9 is a schematic diagram illustrating a process for obtaining a plurality of target crystals used for assembling a crystal array according to some embodiments of the present disclosure. In 811, a plurality of initial crystals are obtained.

In some embodiments, in order to obtain the plurality of initial crystals capable of being assembled into the same crystal array, a plurality of suitable initial crystals may be selected from a large quantity of initial crystals. In some embodiments, a selection basis may include: a difference between initial optical output values of any two initial crystals among the plurality of initial crystals being less than 10% of the initial optical output value of any one of the two initial crystals. In other embodiments, the selection basis may include: the difference between corresponding initial optical output values of any two initial crystals among the plurality of initial crystals being less than 15%, 14%, 13%, 12%, 11%, 9%, 8%, 7%, 6%, 5%, 4%, 3%, 2%, or 1% of the initial optical output value of any one of the two initial crystals.

In other embodiments, the selection basis may include: selecting a plurality of initial crystals having a dimension satisfying a dimension requirement. In some embodiments, the dimension requirement may include: the dimension of the initial crystals being in a range of length (0.2 mm-6 mm)×width (0.2 mm-6 mm)× height (3 mm-100 mm). In some embodiments, the dimension requirement may further include: a height difference between any two initial crystals among the plurality of initial crystals being in a range of 3 mm to 60 mm.

In 812, an initial optical output value of each initial crystal in the plurality of initial crystals is determined.

More descriptions regarding the initial optical output value of the initial crystal may be found in FIG. 6 and related descriptions thereof.

In 813, a target optical output value corresponding to each initial crystal is determined based on the initial optical output value of each initial crystal.

In some embodiments, the target optical output values of the plurality of initial crystals used for assembling into the same crystal array may be the same. For example, the target optical output values of the plurality of initial crystals used for assembling into the same crystal array may be set as a preset target value.

In some embodiments, the preset target value may be one of a median, an average, or a mode of initial optical output values of the plurality of initial crystals used for assembling into the same crystal array.

In some embodiments, the preset target value may be determined according to related parameters of the crystal array constituted by the plurality of initial crystals. In some embodiments, the related parameters of the crystal array may include a wrap count of the crystal array. In some embodiments, a correspondence relationship between different wrap counts of the crystal array and different reference optical output values may be preset based on historical data or prior knowledge. When the plurality of initial crystals are determined to be used to constitute the crystal array having a specific wrap count, the reference optical output value corresponding to the crystal array having the specific wrap count may be determined according to the correspondence relationship, and the reference optical output value is determined as the preset target value.

In some embodiments, the preset target value may also be set manually based on actual production requirements.

In some embodiments, the target optical output values of the plurality of initial crystals used for assembling into the same crystal array may also be different.

In some embodiments, statistical analysis may be performed based on the plurality of initial optical output values of the plurality of initial crystals used for assembling into the same crystal array. For example, a mean value of the plurality of initial optical output values corresponding to the plurality of initial crystals is used as an expectation μ, a normal distribution graph is constructed by taking three standard deviations (i.e., 3σ, where σ is a standard deviation of the plurality of initial optical output values corresponding to the plurality of initial crystals) as a standard, and a preset interval (μ−3σ, α+3σ) is constructed by taking the expectation μ as an interval midpoint. The preset interval may cause a certain proportion (e.g., 95%) of the initial optical output values to fall within the preset interval. Further, the target optical output value of the initial crystal having the initial optical output value within the preset interval (μ−3σ, μ+3σ) may be determined to be equal to the initial optical output value of the initial crystal. The initial crystal having the initial optical output value within the preset interval (μ−3σ, μ+3σ) may be referred to as a baseline crystal. Further, the target optical output value of the initial crystal having the initial optical output value outside the preset interval (μ−3σ, μ+3σ) may be determined to be one of a median, an average, or a mode of initial optical output values of one or more baseline crystals.

In some embodiments, the target optical output value of each initial crystal in the plurality of initial crystals used for assembling into the same crystal array may be determined based on reducing machining time. For example, the initial crystals of which a difference between the initial optical output values corresponding to any two initial crystals among the plurality of initial crystals is not less than 10% of the initial optical output value of any one of the two initial crystals may be determined as the initial crystals to be machined, so as to regulate the actual optical output values of the initial crystals to be machined, such that a difference between the initial optical output values corresponding to any two initial crystals to be machined among the machined initial crystals is less than 10% of the initial optical output value of any one of the two initial crystals.

In 814, one or more side surfaces of one or more initial crystals among the plurality of initial crystals are subjected to surface roughness modification based on the initial optical output value and the target optical output value, such that the actual optical output value of each initial crystal is changed from the initial optical output value to the target optical output value corresponding to the initial crystal, and the plurality of target crystals are obtained.

In some embodiments, in order to improve optical output consistency of the crystal array, the surface roughness modification may be performed on the plurality of initial crystals used for assembling into the same crystal array, such that the actual optical output values of the plurality of initial crystals used for assembling into the same crystal array reach the target optical output values.

More descriptions regarding the surface roughness modification may be found in FIG. 6 and related descriptions thereof.

In some embodiments, when the surface roughness modification is performed on the plurality of initial crystals used for assembling into the same crystal array, it should be noted that a perpendicularity deviation between any two side surfaces of any target crystal among the plurality of target crystals obtained by the machining and used for constituting the crystal array is not greater than 1°.

In some embodiments, when the surface roughness modification is performed on the plurality of initial crystals used for assembling into the same crystal array, it should be noted that the light-exiting surface of any target crystal among the plurality of target crystals obtained by the machining and used for constituting the crystal array may be fully covered with concave points and convex points having an average height difference not greater than 0.03 μm, and other surfaces (e.g., at least one side surface) may be fully covered with concave points and convex points having an average height difference not greater than 1 μm.

In 820, the plurality of target crystals are arranged in an array, to form the crystal array.

The crystal array refers to an array obtained by combining the plurality of target crystals.

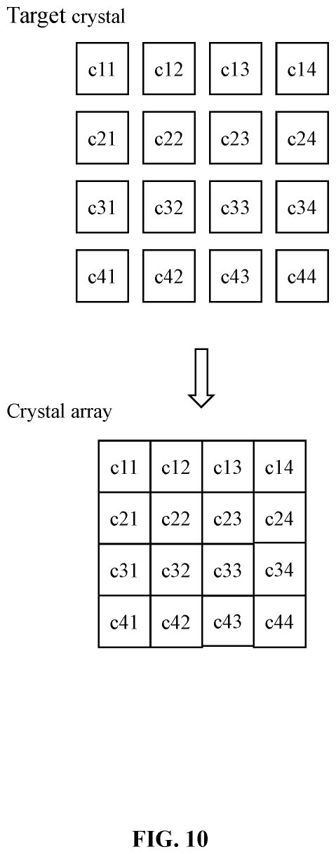

As shown in FIG. 10, target crystals c11, c12, c13, c14, c21, c22, c23, c24, c31, c32, c33, c34, c41, c42, c43, and c44 may form a crystal array [(c11, c12, c13, c14), (c21, c22, c23, c24), (c31, c32, c33, c34), (c41, c42, c43, c44)].

In some embodiments, at least one set of target crystals in the crystal array is coupled through air, and one set of target crystals includes two target crystals. In some embodiments, at least one set of target crystals in the crystal array is coupled through a reflective film. In some embodiments, at least one set of target crystals in the crystal array is coupled through a reflective filling material. In some embodiments, the plurality of target crystals in the crystal array may be coupled through one or more of the foregoing coupling manners. More descriptions regarding the reflective film may be found in the related descriptions above.

In some embodiments, when at least one set of target crystals is formed through coupling, fillers may be disposed between a portion or all of the target crystals, to separate the portion or all of the target crystals. Types of the fillers include, but are not limited to, polytetrafluoro-ethylene (PTFE), an enhanced specular reflector (ESR), E60, Teflon, a barium compound, a titanium compound, a magnesium compound, or the like.

In some embodiments, partitioning and tray arrangement may be performed on the plurality of target crystals, to obtain a plurality of crystal combinations. Each crystal combination may be bonded and assembled into one crystal array according to an arrangement position. More descriptions regarding partitioning and tray arrangement of the plurality of target crystals and the bonding and assembling may be found in the related descriptions above.

In some embodiments of the present disclosure, the partitioning and tray arrangement is performed on the target crystals according to performance of the target crystals (e.g., the optical output performance, decay time, energy resolution, and/or channel values), such that the target crystals having the close optical output performance, decay time, and/or energy resolution and a smaller channel difference are grouped into one crystal combination, so as to facilitate subsequent assembling of the crystal array, effectively ensure performance similarity of the crystals in the crystal array, and improve a qualification rate of the crystal array.

Some embodiments of the present disclosure also provide a system for optical output regulation of a crystal. The system includes a controller and machining equipment. The controller is configured to: obtain an initial optical output value of one or more initial crystals, wherein outer surfaces of an initial crystal include a first end surface and a second end surface disposed opposite to each other, and side surfaces located between the first end surface and the second end surface, and at least one of the first end surface or the second end surface is a light-exiting surface; and determine a target optical output value of the one or more initial crystals. The machining equipment is configured to: perform surface roughness modification on one or more side surfaces, the first end surface, and/or the second end surface of the initial crystal based on the initial optical output value and the target optical output value, such that the actual optical output value of the initial crystal is changed from the initial optical output value to the target optical output value, wherein the surface roughness Ra of at least one outer surface of the initial crystal after the surface roughness modification is within a range of 0.001 μm to 10 μm. In some embodiments, the surface roughness Ra of at least one outer surface of the initial crystal after the surface roughness modification is within a range of 0.001 μm to 0.1 μm. In some embodiments, the initial crystal is a scintillator crystal, and the initial crystal includes at least two of Lu, Si, Y, Ca, Mg, Al, Ga, Sc, In, La, Br, Ba, S, Sn, Zn, Zr, Hf, Cd, Pb, Eu, Ce, Bi, Ge, I, Na, Cs, or Cu. More descriptions may be found in the related descriptions above.

Some embodiments of the present disclosure further disclose a crystal array.

In some embodiments, the crystal array may be assembled and obtained by the method (or process) for crystal assembly described in any one of the foregoing embodiments. Because the method (or process) for crystal assembly described in any one of the foregoing embodiments may regulate the optical output of the plurality of initial crystals used for assembling the crystal array, optical output values of any two target crystals in the crystal array assembled by the method (or process) for crystal assembly described in any one of the foregoing embodiments are close, such that optical output consistency of the crystals in the crystal array and overall optical output performance of the crystal array can be improved.

In some embodiments, the target crystals in the crystal array include the trivalent Ce element (i.e., Ce³⁺) and the tetravalent Ce element (i.e., Ce⁴⁺), a ratio of contents of the trivalent Ce element to the tetravalent Ce element is different in at least two target crystals in the crystal array, and the surface roughness of at least one set of corresponding side surfaces of the two target crystals is different. More descriptions regarding the trivalent Ce element and the tetravalent Ce element may be found in FIG. 6 and related descriptions thereof.

Factors affecting optical output include an element content ratio and the surface roughness. When element content ratios of two target crystals are different (e.g., the content ratios of Ce³⁺ to Ce⁴⁺ of the two target crystals are different), in order to ensure close optical output, the surface roughness of at least one set of the corresponding side surfaces of the two target crystals is also different.

The inventors have found that, when crystals are prepared, a certain ratio of Ce³⁺ and Ce⁴⁺ may be doped therein, and optical output values of individual crystals may be effectively regulated by adjusting the content ratio of Ce³⁺ to Ce⁴⁺. However, because preparation processes of different crystals are different, for example, preparation formulas, growth manners, and growth equipment of different crystals are different, the content ratios of Ce³⁺ to Ce⁴⁺ doped therein are different when different crystals are prepared. In some embodiments, crystals cut from original crystals produced by a preparation process having similar preparation formulas, growth manners, and growth equipment may be selected for array assembly, thereby ensuring that the optical output of the crystals constituting the crystal array may be close, and further improving optical output consistency of the crystal array. However, this array assembly imposes relatively great limitations on the selected crystals.

Further, after the inventors find that the optical output value of the crystal is also related to factors such as the surface roughness of the crystal, the surface roughness of the side surfaces of an individual crystal and/or a surface opposite to a light-exiting surface of the individual crystal may be adjusted, to increase or decrease reflection paths of photons, achieve an objective of increasing or decreasing optical output, improve the optical output consistency of the crystals in the crystal array and the overall optical output performance of the crystal array.

In some embodiments, the relevant information of the one or more initial crystals includes a recognition result of the one or more initial crystals. Correspondingly, determining the processing scheme based on the relevant information of the one or more initial crystals may include: determining the processing scheme for the one or more initial crystals based on the recognition result.

Related descriptions regarding determining the processing scheme for the one or more initial crystals will be described below.

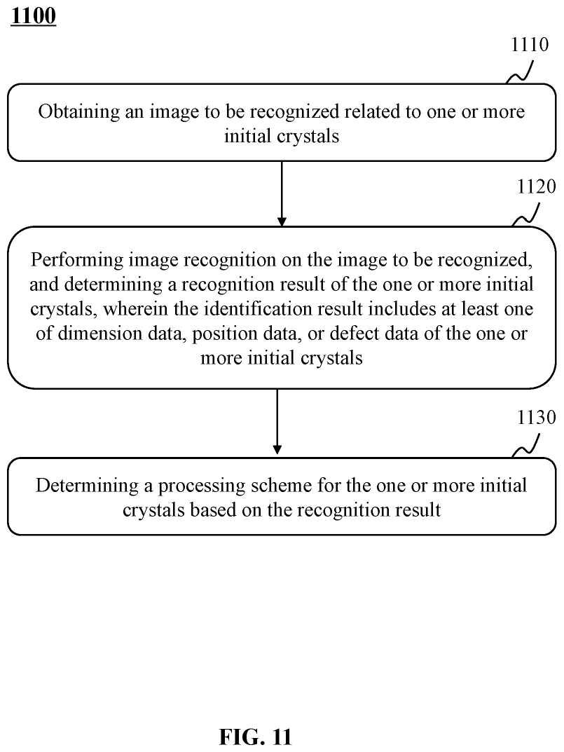

FIG. 11 is a flowchart illustrating another exemplary process for crystal processing according to some embodiments of the present disclosure. In some embodiments, a process 1100 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1100 as an example. As shown in FIG. 11, the process 1100 includes the following operations.

In 1110, an image to be recognized related to one or more initial crystals is obtained.

The image to be recognized refers to an image including the one or more initial crystals.

It may be understood that, when purposes of recognition performed by the crystal processing device are different, contents in the image to be recognized may be different. For example, the image to be recognized may include an image of a material tray containing a plurality of initial crystals, and the crystal processing device may recognize the image to be recognized, thereby determining dimension data and first position data on the material tray, and further determining whether the plurality of initial crystals can be assembled in a next step and whether adjustment needs to be performed through the first adjustment scheme. As another example, the image to be recognized may include an image of one initial crystal, and the crystal processing device may recognize the image to be recognized, thereby determining dimension data and first defect data of the initial crystal, and further determining a cutting scheme for cutting the initial crystal. As yet another example, the image to be recognized may further include an image to be recognized of a plurality of crystal arrays composed of crystal units, and the crystal processing device may recognize the image to be recognized, thereby determining second position data, second defect data, and third defect data of the crystal arrays, and further determining whether the plurality of crystal arrays satisfy requirements and whether adjustment needs to be performed through a second adjustment scheme.

In some embodiments, the image to be recognized may be obtained in a plurality of manners. For example, a user may control an image acquisition device to photograph the one or more initial crystals, and transmit the image to be recognized to the crystal processing device through a user terminal. As another example, the crystal processing device may further control the image acquisition device to photograph the one or more initial crystals, thereby obtaining the image to be recognized.

Types of the image to be recognized may be various. For example, when the image acquisition device is a visual image acquisition device (e.g., a camera), the image to be recognized may be a visual image. As another example, when the image acquisition device is an X-ray machine, the image to be recognized may be an X-ray image. The image to be recognized may be a two-dimensional image or a three-dimensional image. A three-dimensional image to be recognized may be obtained by performing image fusion on two-dimensional images of the one or more initial crystals from different viewing angles.

The count of images to be recognized may be one or more. For example, a photographing position and/or a photographing angle of the image acquisition device may be adjusted, to obtain a plurality of images to be recognized of the one or more initial crystals from different viewing angles. As another example, placement states of the one or more initial crystals may be adjusted (e.g., rotated), and the image acquisition device may photograph the adjusted one or more initial crystals, to obtain images to be recognized of the one or more initial crystals in different placement states.

In some embodiments, the one or more initial crystals may be irradiated by a plurality of light sources with different colors, and the image acquisition device may photograph the one or more initial crystals under irradiation of the light sources, to obtain the plurality of images to be recognized. The colors of the light sources may be preset, for example, preset as five colors. The colors of the light sources may be determined based on colors of the one or more initial crystals. For example, when a color of one initial crystal is yellow, colors used for irradiating the initial crystal may be determined as three colors through a preset crystal-light source correspondence table. It should be noted that absorption of the initial crystals to different colors is different, and thus photographing effects under different light sources are different. Features of the initial crystals (e.g., dimensions, defects, or the like) in some images to be recognized may be relatively more obvious. Furthermore, display effects of some defects are different under different light sources. For example, some defects are difficult to be photographed under one light source, but may be clearly displayed under another light source. Therefore, in some embodiments of the present disclosure, a comprehensive determination is performed by photographing images to be recognized of the initial crystals under light sources with different colors, thereby improving the accuracy of crystal recognition.

It should be noted that many crystals (e.g., silicon dioxide, fluorite, or the like) are transparent. When transparent initial crystals are photographed, reflection and fusion with a background region may occur.

In some embodiments, for the light source of each color, a background color of the initial crystals in the image to be recognized corresponding to the light source is the complementary color of the color corresponding to the light source. The transparent initial crystal may transmit light from the background color. By setting the background color and the light source color as complementary colors, the light of the background color and the light source may be additively mixed in a region corresponding to the initial crystals, such that the color of the region is different from the color of other regions. Based on an additive color mixing principle of colored light, when two colors located at opposite positions on a color wheel are added together, the two colors may cancel and lighten each other or may produce neutrality, and finally form visually white or gray tones, thereby emphasizing the region of the initial crystals and avoiding fusion of the initial crystals with the background region.

In some embodiments, for each initial crystal, the crystal processing device may determine the crystal color of the initial crystal. The crystal processing device may determine the crystal color of the initial crystal in a plurality of manners. For example, the crystal color of the initial crystal may be determined based on user input. As another example, the crystal color of the initial crystal may be determined by photographing the initial crystal and then performing analysis.

In some embodiments, the crystal processing device may illuminate the initial crystal with the light source of the complementary color corresponding to the crystal color, and obtain the image to be recognized corresponding to the initial crystal. For example, when one initial crystal (e.g., neodymium-doped yttrium aluminum garnet) is red, green may be selected as the light source to irradiate the initial crystal, to obtain the image to be recognized. In some embodiments of the present disclosure, through the foregoing arrangement, color saturation and contrast of the crystal in the image to be recognized may be enhanced, a contrast effect between the initial crystal and the background region may be improved, a crystal structure may be highlighted, fusion of the initial crystal with the background region in the image to be recognized may be avoided, and accurate recognition of the initial crystal may be ensured.

In some embodiments, the background color of the initial crystal in the image to be recognized may be selected as the complementary color of the crystal color, thereby highlighting the crystal structure, avoiding fusion of the initial crystal with the background region in the image to be recognized, and ensuring accurate recognition of the initial crystal.

In some embodiments, the crystal processing device may further fuse one or more crystal images of the initial crystal. The fused crystal image may completely display the initial crystal, and determined as the image to be recognized. More descriptions regarding the foregoing embodiments may be found in the related descriptions below.

In some embodiments, the image to be recognized may include a two-dimensional code. The two-dimensional code may label the one or more initial crystals in the image to be recognized, so as to facilitate distinguishing and storing recognition results of different initial crystals by the crystal processing device, and facilitate subsequent query.

In some embodiments, the image to be recognized may include one or more of a first image, a second image, or a third image. More descriptions regarding the first image, the second image, and the third image may be found in the related descriptions below.

In 1120, image recognition is performed on the image to be recognized, and the recognition result of the one or more initial crystals is determined, wherein the recognition result includes at least one of dimension data, position data, or defect data of the one or more initial crystals.

The dimension data refers to data characterizing the dimension of the one or more initial crystals. The dimension data may include, but are not limited to, a diameter, a shape, a crystal axis size, a thickness, and a grain size of the one or more initial crystals.

The position data refers to data characterizing positions of the one or more initial crystals. In some embodiments, the position data may include the first position data. In some embodiments, the position data may include the second position data. More descriptions regarding the first position data and the second position data may be found in the related descriptions below.

The defect data refers to data characterizing defects of the one or more initial crystals. In some embodiments, the defect data may include the first defect data. In some embodiments, the defect data may include the second defect data and the third defect data. More descriptions regarding the first defect data, the second defect data, and the third defect data may be found in the related descriptions below.

In some embodiments, the dimension data and the defect data of the initial crystals may be detected and obtained based on an apparatus for crystal inspection. More descriptions regarding the apparatus for crystal inspection may be found in the related descriptions below.

In some embodiments, the crystal processing device may perform image recognition on the image to be recognized through a machine learning model (e.g., a dimension recognition model, a first position recognition model, a first defect recognition model, or the like) or other image recognition methods (e.g., a template matching method, feature extraction and matching, or the like), to determine the recognition result of the initial crystals. More descriptions regarding the foregoing embodiments may be found in the related descriptions below.

In some embodiments, the crystal processing device may determine the defect data (e.g., the first defect data, the second defect data, or the like) in the one or more initial crystals based on the dimension data and the weight data of the one or more initial crystals. For example, the crystal processing device may determine density data of the initial crystal based on weight data and the dimension data of the initial crystal and compare the density data with density data of corresponding-type initial crystals to determine the defect data of the initial crystal. It may be understood that some initial crystals may include crystals of other types, and direct determination through image recognition is difficult. In some embodiments of the present disclosure, based on weight data of the initial crystal and the dimension data determined through image recognition, density data of the initial crystal may be determined, thereby determining whether the initial crystal has defects, and accuracy of the recognition result may be improved.

In some embodiments, when images to be recognized includes image of the one or more initial crystals under the plurality of light sources with different colors, the crystal processing device may perform image recognition on the images to be recognized corresponding to the plurality of light sources with different colors, to determine a plurality of candidate recognition results for the one or more initial crystals. The candidate recognition results may be candidate recognition results corresponding to the initial crystals. Similar to the recognition result, the candidate recognition result may also include at least one of the dimension data, the position data, or the defect data of the corresponding initial crystal.

In some embodiments, the crystal processing device may perform image recognition on the image to be recognized through the machine learning model or other image recognition methods, to determine the candidate recognition results of the one or more initial crystals. More descriptions regarding determining the candidate recognition results may be found in related descriptions below regarding determining the recognition result.

In some embodiments, the candidate recognition result may further include a confidence level corresponding to the candidate recognition result. Merely by way of example, when the crystal processing device processes the image to be recognized through the machine learning model, output of the machine learning model may further include the confidence level.

In some embodiments, the crystal processing device may determine the recognition result of the one or more initial crystals based on the plurality of candidate recognition results. For example, the crystal processing device may determine a fusion result of the plurality of candidate recognition results as the recognition result of the one or more initial crystals. As another example, when one feature (e.g., the dimension) of the initial crystal includes a plurality of different candidate recognition results, the crystal processing device may determine a candidate recognition result having the highest confidence level among the candidate recognition results as the recognition result of the feature.

In some embodiments of the present disclosure, by performing recognition on the images to be recognized under the different light sources and comprehensively determining the recognition result of the initial crystal, accuracy of the recognition result may be ensured. For example, defects in the initial crystal may be presented differently in lights of different colors. Through the images to be recognized under the light sources with different colors, defects in the initial crystal may be better recognized.

In 1130, the processing scheme for the one or more initial crystals is determined based on the recognition result.

In some embodiments, the processing scheme may include the first adjustment scheme for adjusting the one or more initial crystals on the material tray. More descriptions regarding a process for determining the first adjustment scheme based on the recognition result may be found in the related descriptions below.

In some embodiments, the processing scheme may further include the cutting scheme for cutting the one or more initial crystals. More descriptions regarding a process for determining the cutting scheme based on the recognition result may be found in the related descriptions below.

In some embodiments, the processing scheme may further include the second adjustment scheme for adjusting the crystal units and/or the reflective structure in the crystal array composed of the one or more initial crystals. More descriptions regarding a process for determining the second adjustment scheme for the crystal array based on the recognition result may be found in the related descriptions below.

In some embodiments of the present disclosure, by performing image recognition on the one or more initial crystals, the processing scheme for processing the one or more initial crystals may be accurately determined, automated processing of the one or more initial crystals may be realized, efficiency of processing the one or more initial crystals may be improved, and production and processing costs of the one or more initial crystals may be reduced.

Crystals produced by the crystal growth equipment vary in size and shape and may have defects, and cannot be directly used. The crystals need to be divided into the crystal units having a specified size and having no defects or fewer defects, so as to facilitate subsequent processing (e.g., assembling the crystals into the crystal array and installed in scanning equipment). If the dimensions and defects of the initial crystals are evaluated manually, accuracy is not high on the one hand, and on the other hand, the cost is high and the efficiency is low. Based on this, in some embodiments of the present disclosure, by performing image recognition on the image to be recognized of the one or more initial crystals, the dimension data and the first defect data of the initial crystals may be determined, thereby determining the cutting scheme for the initial crystals, so as to improve the accuracy of initial crystal recognition, reduce costs, and improve processing efficiency.

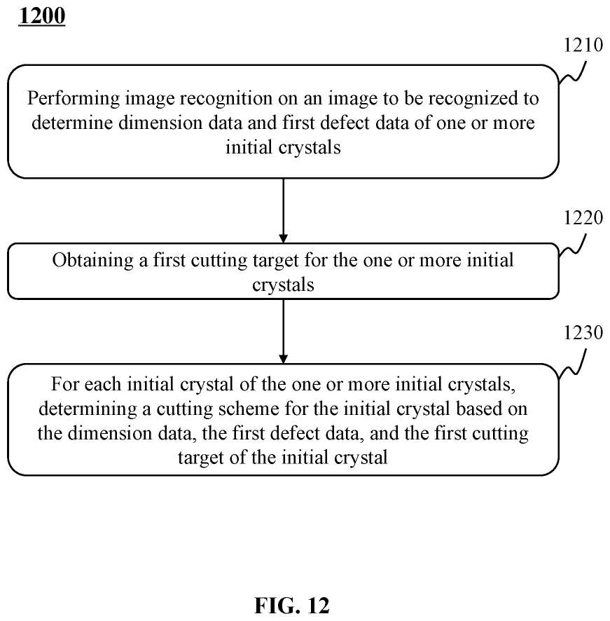

FIG. 12 is a flowchart illustrating an exemplary process for determining a cutting scheme for one or more initial crystals according to some embodiments of the present disclosure. In some embodiments, a process 1200 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1200 as an example. As shown in FIG. 12, the process 1200 may include the following operations. As shown in FIG. 12, process 1200 may include the following operations.

In 1210, image recognition is performed on an image to be recognized to determine dimension data and first defect data of the one or more initial crystals.

In some embodiments, the crystal processing device may perform image recognition on the image to be recognized through a dimension recognition model to determine the dimension data of the one or more initial crystals. The crystal processing device may input the image to be recognized into the dimension recognition model, and output of the dimension recognition model may be the dimension data of the one or more initial crystals in the image to be recognized. The dimension recognition model may be any one or a combination of a convolutional neural network or any other machine learning model capable of implementing such function.

The dimension recognition model may be obtained through training based on third training samples with third labels. The third training samples may include first sample images, and the third labels may include sample dimension data corresponding to first sample crystals in the first sample images. The third training samples may be determined by photographing the first sample crystals, and the third labels may be determined by manually measuring the photographed first sample crystals.

In some embodiments, output of the dimension recognition model may further include a confidence level of the dimension data. Correspondingly, when the dimension recognition model is trained, the third labels may further include first sample confidence levels, and the first sample confidence levels may be determined through manual annotation (e.g., annotated as 1). When the confidence level of the dimension data output by the dimension recognition model is greater than a preset first confidence level threshold, the dimension data output by the dimension recognition model may be determined as the dimension data of the initial crystal. When the confidence level of the dimension data output by the dimension recognition model is less than or equal to the preset first confidence level threshold, a new image to be recognized may be obtained by adjusting a color of the light source or a photographing angle, a position, or the like of the image acquisition device, and processed through the dimension recognition model until the dimension data output by the dimension recognition model is greater than the first confidence level threshold, thereby ensuring accuracy of the dimension data in the recognition result.

The first defect data refers to first defect data characterizing defects of the one or more initial crystals themselves. For example, the first defect data may include, but are not limited to, positions, sizes, or the like of defects such as point defects, line defects, surface defects, crystal textures, and inclusions of the one or more initial crystals.

In some embodiments, the crystal processing device may perform image recognition on the image to be recognized through the first defect recognition model, to determine the first defect data of the one or more initial crystals. The crystal processing device may input the image to be recognized into the first defect recognition model, and output of the first defect recognition model may be the first defect data of the one or more initial crystals in the image to be recognized. The first defect recognition model may be any one or a combination of a convolutional neural network or any other machine learning model capable of implementing such function.

The first defect recognition model may be obtained through training based on fourth training samples with fourth labels. The fourth training samples may include second sample images, and the fourth labels may include sample second defect data corresponding to second sample crystals in the second sample images. The fourth training samples may be determined by photographing the second sample crystals, and the fourth labels may be determined through manual observation and annotation of the photographed second sample crystals.

In some embodiments, output of the first defect recognition model may further include a confidence level of the first defect data. Correspondingly, when the first defect recognition model is trained, the fourth labels may further include second sample confidence levels, and the second sample confidence levels may be determined through manual annotation. When the confidence level of the first defect data output by the first defect recognition model is greater than a preset second confidence level threshold, the first defect data output by the first defect recognition model may be determined as the first defect data of the initial crystal. When the confidence level of the first defect data output by the first defect recognition model is less than or equal to the preset second confidence level threshold, a new image to be recognized may be obtained by adjusting the color of the light source or the photographing angle, the position, or the like of the image acquisition device, and may be processed through the first defect recognition model until the first defect data output by the first defect recognition model is greater than the second confidence level threshold, thereby ensuring accuracy of the first defect data in the recognition result.

In 1220, a first cutting target for the one or more initial crystals is obtained.

The first cutting target refers to a primary target for cutting the one or more initial crystals. When the one or more initial crystals are cut, priority is to be given to satisfying the first cutting target.

In some embodiments, the first cutting target may include the dimension of the one or more initial crystal units to be cut. In some embodiments, the dimension of the crystal units may also be determined by presetting. For example, the dimension of the crystal units may be determined by order requirements.

In some embodiments, the first cutting target may include a cutting priority. For example, the first cutting target may be crystal quantity priority or quality priority.

In some embodiments, the first cutting target may include a specific cutting quantity and/or cutting quality. For example, the first cutting target may include cutting 10 crystal units having a specified size. The cutting quality may be related to defects in the crystal units after cutting. The fewer the defects in the crystal units after cutting are, the higher the cutting quality is. The cutting quality may be represented by a quality score, for example, 1 to 10. The higher the quality score is, the higher the cutting quality is. The cutting quality may also be represented by a quality grade, for example, Grade I to Grade V. The higher the quality grade is, the higher the cutting quality is. Merely by way of example, the first cutting target may include that the quality grade of the crystal units after cutting is at least Grade II.

In some embodiments, the first cutting target of the one or more initial crystals may be obtained in a plurality of manners. For example, the first cutting target of the one or more initial crystals may be obtained through user input. As another example, the first cutting target may also be determined through a preset correspondence relationship table based on the dimension data and the first defect data of the one or more initial crystals.

In 1230, for each initial crystal of the one or more initial crystals, the cutting scheme for the initial crystal is determined based on the dimension data, the first defect data, and the first cutting target of the initial crystal.

The cutting scheme may be a specific scheme for cutting the initial crystal. The cutting scheme may include, but is not limited to, a count of cutting operations on the crystal, an angle of each cutting operation, a depth of each cutting operation, or the like. A cutting machine may cut the initial crystal based on the cutting scheme, and the crystal units obtained after cutting satisfy the first cutting target.

In some embodiments, for each initial crystal, the crystal processing device may perform modeling or use various data analysis algorithms, such as a regression analysis method, a discriminant analysis method, or the like, to analyze and process the dimension data, the first defect data, and the first cutting target of the initial crystal, to obtain the cutting scheme for the initial crystal.

In some embodiments, for each initial crystal, the crystal processing device obtains the plurality of candidate cutting schemes based on the dimension data, the first defect data, and the first cutting target of the initial crystal, and screens the plurality of candidate cutting schemes to determine the cutting scheme for the initial crystal. More descriptions regarding the foregoing embodiments may be found in the related descriptions below.

In some embodiments of the present disclosure, by performing image recognition on the one or more initial crystals, the dimension data and the first defect data of the crystals may be accurately determined, and, in combination with the first cutting target, the cutting scheme for cutting the initial crystals is determined, such that automated processing of the initial crystals may be realized, cutting precision and cutting consistency of the initial crystals may be improved, crystal loss may be reduced, and labor costs may be lowered.

In some embodiments, for each order, the crystal processing device may determine a crystal input amount corresponding to the order based on order requirements and the cutting scheme of each initial crystal. The order requirements may include a required dimension of crystal units and a required quantity of crystals. For example, the order requirements may include two hundred crystal units having dimension A. The crystal processing device may determine, for each initial crystal, the cutting scheme for the initial crystal when the required dimension of the crystal units is satisfied, thereby determining a quantity of crystal units of each initial crystal after the cutting scheme is performed, and determining a crystal input amount corresponding to the order based on the quantity of crystals in the order requirements and the quantity of crystal units of each initial crystal after the cutting scheme is performed. It may be understood that the dimensions of the crystal units required by each order may be different. If an input quantity of initial crystals during cutting is excessively small, the quantity of obtained crystal units cannot satisfy the order requirements, and repeated cutting operations are caused, such that the process is cumbersome. If the input quantity of initial crystals during cutting is excessively large, the quantity of obtained crystal units exceeds the order requirements, thereby causing waste of crystals and increasing a cost. In some embodiments of the present disclosure, the crystal input amount corresponding to each order may be accurately determined based on the order requirements and the cutting scheme of each initial crystal, such that the count of crystal units obtained after cutting satisfies the order requirements, and problems caused by excessive input or insufficient input are avoided.

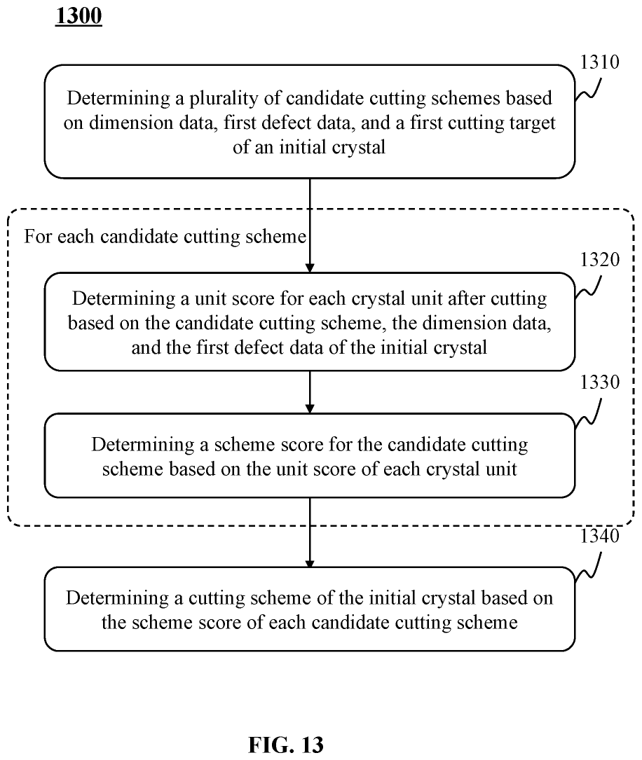

FIG. 13 is a flowchart illustrating another exemplary process for determining a cutting scheme for one or more initial crystals according to some embodiments of the present disclosure. In some embodiments, a process 1300 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1300 as an example. As shown in FIG. 13, the process 1300 may include the following operations.

In 1310, a plurality of candidate cutting schemes are determined based on dimension data, first defect data, and a first cutting target of an initial crystal.

The candidate cutting schemes refer to schemes to be evaluated for cutting the initial crystal. Similar to the cutting scheme, the candidate cutting schemes may include, but are not limited to, a count of cutting operations on the crystal, an angle of each cutting operation, a depth of each cutting operation, or the like. It should be noted that the crystal units obtained after the initial crystal is cut based on each candidate cutting scheme satisfy the first cutting target.

In some embodiments, the plurality of candidate cutting schemes may be determined in a plurality of manners based on the dimension data, the first defect data, and the first cutting target of the initial crystal. For example, a user may generate the plurality of candidate cutting schemes based on the dimension data, the first defect data, and the first cutting target of the initial crystal, and the crystal processing device may obtain the candidate cutting schemes input by the user. As another example, the crystal processing device may randomly generate the plurality of candidate cutting schemes based on the dimension data, the first defect data, and the first cutting target of the initial crystal.

For each candidate cutting scheme, the crystal processing device may perform the following operation 1320 and operation 1330.

In 1320, a unit score for each crystal unit after cutting is determined based on the candidate cutting scheme, the dimension data, and the first defect data of the initial crystal.

The crystal processing device may generate a three-dimensional model of the initial crystal based on the dimension data and the first defect data of the initial crystal, and then perform simulated cutting on the three-dimensional model of the initial crystal based on the candidate cutting scheme through simulation cutting software, to obtain a plurality of crystal units after cutting.

In some embodiments, for each crystal unit after cutting, the crystal processing device may analyze and process the crystal unit, and then determine the unit score of the crystal unit based on a preset scoring relationship table. The unit score may be used to evaluate quality of the crystal unit. The unit score may be represented by a score value. For example, the unit score may be 0 to 100, and a higher score indicates that the corresponding crystal unit is more excellent.

In some embodiments, the unit score may be related to defects in the crystal unit. For example, the crystal processing device analyzes whether the crystal unit has defects and specific defect dimensions, and determines the unit score of the crystal unit through the preset scoring relationship table. In some embodiments, the unit score may further be related to other parameter information of the crystal unit. For example, the crystal processing device may determine the unit score of the crystal unit in combination with the dimension of the crystal unit. As another example, the crystal processing device may determine optical performance of each crystal unit, such as refractive index, transmittance, and polarization, through simulation analysis by optical simulation software (e.g., TracePro, CODE V, or the like), and thus determine the unit score of the crystal unit in combination with the optical performance of each crystal unit.

In 1330, a scheme score for the candidate cutting scheme is determined based on the unit score of each crystal unit.

The scheme score may be used to evaluate quality of the candidate cutting scheme. Merely by way of example, the scheme score may be represented by a score value, and a higher scheme score may indicate that the corresponding candidate cutting scheme is more excellent.

In some embodiments, the crystal processing device may perform a summation on the unit scores of the crystal units to determine the scheme score of the candidate cutting scheme.

In some embodiments, the crystal processing device may obtain a second cutting target for cutting the initial crystal. The second cutting target refers to a secondary target for cutting the one or more initial crystals. The second cutting target may be determined through user input. When the initial crystal is cut, on a premise that the first cutting target is satisfied, satisfying the second cutting target may further be considered. It should be noted that, on the premise that the first cutting target is satisfied, the candidate cutting scheme may fail to satisfy the second cutting target, or may satisfy the second cutting target, and the candidate cutting scheme satisfying both the first cutting target and the second cutting target better conforms to user expectations.

In some embodiments, the second cutting target may include a cutting priority. For example, the first cutting target may be to cut 10 crystal units having a specified dimension, and the second cutting target may include that the higher the quality of the foregoing 10 crystal units having the specified dimension, the better. As another example, the first cutting target may be to cut 10 crystal units having a specified dimension, and the second cutting target may include that the more the crystal units having the specified dimension, the better.

In some embodiments, the crystal processing device may determine a quantity weight and a quality weight of the crystal unit based on the second cutting target. Merely by way of example, the crystal processing device may determine the quantity weight and the quality weight of the crystal unit through a preset weight relationship table based on the cutting priority in the second cutting target. For example, when the cutting priority in the second cutting target is quality priority, the crystal processing device may determine, through the preset weight relationship table, that the quantity weight of the crystal unit is 0.3 and the quality weight of the crystal unit is 0.7.

In some embodiments, the crystal processing device may determine the scheme score of the candidate cutting scheme based on the quantity weight, the quality weight, a count of the crystal units, and the unit score of each crystal unit. For example, the crystal processing device may determine the scheme score of the candidate cutting scheme based on the following formula:

$$S = ( {w}_{1} * N ) + {w}_{2} * {\sum }_{i = 1}^{n} {s}_{i} \qquad ( 1 )$$

where S is the scheme score of the candidate cutting scheme, w₁ is the quantity weight, N is the count of crystal units, w₂ is the quality weight, and sᵢ is the unit score of an i-th crystal unit.

In some embodiments of the present disclosure, the second cutting target may further refine user requirements for cutting the one or more initial crystals, so as to ensure that crystal units obtained after cutting the one or more initial crystals according to the determined cutting scheme better satisfy user requirements, and optimize flexibility of initial crystal cutting.

In some embodiments, the crystal processing device may determine a discarded portion after the initial crystal is cut based on the candidate cutting scheme and the dimension data, determine a waste score of the candidate cutting scheme based on the discarded portion, and determine the scheme score of the candidate cutting scheme in combination with the unit score of the crystal unit. The waste score may be used to evaluate a waste degree of the candidate cutting scheme with respect to the initial crystal. The waste score may be related to a volume or a weight of waste generated by cutting the initial crystal after the candidate cutting scheme is performed. The more waste is generated, the more waste is caused, and the lower the waste score is. In some embodiments, the waste score may be a negative value.

In some embodiments of the present disclosure, by combining the waste score, the candidate cutting scheme may be evaluated from a plurality of aspects, crystal consumption may be effectively reduced, and production costs may be saved.

In 1340, the cutting scheme of the initial crystal is determined based on the scheme score of each candidate cutting scheme.

In some embodiments, the crystal processing device may determine a candidate cutting scheme having the highest scheme score as the cutting scheme of the initial crystal.

In some embodiments of the present disclosure, by screening the candidate cutting schemes, the determined cutting scheme may better satisfy cutting requirements, automation of crystal production may be improved, flexibility and adaptability of initial crystal cutting may be improved, costs and errors caused by manually designing cutting schemes may be reduced, and smooth implementation of initial crystal cutting may be ensured.

In some embodiments, the initial crystals on the material tray (e.g., crystal units that have been cut) may be assembled by the robotic arm, so as to improve automation of crystal production, improve assembling efficiency and accuracy, and reduce an assembling cost. It may be understood that the robotic arm may grasp and assemble the initial crystals on the material tray based on a preset program. If the initial crystals are not placed at designated positions on the material tray, or the dimension of crystals placed at corresponding positions is incorrect, crystal assembly may fail or defects may exist. Based on this, in some embodiments of the present disclosure, by performing image recognition on the image to be recognized of the one or more initial crystals on the material tray, the dimension data and the first position data of the one or more initial crystals may be determined, thereby determining the first adjustment scheme for adjusting the one or more initial crystals on the material tray, and improving a success rate of crystal assembly. More descriptions regarding assembling the one or more initial crystals may be found in the related descriptions above.

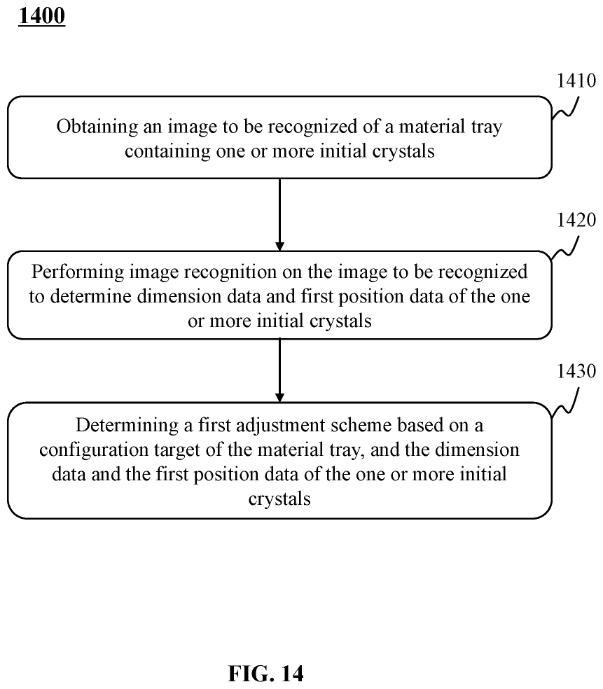

FIG. 14 is a flowchart illustrating an exemplary process for determining a first adjustment scheme for one or more initial crystals according to some embodiments of the present disclosure. In some embodiments, a process 1400 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1400 as an example. As shown in FIG. 14, the process 1400 may include the following operations.

In 1410, an image to be recognized of a material tray containing one or more initial crystals is obtained.

In 1420, image recognition is performed on the image to be recognized to determine dimension data and first position data of the one or more initial crystals.

In some embodiments, the crystal processing device may perform image recognition on the image to be recognized through a dimension recognition model to determine the dimension data of the one or more initial crystals. More descriptions regarding the dimension recognition model may be found in the related description in the present disclosure.

The first position data refers to position data of the one or more initial crystals on the material tray. For example, when the material tray is a rectangular material tray, a tray coordinate system may be constructed by taking a lower-left corner of the material tray as a coordinate origin, taking a width of the material tray as an X-axis, and taking a length of the material tray as a Y-axis, and the first position data include positions of the one or more initial crystals on the material tray in the tray coordinate system. In some embodiments, the first position data may include a coordinate position and an inclination angle on the material tray. The coordinate position may be a coordinate position of a centroid of the initial crystal, and the foregoing inclination angle may be an inclination angle of an extending direction of the initial crystal.

In some embodiments, the crystal processing device may analyze and process the image to be recognized through a first position recognition model to determine the first position data of the one or more initial crystals. The crystal processing device may input the image to be recognized into the first position recognition model, and output of the first position recognition model may be the first position data of the one or more initial crystals. The first position recognition model may be any one or a combination of a convolutional neural network or any other machine learning model capable of implementing such function.

The first position recognition model may be obtained through training based on fifth training samples with fifth labels. The fifth training samples may include third sample images, and the fifth labels may include sample first position data corresponding to third sample crystals in the third sample images. The fifth training samples may be determined by photographing the third sample crystals, and the fifth labels may be determined by manually measuring positions of the third sample crystals.

In some embodiments, the output of the first position recognition model may further include a confidence level of the first position data. Correspondingly, when the first position recognition model is trained, the fifth labels may further include a third sample confidence level, and the third sample confidence level may be determined through manual annotation. When the confidence level of the first position data output by the first position recognition model is greater than a preset third confidence level threshold, the first position data output by the first position recognition model may be determined as the first position data of the initial crystal. When the confidence level of the first position data output by the first position recognition model is less than or equal to the preset third confidence level threshold, a new image to be recognized may be obtained by adjusting the color of the light source or the photographing angle, the position, or the like of the image acquisition device, and the new image to be recognized is processed through the first position recognition model until the first position data output by the first position recognition model is greater than the third confidence level threshold, thereby ensuring accuracy of the first position data in the recognition result.

In 1430, the first adjustment scheme is determined based on a configuration target of the material tray, and the dimension data and the first position data of the one or more initial crystals.

The configuration target refers to a target for configuring the one or more initial crystals on the material tray. The configuration target may include a quantity of the one or more initial crystals required to be configured on the material tray, the dimension of each initial crystal, the position of each initial crystal relative to the material tray, or the like.

In some embodiments, the crystal processing device may analyze the dimension data and the first position data of each initial crystal, and evaluate whether each initial crystal satisfies the configuration target. When each initial crystal satisfies the configuration target, the first adjustment scheme may be determined as no adjustment being needed. When one or more initial crystals fail to satisfy the configuration target, the crystal processing device may determine the first adjustment scheme for adjusting the corresponding one or more initial crystals.

For example, when one initial crystal on the material tray does not match a position specified in the configuration target (e.g., the position coordinate or angle deviates), the first adjustment scheme may include adjusting the initial crystal to a corresponding position of the configuration target. As another example, when redundant initial crystals exist in the material tray, the first adjustment scheme may include removing the redundant initial crystals from the material tray. As yet another example, when dimension data of one initial crystal on the material tray does not conform to the crystal dimension specified by the configuration target for a corresponding position, the first adjustment scheme may include replacing the initial crystal at the corresponding position, and dimension data of the replaced initial crystal conforms to the crystal dimension specified by the configuration target for the corresponding position.

In some embodiments, the crystal processing device may send the first adjustment scheme to a user terminal, so as to facilitate viewing by a user.

In some embodiments, the crystal processing device may generate a control instruction based on the first adjustment scheme and send the control instruction to the robotic arm, and the robotic arm may adjust the initial crystals on the material tray after receiving the control instruction.

In some embodiments of the present disclosure, by performing image recognition on the one or more initial crystals on the material tray, and determining the first adjustment scheme for adjusting the initial crystals on the material tray based on the recognition result, it may be ensured that the initial crystals are all located at designated positions on the material tray, smooth subsequent assembly of the initial crystals on the material tray may be ensured, and assembly efficiency and quality of the initial crystals may be improved.

In some embodiments, the one or more initial crystals may further include the crystal units constituting the crystal array. In some embodiments of the present disclosure, image recognition is further performed on the image to be recognized of the crystal array composed of the plurality of initial crystals. Whether the initial crystals at various positions in the crystal array need to be adjusted is determined through the dimension data of the initial crystals in the crystal array, such that appearance consistency of the crystal array may be ensured, assembling quality of the crystal array may be improved, and detection efficiency may be improved.

In some embodiments, the crystal processing device may analyze performance data and the first position data of each initial crystal, and evaluate whether the initial crystal satisfies a performance target. When all initial crystals all satisfy the performance target, the third adjustment scheme may be determined as no adjustment being needed; and when one or more initial crystals fail to satisfy the performance target, the crystal processing device may determine the third adjustment scheme for adjusting the corresponding one or more initial crystals.

The performance target refers to a target to be satisfied by one or more performance parameters of the initial crystals on the material tray. The performance parameters refer to parameters characterizing crystal performance, and the performance parameters may include, but are not limited to, surface roughness, light yield, energy resolution, decay time, or the like. The performance parameters may be detected and obtained by detecting the initial crystals through performance detection equipment.

The performance target may include a range to be satisfied by one or more performance parameters of the initial crystals required to be configured on the material tray. For example, the performance target may include one or more of a surface roughness target (also referred to as target surface roughness), a light yield target (also referred to as a target light yield), an energy resolution target (also referred to as a target energy resolution), a decay time target (also referred to as a target decay time), or the like. The performance target may be determined according to application requirements of the crystal array.

For example, the crystal processing device may obtain one or more performance parameters of the initial crystals at various positions on the material tray, and determine whether data of the initial crystals at the various positions satisfy the performance target. When a performance parameter of an initial crystal at one position satisfies the configuration target, the initial crystal at the corresponding position is retained. When a performance parameter of an initial crystal at one position does not satisfy the configuration target, the initial crystal at the corresponding position is replaced, and the performance parameter of the replaced initial crystal satisfies the configuration target.

In some embodiments, the crystal processing device may send the third adjustment scheme to the user terminal, to prompt the user to adjust the crystal array. After the third adjustment scheme is received through the user terminal, the user may select whether to adjust the crystal array according to requirements.

In some embodiments, the crystal processing device may generate a control instruction based on the third adjustment scheme and send the control instruction to the robotic arm. After the control instruction is received, the robotic arm may adjust the initial crystals on the material tray.

In some embodiments of the present disclosure, by performing image recognition on the image to be recognized of the crystal array composed of the plurality of initial crystals, and determining, through performance parameters of the initial crystals in the crystal array, whether the initial crystals at various positions in the foregoing crystal array need to be adjusted, performance consistency of the crystal array may be ensured, assembling quality of the crystal array may be improved, and detection efficiency may be improved.

In some embodiments, the one or more initial crystals form a crystal array including a plurality of crystal units, a reflective structure is disposed between at least two adjacent crystal units of the crystal array, and the processing scheme may include a second adjustment scheme for adjusting at least one of the crystal units or the reflective structure in the one or more initial crystals.

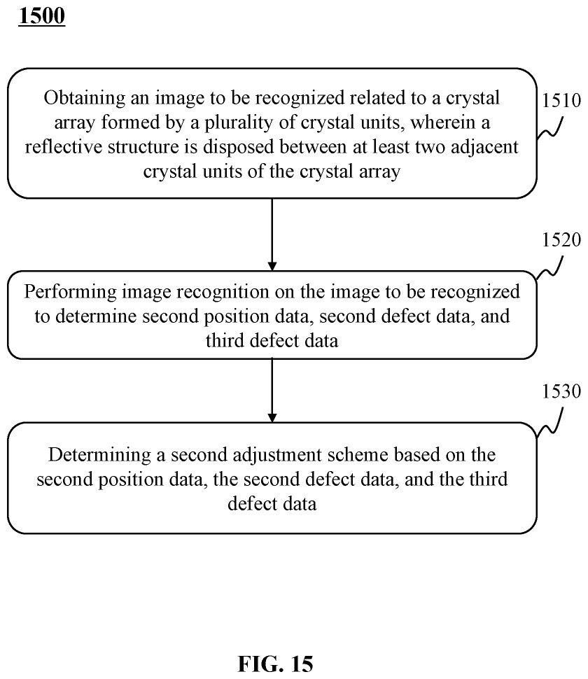

FIG. 15 is a flowchart illustrating an exemplary process for determining a second adjustment scheme the one or more initial crystals according to some embodiments of the present disclosure. In some embodiments, a process 1500 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1500 as an example. As shown in FIG. 15, the process 1500 may include the following operations.

In 1510, an image to be recognized related to a crystal array formed by a plurality of crystal units is obtained, wherein a reflective structure is disposed between at least two adjacent crystal units of the crystal array.

The crystal array refers to an array obtained by combining the plurality of crystal units. The crystal array may be used for nuclear medicine such as X-ray computed tomography and positron emission tomography, and may also be used for nuclear detection technologies such as industrial computed tomography, oil well exploration, nuclear physics, high-energy physics, environmental detection, security detection, fire control of weapons and equipment, guidance, or the like.

The reflective structure is disposed between at least two adjacent crystal units of the crystal array. The reflective structure refers to a structure having a light reflection capability inside the crystal array. The reflective structure may enhance optical performance of the crystal array and prevent optical crosstalk between the crystal units. The reflective structure includes, but is not limited to at least one of a reflective filling material (e.g., a barium compound, a titanium compound, or a mixture of the barium compound and the titanium compound) or a reflective film (e.g., an ESR film, a polytetrafluoroethylene tape, aluminum foil paper, a white polyester reflective film, or the like).

More descriptions regarding a process for obtaining the image to be recognized of the crystal array may be found in FIG. 11 and related descriptions thereof.

In 1520, image recognition is performed on the image to be recognized to determine second position data, second defect data, and third defect data.

The second position data characterizes relative positions of the plurality of crystal units in the crystal array. For example, the second position data may include arrangement positions of the crystal units in the crystal array (e.g., a certain position in a certain row).

In some embodiments, the crystal processing device may perform image recognition on the image to be recognized based on a second position recognition model to determine the second position data. The crystal processing device may input the image to be recognized into the second position recognition model, and output of foregoing second position recognition model may be the second position data of the crystal units in the crystal array. The second position recognition model may be any one or a combination of a convolutional neural network or any other machine learning model capable of implementing such function.

The second position recognition model may be obtained through training based on sixth training samples with sixth labels. The sixth training samples may include fourth sample images, and the sixth labels may include sample second position data corresponding to first sample crystal units in the fourth sample images. The sixth training samples may be determined by photographing a first sample crystal array, and the sixth labels may be determined by manually annotating positions of the first sample crystal units in the photographed first sample crystal array.

In some embodiments, the output of the second position recognition model may further include a confidence level of the second position data. Correspondingly, when the second position recognition model is trained, the sixth labels may further include a fourth sample confidence level, and the fourth sample confidence level may be determined through manual annotation. When the confidence level of the second position data output by the second position recognition model is greater than a preset fourth confidence level threshold, the second position data output by the second position recognition model may be determined as the second position data of the crystal units. When the confidence level of the second position data output by the second position recognition model is less than or equal to the preset fourth confidence level threshold, a new image to be recognized may be obtained by adjusting the color of the light source or the photographing angle, the position, or the like of the image acquisition device, and the new image to be recognized is processed through the second position recognition model until the second position data output by the second position recognition model is greater than the fourth confidence level threshold, thereby ensuring accuracy of the second position data in the recognition result.

The second defect data refers to data characterizing defects of the crystal units themselves in the crystal array. For example, the second defect data may include, but is not limited to, positions, sizes, or the like of defects such as point defects, line defects, surface defects, crystal textures, and inclusions of the crystal units.

In some embodiments, the crystal processing device may perform image recognition on the image to be recognized through a second defect recognition model to determine the second defect data. The crystal processing device may input the image to be recognized into the second defect recognition model, and output of the second defect recognition model may be the second defect data of the crystal units in the image to be recognized. The second defect recognition model may be any one or a combination of a convolutional neural network or any other machine learning model capable of implementing such function.

The second defect recognition model may be obtained through training based on seventh training samples with seventh labels. The seventh training samples may include fifth sample images, and the seventh labels may include sample second defect data corresponding to second sample crystal units in the fifth sample images. The seventh training samples may be determined by photographing a second sample crystal array, and the seventh labels may be determined through manual annotation after observing the second sample crystal units in the photographed second sample crystal array.

In some embodiments, the output of the second defect recognition model may further include a confidence level of the second defect data. Correspondingly, when the second defect recognition model is trained, the seventh labels may further include a fifth sample confidence level, and the fifth sample confidence level may be determined through manual annotation. When the confidence level of the second defect data output by the second defect recognition model is less than or equal to a preset fifth confidence level threshold, the new image to be recognized may be obtained by adjusting the color of the light source or the photographing angle, the position, or the like of the image acquisition device, and the new image to be recognized is processed through the second defect recognition model until the confidence level of the second defect data output by the second defect recognition model is greater than the fifth confidence level threshold, thereby ensuring accuracy of the second defect data in the recognition result.

The third defect data refers to data characterizing arrangement defects of the crystal array. In some embodiments, the third defect data may include defects in arrangement of positions of crystal units in the crystal array, for example, a crystal unit at a certain position in a certain row is not aligned with other crystal units. In some embodiments, the third defect data may further include defects in arrangement of position of the reflective structure in the crystal array. For example, a reflective structure is missing between two adjacent crystal units. As another example, the reflective structure is arranged at an incorrect position.

In some embodiments, the crystal processing device may perform image recognition on the image to be recognized through a third defect recognition model to determine the third defect data. The crystal processing device may input the image to be recognized and the target array image into the third defect recognition model, and output of the third defect recognition model may be the third defect data of the crystal units in the image to be recognized. The third defect recognition model may be any one or a combination of a convolutional neural network or any other machine learning model capable of implementing such function. The target array image may be an image of the crystal array to be arranged. The target array image may be determined through user input.

The third defect recognition model may be obtained through training based on eighth training samples with eighth labels. The eighth training samples may include sixth sample images and sample array images, and the eighth labels may include sample third defect data corresponding to third sample crystal units in the sixth sample images. The eighth training samples may be determined by photographing a third sample crystal array, and the eighth labels may be determined by manually comparing arrangement of the third sample crystal units and sample reflective structures in the sixth sample images and the sample array images.

In some embodiments, the output of the third defect recognition model may further include a confidence level of the third defect data. Correspondingly, when the third defect recognition model is trained, the eighth labels may further include a sixth sample confidence level, and the sixth sample confidence level may be determined through manual annotation. When the confidence level of the third defect data output by the third defect recognition model is greater than a preset sixth confidence level threshold, the third defect data output by the third defect recognition model may be determined as the third defect data of the crystal units; when the confidence level of the third defect data output by the third defect recognition model is less than or equal to the preset sixth confidence level threshold, a new image to be recognized may be obtained by adjusting the color of the light source or the photographing angle, the position, or the like of the image acquisition device, and the new image to be recognized is processed through the third defect recognition model until the confidence level of the third defect data output by the third defect recognition model is greater than the sixth confidence level threshold, thereby ensuring accuracy of the third defect data in the recognition result.

In 1530, a second adjustment scheme is determined based on the second position data, the second defect data, and the third defect data.

The crystal processing device may analyze and process the second position data, the second defect data, the third defect data, and a target array requirement to determine the second adjustment scheme. The target array requirements may be requirements for the crystal array input by the user. For example, the target array requirements may include allowed defect types, sizes, or the like. As another example, the target array requirements may include a specific arrangement of the crystal array.

For example, when the second position data characterizes that a second row includes only 3 crystal units, but the target array requirement characterizes that the second row includes 4 crystal units, the crystal processing device may determine that the second adjustment scheme includes supplementing one crystal unit to the second row.

As another example, when the second defect data characterizes that a defect with a volume of 0.02 mm³ exists in the second crystal unit from the left in the second row, but the target array requirement characterizes that a maximum volume of an allowed defect is 0.01 mm³, the crystal processing device may determine that the second adjustment scheme includes supplementing the reflective structure between the second crystal unit and the third crystal unit from the left in the second row.

As yet another example, when the third defect data characterizes that the reflective structure is not disposed between the second crystal unit and the third crystal unit from the left in the second row, the crystal processing device may determine that the second adjustment scheme includes supplementing the reflective structure between the second crystal unit from the left and the third crystal unit in the second row.

For a further example, when the second position data, the second defect data, and the third defect data all satisfy the target array requirement, the crystal processing device may determine the second adjustment scheme as no adjustment being needed.

In some embodiments, the crystal processing device may send the second adjustment scheme to the user terminal, to prompt the user to adjust the crystal array. After the second adjustment scheme is received through the user terminal, the user may select whether to adjust the crystal array according to requirements.

In some embodiments, the crystal processing device may send the second adjustment scheme to the user terminal, to prompt the user to adjust the crystal array. The user may, after receiving the second adjustment scheme through the user terminal, select whether to adjust the crystal array according to requirements.

In some embodiments, based on the second adjustment scheme, at least one of the crystal units or the reflective structure in the crystal array may be adjusted by the robotic arm, to complete packaging of the crystal array. The crystal processing device may generate a control instruction based on the second adjustment scheme and send the control instruction to the robotic arm. The robotic arm may adjust at least one of the crystal units or the reflective structure in the crystal array based on the received control instruction, thereby completing packaging of the crystal array, improving packaging efficiency of the crystals, improving packaging accuracy, ensuring continuous operation capability of crystal packaging, and reducing the cost.

It may be understood that, when a transparent initial crystal is photographed, the transparent initial crystal in the crystal image may have reflection or may be fused with the background region, such that the transparent initial crystal is incompletely displayed. If image recognition is directly performed based on the crystal image as the image to be recognized, accuracy of the recognition result is reduced. Based on this, in some embodiments of the present disclosure, completeness of the initial crystals in the crystal image may be determined, so as to ensure that the initial crystals are completely displayed in the image to be recognized, thereby ensuring accuracy when image recognition is performed on the image to be recognized.

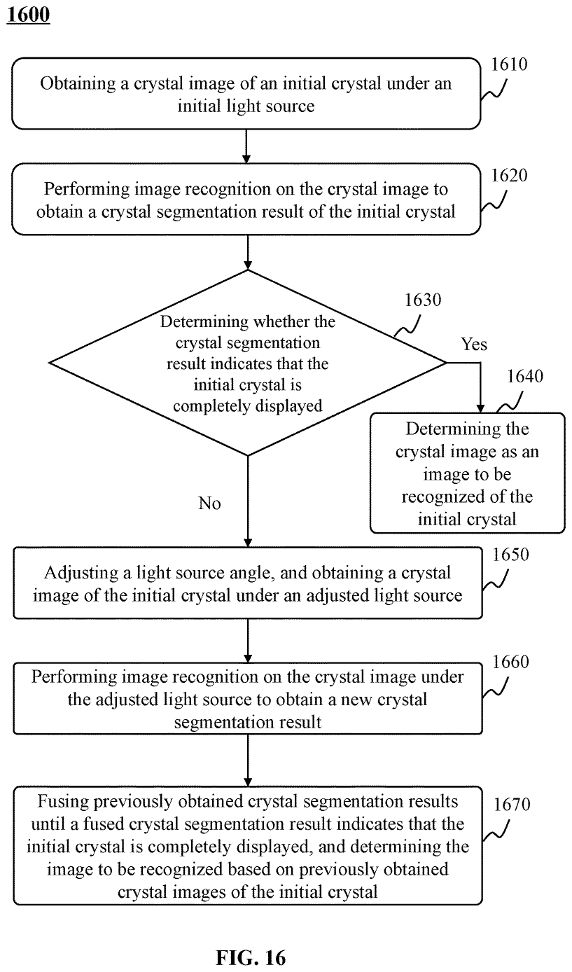

FIG. 16 is a flowchart illustrating an exemplary process for determining an image to be recognized according to some embodiments of the present disclosure. In some embodiments, a process 1600 may be performed by a crystal processing system or a crystal processing device, may be performed by a processor of the crystal processing system or the crystal processing device, or may be performed in other manners. For ease of description, the following descriptions in the present disclosure take the crystal processing device performing the process 1600 as an example. In some embodiments, for each initial crystal of the one or more initial crystals, the crystal processing device may perform the process 1600, to determine completeness of the initial crystal in the image to be recognized. As shown in FIG. 16, the process 1600 may include the following operations.

In 1610, a crystal image of the initial crystal under an initial light source is obtained. The initial light source refers to a preset light source.

In 1620, image recognition is performed on the crystal image to obtain a crystal segmentation result of the initial crystal.

The crystal segmentation result refers to a result of segmenting the initial crystal in the crystal image. The crystal segmentation result includes only the initial crystal in the crystal image.

In some embodiments, the crystal processing device may perform image recognition on the crystal image based on a segmentation model to obtain the crystal segmentation result of the initial crystal in the crystal image. The crystal processing device may input the crystal image into the segmentation model to obtain the crystal segmentation result of the initial crystal in the crystal image from the segmentation model. The segmentation model may be any one or a combination of a convolutional neural network (CNN) or any other machine learning model capable of implementing such function.

The segmentation model may be obtained through training based on ninth training samples with ninth labels. The ninth training samples may include a seventh sample image, and the ninth labels may include a crystal segmentation result corresponding to a fourth sample crystal in the seventh sample image. The ninth training samples may be determined by photographing the fourth sample crystal, and the ninth labels may be determined by manually segmenting the fourth sample crystal in the seventh sample image.

In 1630, whether the crystal segmentation result indicates that the initial crystal is completely displayed is determined.

The crystal processing device may evaluate the crystal segmentation result through a completeness evaluation model to determine whether the crystal segmentation result completely displays the corresponding initial crystal. Input of the completeness evaluation model may be the crystal segmentation result, and output of the completeness evaluation model may be a determination result indicating whether the crystal segmentation result completely displays the corresponding initial crystal. The completeness evaluation model may be any one or a combination of a convolutional neural network (CNN) or any other machine learning model capable of implementing such function.

The completeness evaluation model may be obtained through training based on tenth training samples with tenth labels. The tenth training samples may include a first sample segmentation result, and the tenth labels may include a sample determination result indicating whether the first sample segmentation result completely displays the corresponding initial crystal. The tenth training samples may be determined by photographing the initial crystal and then performing segmentation. The tenth labels may be determined by manually partially occluding or not occluding the tenth training samples. When the tenth training samples are not occluded, corresponding tenth labels indicate complete display. When the tenth training samples are partially occluded, corresponding tenth labels indicate incomplete display.

In 1640, when the crystal segmentation result indicates that the initial crystal is completely displayed, the crystal image is determined as an image to be recognized of the initial crystal.

In 1650, when the crystal segmentation result indicates that the initial crystal is not completely displayed, a light source angle is adjusted, and a crystal image of the initial crystal under an adjusted light source is obtained.

In some embodiments, the crystal processing device may adjust the light source angle in a plurality of manners. For example, the crystal processing device may adjust the light source based on a preset adjustment angle.

In some embodiments, the crystal processing device may analyze and process the crystal segmentation result based on a light source adjustment model to determine the adjusted light source angle.

In some embodiments, the light source adjustment model may include a missing-position determination layer and an angle adjustment layer. The missing-position determination layer may be configured to determine a missing crystal position in the crystal segmentation result. Input of the missing-position determination layer may include the crystal segmentation result of each initial crystal, and output of the missing-position determination layer may include a missing crystal position in the corresponding initial crystal. The angle adjustment layer may be configured to determine how to adjust the light source angle to supplement the missing crystal position in the initial crystal. Input of the angle adjustment layer may include the missing crystal position in the initial crystal, and output of the angle adjustment layer may include the adjusted light source angle. The missing-position determination layer and the angle adjustment layer may be any one or a combination of a convolutional neural network (CNN) or any other machine learning model capable of implementing such function.

In some embodiments, the light source adjustment model may be obtained by jointly training the missing-position determination layer and the angle adjustment layer. An eleventh training sample may include a second sample segmentation result, and an eleventh label may include an adjusted sample light source angle. The eleventh training sample may be input into an initial missing-position determination layer, output of the initial missing-position determination layer is input into an initial angle adjustment layer, a loss function is constructed based on output of the initial angle adjustment layer and the eleventh label, and parameters of the initial missing-position determination layer and the initial angle adjustment layer are iteratively updated based on a loss function until a preset condition is satisfied, so as to determine parameters in the missing-position determination layer and the angle adjustment layer and obtain the trained light source adjustment model. The preset condition may include, but is not limited to, the loss function converges, an iteration count reaches a threshold, etc.

In some embodiments, an image may be obtained by photographing a fifth sample crystal under a sample light source angle. In the image, the fifth sample crystal has reflection or is fused with a background region. The image is processed to obtain the second sample segmentation result, and the second sample segmentation result indicates that the fifth sample crystal is not completely displayed, and the second sample segmentation result is used as the eleventh training sample. By manually adjusting the sample light source angle, an image is obtained by photographing the fifth sample crystal after the adjustment, and a new sample crystal segmentation result may be obtained by processing the image. The new sample crystal segmentation result may supplement a missing part of the fifth sample crystal in the second sample segmentation result, and the adjusted sample light source is used as the eleventh label. It should be noted that the new sample crystal segmentation result may completely display the fifth sample crystal, or may incompletely display the fifth sample crystal.

In 1660, image recognition is performed on the crystal image under the adjusted light source to obtain a new crystal segmentation result.

More descriptions regarding a process for performing image recognition on the crystal image under the adjusted light source to obtain the new crystal segmentation result, may be found in related descriptions regarding the process for performing image recognition on the crystal image to obtain the crystal segmentation result of the initial crystal in operation 1620.

In 1670, previously obtained crystal segmentation results are fused until a fused crystal segmentation result indicates that the initial crystal is completely displayed, and the image to be recognized is determined based on previously obtained crystal images of the initial crystal.

In some embodiments, when the new crystal segmentation result is obtained, the crystal processing device may fuse the previously obtained crystal segmentation results, and determine, based on the completeness evaluation model, whether the fused crystal segmentation result indicates that the initial crystal is completely displayed. When the fused crystal segmentation result indicates that the initial crystal is completely displayed, image fusion may be performed on the previously obtained crystal images of the initial crystal, and the fused crystal image is determined as the image to be recognized. When the fused crystal segmentation result indicates that the initial crystal is not completely displayed, operation 1650 to operation 1660 may be repeatedly performed until the fused crystal segmentation result indicates that the initial crystal is completely displayed.

In some embodiments, when it is necessary to determine the processing scheme for the one or more initial crystals, the crystal processing device may fuse images in which the plurality of initial crystals are completely displayed, to obtain the image to be recognized corresponding to the plurality of initial crystals.

In some embodiments of the present disclosure, by determining completeness of the one or more initial crystals in the crystal image, it is ensured that the one or more initial crystals can be completely displayed in the image to be recognized, thereby ensuring accuracy when image recognition is performed on the image to be recognized.

It should be noted that the foregoing descriptions regarding the various processes are merely for illustration and explanation, and do not limit an application scope of the present disclosure. For those skilled in the art, various modifications and changes may be made to the various processes under guidance of the present disclosure. However, the modifications and changes still fall within the scope of the present disclosure.

The present disclosure further discloses an apparatus for crystal inspection, and the apparatus for crystal inspection may be configured for detecting the dimension data, the defect data, or the like of the one or more initial crystals.

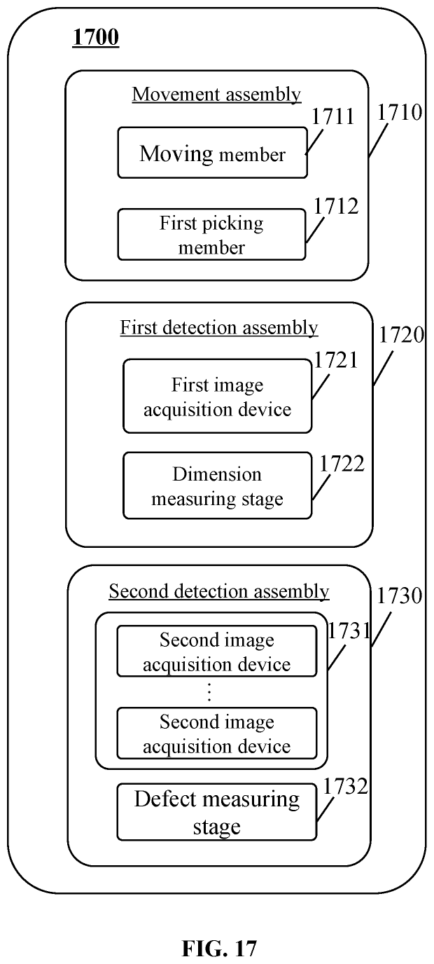

FIG. 17 is a block diagram illustrating an exemplary apparatus for crystal inspection according to some embodiments of the present disclosure.

An apparatus for crystal inspection 1700 may be configured to automatically detect dimension data, defect data, or the like of one or more initial crystals. The dimension data of the one or more initial crystals may include geometric data such as a length, a width, and a height of the one or more initial crystals. The defect data of the one or more initial crystals may include point defects (i.e., defects at an atomic scale, such as vacancies, interstitial atoms, substitutional atoms, or the like), line defects (i.e., defects distributed along linear paths in the crystals, such as dislocations), surface defects (i.e., defects at surfaces or interfaces of the crystals, such as the surface roughness, cracks, or the like), and volume defects (i.e., defects existing inside the crystals, such as inclusions, holes, or the like) of the one or more initial crystals.

In some embodiments, as shown in FIG. 17, the apparatus for crystal inspection 1700 may include a movement assembly 1710, a first detection assembly 1720, and a second detection assembly 1730.

The movement assembly 1710 may be configured to move a position of the one or more initial crystals. In some embodiments, as shown in FIG. 17, the movement assembly 1710 may include a moving member 1711 and a first picking member 1712, wherein the first picking member 1712 may be disposed on the moving member 1711, the first picking member 1712 may pick up the one or more initial crystals, and the moving member 1711 may adjust a position and/or an angle of the first picking member 1712, thereby adjusting a position and/or an angle of the one or more initial crystals. For example, the movement assembly 1710 may take the one or more initial crystals out of a tray and place the one or more initial crystals on a dimension measuring stage 1722. As another example, the movement assembly 1710 may pick up the one or more initial crystals placed on the dimension measuring stage 1722 and place the one or more initial crystals on a defect measuring stage 1732. As yet another example, the movement assembly 1710 may pick up the one or more initial crystals placed on the dimension measuring stage 1722 or the defect measuring stage 1732, rotate or flip the one or more initial crystals, and place the one or more initial crystals back at corresponding positions.

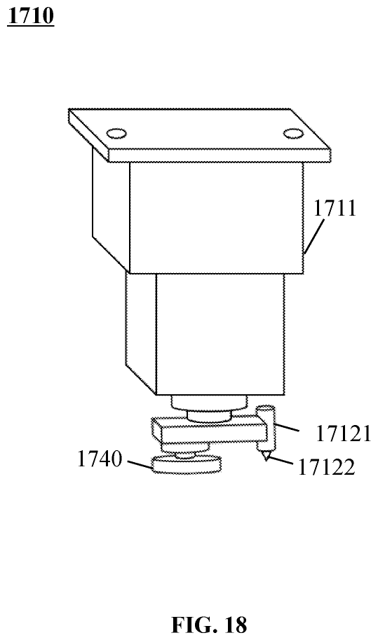

The moving member 1711 may be various movable structures. For example, the moving member 1711 may be the robotic arm as shown in FIG. 18. As another example, the moving member 1711 may be a rail system. The moving member 1711 may control the first picking member 1712 to rotate or flip, so as to drive the one or more initial crystals to rotate or flip. For example, the robotic arm may drive the first picking member 1712 disposed thereon to rotate or flip.

The first picking member 1712 may be various structures capable of picking up the one or more initial crystals. For example, as shown in FIG. 18, the first picking member 1712 may include an air pump and a suction cup, and the first picking member 1712 may pick up the one or more initial crystals through inflation and deflation. More descriptions regarding the foregoing example may be found in the related descriptions below. As another example, the first picking member 1712 may include a mechanical gripper.

The first detection assembly 1720 may be configured to obtain a first image of the one or more initial crystals, and the first image is used to determine the dimension data of the one or more initial crystals. The first image may be a two-dimensional image or a three-dimensional image.

In some embodiments, as shown in FIG. 17, the first detection assembly 1720 may include a first image acquisition device 1721 and the dimension measuring stage 1722. The dimension measuring stage 1722 may carry the one or more initial crystals.

In some embodiments, dimension identifiers may be disposed on a surface of the dimension measuring stage 1722 that is in contact with the one or more initial crystals. Correspondingly, when the first image acquisition device 1721 photographs the one or more initial crystals on the dimension measuring stage 1722, the obtained first image may include at least a portion of the dimension identifiers, so as to assist in analyzing the dimension data of the one or more initial crystals. The dimension identifiers may be set in a plurality of forms. For example, the dimension identifiers may be unit dimension identifiers. As another example, the dimension identifiers may be grid dimension identifiers.

The first image acquisition device 1721 photographs the one or more initial crystals on the dimension measuring stage 1722, so as to obtain at least one first image of the one or more initial crystals. The first image acquisition device 1721 may include, but is not limited to, a camera, a video camera, or the like.

In some embodiments, the first image acquisition device 1721 photographs the one or more initial crystals on the dimension measuring stage 1722, so as to obtain one first image of the one or more initial crystals. For example, the first image acquisition device 1721 photographs the one or more initial crystals on the dimension measuring stage 1722, so as to obtain one first image of the one or more initial crystals, and the foregoing first image may be a stereoscopic image of the one or more initial crystals. The stereoscopic image may include a plurality of peripheral surfaces of the one or more initial crystals. More descriptions regarding the peripheral surfaces may be found in the related descriptions below.

In some embodiments, the first detection assembly 1720 may include one first image acquisition device 1721. For example, after the first image acquisition device 1721 completes photographing the one or more initial crystals on the dimension measuring stage 1722, the movement assembly 1710 may pick up the one or more initial crystals on the dimension measuring stage 1722, rotate or flip the one or more initial crystals, and place the one or more initial crystals back on the dimension measuring stage 1722. The first image acquisition device 1721 may photograph the one or more initial crystals again, so as to obtain a plurality of first images of the one or more initial crystals, thereby ensuring that the dimensions of the one or more initial crystals in different directions can be obtained. As another example, after the first image acquisition device 1721 completes photographing the one or more initial crystals on the dimension measuring stage 1722, the first image acquisition device 1721 may move relative to the dimension measuring stage 1722 (e.g., from a top surface of the dimension measuring stage 1722 to a peripheral surface of the dimension measuring stage 1722). The moved first image acquisition device 1721 may photograph the one or more initial crystals on the dimension measuring stage 1722 again, so as to obtain the plurality of first images of the one or more initial crystals, thereby ensuring that the dimensions of the one or more initial crystals in different directions may be obtained. More descriptions regarding how the first image acquisition device 1721 moves may be found in the related descriptions below.

In some embodiments, the first detection assembly 1720 may include a plurality of first image acquisition devices 1721. The plurality of first image acquisition devices 1721 may be oppositely disposed in different directions relative to the dimension measuring stage 1722. The plurality of first image acquisition devices 1721 may all photograph the one or more initial crystals on the dimension measuring stage 1722, to obtain the plurality of first images of the one or more initial crystals, thereby ensuring that the dimensions of the initial crystals in different directions may be obtained. For example, the first detection assembly 1720 may include two first image acquisition devices 1721, and the two first image acquisition devices 1721 are respectively disposed on the top surface and the peripheral surface of the dimension measuring stage 1722.

In some embodiments, the first image acquisition device 1721 and the dimension measuring stage 1722 may move, such that the first image acquisition device 1721 may be aligned with the one or more initial crystals on the dimension measuring stage 1722 for photographing, thereby ensuring that the one or more initial crystals are located within a photographing range of the first image acquisition device 1721. In addition, by setting the dimension measuring stage 1722 to be movable, it is convenient for the movement assembly 1710 to place the one or more initial crystals on the dimension measuring stage 1722 or pick up the one or more initial crystals on the dimension measuring stage 1722, thereby avoiding shielding by other structures (e.g., the first image acquisition device 1721). More descriptions regarding the foregoing embodiments may be found in the related descriptions below.

The second detection assembly 1730 may be configured to obtain a second image of the one or more initial crystals, and the second image is used to determine defect data of the one or more initial crystals. The second image may be a two-dimensional image or a three-dimensional image.

In some embodiments, as shown in FIG. 17, the second detection assembly 1730 may include at least one second image acquisition device 1731 and at least one defect measuring stage 1732.

The defect measuring stage 1732 may be used to carry the one or more initial crystals.

The second image acquisition device 1731 photographs the one or more initial crystals on the defect measuring stage 1732, so as to obtain at least one second image of the one or more initial crystals. The second image acquisition device 1731 may include, but is not limited to, a camera, a video camera, or the like.

In some embodiments, the second image acquisition device 1731 photographs the one or more initial crystals on the defect measuring stage 1732, to obtain one second image of the one or more initial crystals.

In some embodiments, the second detection assembly 1730 may include one second image acquisition device 1731. For example, after the second image acquisition device 1731 completes photographing the one or more initial crystals on the defect measuring stage 1732, the movement assembly 1710 may pick up the one or more initial crystals on the defect measuring stage 1732, rotate or flip the one or more initial crystals, and place the one or more initial crystals back on the defect measuring stage 1732. The second image acquisition device 1731 may photograph the one or more initial crystals again, so as to obtain a plurality of second images of the one or more initial crystals, thereby ensuring that defects at different positions on the one or more initial crystals may be more comprehensively understood. As another example, after the second image acquisition device 1731 completes photographing the one or more initial crystals on the defect measuring stage 1732, the second image acquisition device 1731 may move relative to the defect measuring stage 1732 (e.g., from a top surface of the defect measuring stage 1732 to a peripheral surface of the defect measuring stage 1732). The moved second image acquisition device 1731 may photograph the one or more initial crystals on the defect measuring stage 1732 again, so as to obtain the plurality of second images of the one or more initial crystals, thereby ensuring that defects at different positions on the one or more initial crystals may be more comprehensively understood. More descriptions regarding how the second image acquisition device 1731 moves may be found in related descriptions regarding the first image acquisition device 1721.

In some embodiments, the second detection assembly 1730 may include a plurality of second image acquisition devices 1731. More descriptions regarding the plurality of second image acquisition devices 1731 may be found in the related descriptions below.

In some embodiments of the present disclosure, through the apparatus for crystal inspection 1700, the dimension data, the defect data, or the like of the one or more initial crystals may be automatically detected, the detection efficiency of crystals may be improved, and the detection accuracy of crystals may be ensured.

In some embodiments, the apparatus for crystal inspection 1700 may further include other structures.

In some embodiments, the apparatus for crystal inspection 1700 may further include a processing device. The processing device may be directly disposed in the apparatus for crystal inspection 1700, or may be disposed outside the apparatus for crystal inspection 1700 and in communication connection with a plurality of assemblies in the apparatus for crystal inspection 1700.

The processing device may control the plurality of assemblies in the apparatus for crystal inspection 1700. For example, the processing device may control the movement assembly 1710 to pick up the one or more initial crystals, and adjust a position and/or an angle of the one or more initial crystals. As another example, the processing device may control the first image acquisition device 1721 and the second image acquisition device 1731 to photograph the one or more initial crystals.

The processing device may process data and/or information obtained from other devices or the plurality of assemblies of the apparatus for crystal inspection 1700.

In some embodiments, the processing device may obtain the first image, and analyze and process the first image, thereby determining the dimension data of the one or more initial crystals. For example, the processing device may analyze and process dimensions of various dimensions of the one or more initial crystals in the first image based on dimension identifiers in the first image, thereby determining geometric data such as a length, a width, and a height of the one or more initial crystals.

In some embodiments, the processing device may obtain the second image, and perform modeling or employ various data analysis algorithms, for example, a regression analysis method, a discriminant analysis method, or the like, to analyze and process the second image, so as to determine the defect data of the one or more initial crystals. For example, the processing device may input the second image into a defect analysis model, and output of the defect analysis model is the defect data of the one or more initial crystals. The defect analysis model may be a convolutional neural network or any other machine learning model capable of implementing such function. The defect analysis model may be obtained by training based on twelfth training samples with twelfth labels. The twelfth training samples may include sample second images of sixth sample crystals, the twelfth labels may include defect data of the sixth sample crystals, the twelfth training samples may be obtained by manually photographing the sixth sample crystals, and the twelfth labels may be obtained by manually annotating the sixth sample crystals.

In some embodiments, the processing device may classify the one or more initial crystals based on the dimension data and the defect data of the one or more initial crystals. For example, the processing device may analyze and process the dimension data and the defect data of the one or more initial crystals, determine initial crystals satisfying a preset condition as qualified crystals, and determine initial crystals not satisfying the preset condition as unqualified crystals. Furthermore, the processing device may control the movement assembly 1710 to place the qualified crystals and the unqualified crystals in different regions, so as to facilitate subsequent processing.

In some embodiments, the apparatus for crystal inspection 1700 may further include the third image acquisition device 1740. The third image acquisition device 1740 may include, but is not limited to, a camera, a video camera, or the like. In some embodiments, the third image acquisition device 1740 may be fixedly disposed at a preset position in the apparatus for crystal inspection 1700. The third image acquisition device 1740 disposed at the preset position may photograph various positions where the one or more initial crystals may be present in the apparatus for crystal inspection 1700. For example, the third image acquisition device 1740 may be disposed on a top wall of the apparatus for crystal inspection 1700, so as to photograph various positions where the one or more initial crystals may be present. As another example, as shown in FIG. 18, the third image acquisition device 1740 may be disposed on the movement assembly 1710, so that the movement assembly 1710 may photograph various positions where the one or more initial crystals may be present before picking up the one or more initial crystals.

The third image acquisition device 1740 may photograph a region where the one or more initial crystals are located, to obtain a third image, and the third image is used to determine positions of the one or more initial crystals, thereby facilitating more accurate picking up of the one or more initial crystals by the movement assembly 1710. In some embodiments, the processing device may analyze and process the third image to determine the positions of the one or more initial crystals. For example, the processing device may input the third image into a position analysis model, and output of the position analysis model is positions of the one or more initial crystals. The position analysis model may be a convolutional neural network or any other machine learning model capable of implementing such function. The position analysis model may be obtained by training based on thirteenth training samples with thirteenth labels. The thirteenth training samples may include sample third images of seventh sample crystals, the thirteenth labels may include sample positions of the seventh sample crystals, the thirteenth training samples may be obtained by manually photographing the seventh sample crystals, and the thirteenth labels may be obtained by manually annotating positions of the seventh sample crystals. When the third image acquisition device 1740 is a movable component (e.g., the third image acquisition device 1740 is disposed on the movement assembly 1710), input of the position analysis model may include a position of the third image acquisition device 1740. The position of the third image acquisition device 1740 may be obtained through an internal positioning component thereof, or obtained after analyzing and processing an initial position of the third image acquisition device 1740 and data of each movement thereof (e.g., displacement and direction). Correspondingly, when the position analysis model is trained, the thirteenth training samples may further include a position of a sample image acquisition device, and the position of the sample image acquisition device may be obtained through manual annotation.

In some embodiments of the present disclosure, by providing the third image acquisition device 1740 to acquire the third image used for determining positions of the crystals, positions of the one or more initial crystals may be learned, thereby enabling precise control of the one or more initial crystals.

A configuration of the movement assembly 1710 will be described below.

In some embodiments, as shown in FIG. 18, the first picking member 1712 may include an air pump 17121 and a suction cup 17122. The air pump 17121 may be used for air suction and air release. The suction cup 17122 is capable of contacting the one or more initial crystals. The suction cup 17122 may be made of a flexible material. For example, the suction cup 17122 may be made of silica gel, rubber, or the like, so as to improve sealing performance when the one or more initial crystals are picked up and avoid dropping of the one or more initial crystals. In addition, the suction cup 17122 made of the flexible material may also avoid damage to the one or more initial crystals when the one or more initial crystals are picked up.

The suction cup 17122 may be connected to the air pump 17121. For example, the suction cup 17122 may be directly connected to the air pump 17121. As another example, the suction cup 17122 may also be connected to the air pump 17121 via a pipeline. The air pump 17121 performs air suction, such that the suction cup 17122 generates negative pressure.

Correspondingly, the suction cup 17122 may pick up the one or more initial crystals. The air pump 17121 performs air inflation, such that the negative pressure of the suction cup 17122 disappears. Correspondingly, the suction cup 17122 may release the one or more initial crystals.

In some embodiments of the present disclosure, picking up of the one or more initial crystals is implemented through the air pump 17121 and the suction cup 17122, which can be applied to initial crystals of different shapes and dimensions, and avoid damage to the initial crystals that may be caused by directly grasping the one or more initial crystals.

The present disclosure will describe a configuration of the first detection assembly 1720 below.

In some embodiments, the first detection assembly 1720 further includes a first rail 1723, a second rail 1724, and a third rail 1725. The first rail 1723, the second rail 1724, and the third rail 1725 are perpendicular to each other, at least one of the first image acquisition device 1721 and the dimension measuring stage 1722 is disposed on the first rail 1723 and is movable along an extending direction of the first rail 1723; at least one of the first image acquisition device 1721 and the dimension measuring stage 1722 is disposed on the second rail 1724 and is movable along an extending direction of the second rail 1724; and at least one of the first image acquisition device 1721 and the dimension measuring stage 1722 is disposed on the third rail 1725 and is movable along an extending direction of the third rail 1725.

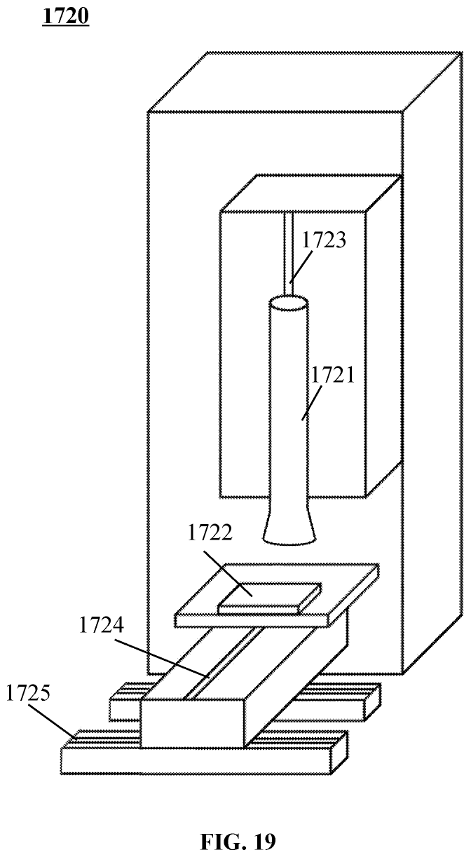

In some embodiments, the first rail 1723, the second rail 1724, and the third rail 1725 may be implemented in a plurality of manners. One or more of the first rail 1723, the second rail 1724, and the third rail 1725 may be embedded rails. For example, as shown in FIG. 19, the second rail 1724 is an embedded rail, the dimension measuring stage 1722 may be disposed on a connection structure, and a portion of the connection structure is embedded in the second rail 1724 and may slide on the second rail 1724. One or more of the first rail 1723, the second rail 1724, and the third rail 1725 may be protruding rails.

It should be noted that, when a plurality of rails are arranged in an overlapping manner, the same component (e.g., the first image acquisition device 1721 or the dimension measuring stage 1722) may be disposed on the plurality of rails at the same time. For example, as shown in FIG. 19, the dimension measuring stage 1722 is disposed on the second rail 1724, and the second rail 1724 is disposed on the third rail 1725. Therefore, the second rail 1724 may drive the dimension measuring stage 1722 disposed thereon to move along an extending direction of the third rail 1725, such that the dimension measuring stage 1722 may be disposed on the second rail 1724 and the third rail 1725 at the same time.

In some embodiments, the first image acquisition device 1721 and the dimension measuring stage 1722 may be disposed on different rails, respectively. For example, as shown in FIG. 19, the first image acquisition device 1721 may be disposed on the first rail 1723 and may move along an extending direction of the first rail 1723, the dimension measuring stage 1722 may be disposed on the second rail 1724 and may move along an extending direction of the second rail 1724, and the second rail 1724 may be disposed on the third rail 1725 and may move along the extending direction of the third rail 1725. That is, the dimension measuring stage 1722 is disposed on the second rail 1724 and the third rail 1725 at the same time, and may move along the extending direction of the second rail 1724 and the extending direction of the third rail 1725, respectively.

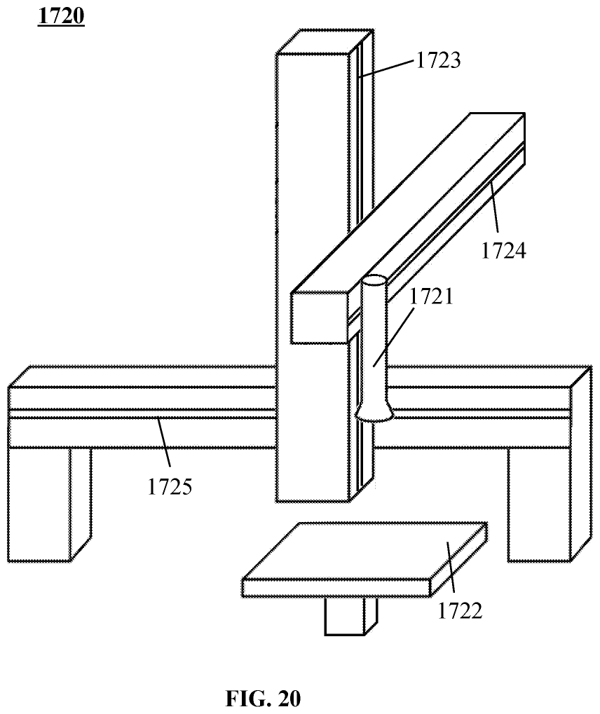

In some embodiments, one of the first image acquisition device 1721 and the dimension measuring stage 1722 may be disposed on the three rails at the same time, and the other one of the first image acquisition device 1721 and the dimension measuring stage 1722 may be fixedly disposed in the apparatus for crystal inspection 1700. For example, as shown in FIG. 20, the dimension measuring stage 1722 may be fixedly disposed in the apparatus for crystal inspection 1700, and the first image acquisition device 1721 may be disposed on the second rail 1724 and may move along the extending direction of the second rail 1724, the second rail 1724 may be disposed on the first rail 1723 and may move along the extending direction of the first rail 1723, and the first rail 1723 may be disposed on the third rail 1725 and may move along the extending direction of the third rail 1725. Accordingly, the first image acquisition device 1721 may be disposed on the first rail 1723, the second rail 1724, and the third rail 1725 at the same time, and may move along the extending direction of the first rail 1723, the extending direction of the second rail 1724, and the extending direction of the third rail 1725, respectively.

In some embodiments, the first image acquisition device 1721 and the dimension measuring stage 1722 may be disposed on a same rail, and the first image acquisition device 1721 and the dimension measuring stage 1722 may move along an extending direction of the rail, respectively. For example, the first image acquisition device 1721 may be disposed on the first rail 1723 and may move along the extending direction of the first rail 1723, and the first rail 1723 may be disposed on the second rail 1724 and may move along the extending direction of the second rail 1724. That is, the first image acquisition device 1721 may be disposed on the first rail 1723 and the second rail 1724 at the same time, and may move along the extending direction of the first rail 1723 and the extending direction of the second rail 1724, respectively. The dimension measuring stage 1722 may be disposed on the second rail 1724 and may move along the extending direction of the second rail 1724, and the second rail 1724 may be disposed on the third rail 1725 and may move along the extending direction of the third rail 1725. That is, the dimension measuring stage 1722 may be disposed on the second rail 1724 and the third rail 1725 at the same time, and may move along the extending direction of the second rail 1724 and the extending direction of the third rail 1725, respectively.

In some embodiments of the present disclosure, by disposing the first image acquisition device 1721 and/or the dimension measuring stage 1722 on one or more rails, relative movement between the first image acquisition device 1721 and the dimension measuring stage 1722 may be achieved, such that alignment between the first image acquisition device 1721 and the initial crystal on the dimension measuring stage 1722 may be achieved, thereby ensuring that the initial crystal is located within an acquisition range of the first image acquisition device 1721. In addition, the arrangement facilitates placement of the initial crystal on the dimension measuring stage 1722 by the first movement assembly 1710, avoids shielding of the dimension measuring stage 1722 by the first image acquisition device 1721, and ensures stability and safety of the initial crystal during movement.

The present disclosure describes a configuration of the second detection assembly 1730 below.

In some embodiments, the at least one second image includes images reflecting defects in the initial crystal from a plurality of different directions, so as to ensure that defects at various positions in the initial crystal may be reflected more comprehensively.

In some embodiments, the at least one second image acquisition device may include one second image acquisition device 1731, and the at least one defect measuring stage 1732 may include one defect measuring stage. The second image acquisition device 1731 may be configured to move relative to the defect measuring stage 1732, so as to obtain second images of the initial crystal from different directions. More descriptions regarding how the second image acquisition device 1731 is configured to move relative to the defect measuring stage 1732 may be found in the related descriptions of movement of the first image acquisition device 1721 relative to the dimension measuring stage 1722.

In some embodiments, the at least one second image acquisition device may include a front image acquisition device 17311 and a side image acquisition device, and the at least one defect measuring stage 1732 may include a first defect measuring stage 17321.

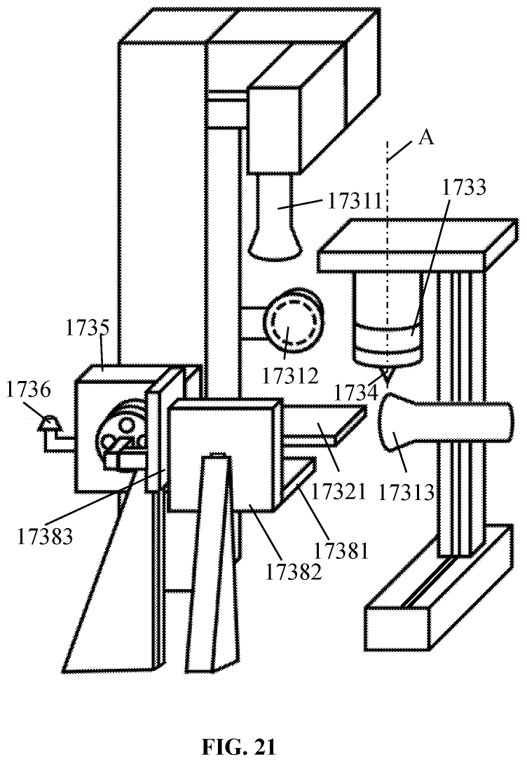

As shown in FIG. 21, the front image acquisition device 17311 may be disposed above the first defect measuring stage 17321, and is configured to photograph a top surface of the initial crystal to obtain the second image. The second image may reflect related defects of the top surface of the initial crystal. The top surface of the initial crystal refers to a surface at a top of the initial crystal when the initial crystal is placed on the first defect measuring stage 17321, that is, a surface of the initial crystal away from the first defect measuring stage 17321.

In some embodiments, the front image acquisition device 17311 and the first defect measuring stage 17321 may move relative to each other. For example, the front image acquisition device 17311 and/or the first defect measuring stage 17321 may be disposed on one or more rails and may move along an extending direction of the one or more rails. More descriptions regarding the front image acquisition device 17311 and/or the first defect measuring stage 17321 being disposed on the one or more rails may be found in the related descriptions of the first image acquisition device 1721 and/or the dimension measuring stage 1722 being disposed on the one or more rails.

The side image acquisition device may be disposed on a side of the first defect measuring stage 17321, and is configured to photograph circumferential surfaces of the initial crystal to obtain the second image. The second image may reflect related defects of the circumferential surface of the initial crystal. The circumferential surfaces of the initial crystal refer to surfaces of the initial crystal other than the top surface and a bottom surface when the initial crystal is placed on the first defect measuring stage 17321.

In some embodiments, the side image acquisition device and the first defect measuring stage 17321 may move relative to each other. For example, the side image acquisition device and/or the first defect measuring stage 17321 may be disposed on one or more rails and may move along an extending direction of the one or more rails. More descriptions regarding the side image acquisition device and/or the first defect measuring stage 17321 being disposed on the one or more rails may be found in the related descriptions of the first image acquisition device 1721 and/or the dimension measuring stage 1722 being disposed on the one or more rails.

Through the front image acquisition device 17311 and the side image acquisition device, the second images of the initial crystal may be obtained from different angles, such that the defect data of the initial crystal may be evaluated more comprehensively.

In some embodiments, a count of the side image acquisition device is one.

In some embodiments, as shown in FIG. 21, the side image acquisition device may include a long side image acquisition device 17312 and a short side image acquisition device 17313, the long side image acquisition device 17312 and the short side image acquisition device 17313 are disposed on different sides of the first defect measuring stage 17321. Through the foregoing arrangement, the second images reflecting defects of the initial crystal from two circumferential surfaces of the initial crystal may be obtained at one time, thereby improving inspection efficiency of the initial crystal.

In some embodiments, as shown in FIG. 21, the second detection assembly 1730 further includes a first driving member (not shown in FIG. 21), a rotating member 1733, and a second picking member 1734, and the second picking member 1734 is disposed on the rotating member 1733. The first driving member may drive the rotating member 1733 to rotate around a first rotation axis A, thereby driving the second picking member 1734 to rotate around the first rotation axis A. The second picking member 1734 picks up the initial crystal placed on the first defect measuring stage 17321, and places the rotated initial crystal back onto the first defect measuring stage 17321, wherein the first rotation axis A is parallel to a height direction.

The first driving member may be a rotating motor, and the rotating member 1733 may be a structure connected to the rotating motor. In some embodiments, the second detection assembly 1730 may not include the rotating member 1733, and the second picking member 1734 may be directly connected to the first driving member and rotate under driving of the first driving member.

Similar to the first picking member 1712, the second picking member 1734 may also be various structures capable of picking up the initial crystal. For example, the second picking member 1734 may include a mechanical clamping jaw. As another example, the second picking member 1734 may include an air pump and a suction cup, and the second picking member 1734 may pick up the initial crystal by inflation and deflation.

In some embodiments, the second picking member 1734 and the first defect measuring stage 17321 may move relative to each other. For example, the second picking member 1734 and/or the first defect measuring stage 17321 may be disposed on one or more rails and may move along an extending direction of the one or more rails. More descriptions regarding the second picking member 1734 and/or the first defect measuring stage 17321 being disposed on the one or more rails may be found in the related descriptions of the first image acquisition device 1721 and/or the dimension measuring stage 1722 being disposed on the one or more rails.

It should be noted that, when defects of the initial crystal are photographed, a relatively large number of components are provided. If a state (e.g., a placement angle) of the initial crystal on the defect measuring stage 1732 is adjusted by the movement assembly 1710, a relatively large movement space needs to be reserved for the movement assembly 1710, which may also easily damage other components. In some embodiments of the present disclosure, through the first driving member, the rotating member 1733, and the second picking member 1734, the placement angle of the initial crystal on the first defect measuring stage 17321 may be adjusted within a relatively small space, such that the side image acquisition device may conveniently photograph different sides of the initial crystal to obtain second images reflecting defects of different sides of the initial crystal, thereby ensuring integrity of crystal defect inspection and avoiding an excessively large volume of the apparatus for crystal inspection 1700.

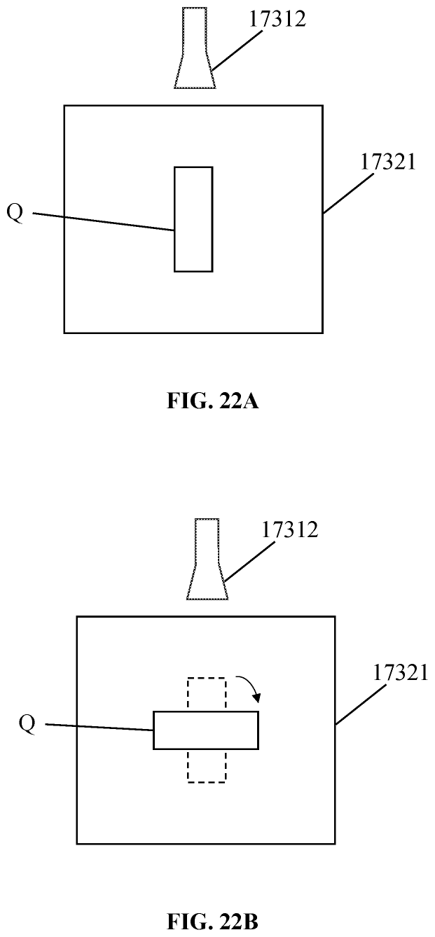

For example, as shown in FIG. 22A, when the count of the side image acquisition device is one, after the side image acquisition device photographs one side of an initial crystal Q having a rectangular shape, the second picking member 1734 may pick up the initial crystal Q, and the first driving member may drive the rotating member 1733 to rotate by 90° around the first rotation axis A, thereby driving the initial crystal Q on the second picking member 1734 to rotate by 90° around the first rotation axis A. After the rotation is completed, the second picking member 1734 may place the initial crystal Q back onto the first defect measuring stage 17321. As shown in FIG. 22B, the side image acquisition device may photograph another side of the initial crystal Q. After the photographing, the initial crystal Q may be rotated again and photographed, until photographing of all sides of the initial crystal Q is completed.

It should be understood that the rotation angle of the initial crystal in each rotation may be determined by analyzing a crystal shape, the count of the side image acquisition device, and the arrangement position of the side image acquisition device. For example, when the initial crystal is rectangular and the count of the side image acquisition device is one, the initial crystal may be rotated by 90° before each photographing. As another example, when the initial crystal is triangular and the count of the side image acquisition device is one, the initial crystal may be rotated by 120° before each photographing. As yet another example, when the initial crystal is rectangular and the second detection assembly 1730 includes the long side image acquisition device 17312 and the short side image acquisition device 17313, the initial crystal may be rotated by 180° before each photographing.

In some embodiments, the second image acquisition device 1731 further includes a back image acquisition device 17314, and the back image acquisition device 17314 is configured to photograph a back surface of the initial crystal to obtain the second image. The second image may reflect related defects of the bottom surface, such that the defect data of the initial crystal may be evaluated more comprehensively. The bottom surface of the initial crystal refers to a surface at a bottom of the initial crystal when the initial crystal is placed on the first defect measuring stage 17321, that is, a surface of the initial crystal in contact with the first defect measuring stage 17321.

In some embodiments, the first defect measuring stage 17321 may be made of a transparent material, the back image acquisition device 17314 may be disposed below the first defect measuring stage 17321, and a photographing angle of the back image acquisition device 17314 may be set toward the bottom surface of the initial crystal in the first defect measuring stage 17321, such that the back image acquisition device 17314 may obtain the second image reflecting related defects of the bottom surface of the initial crystal.

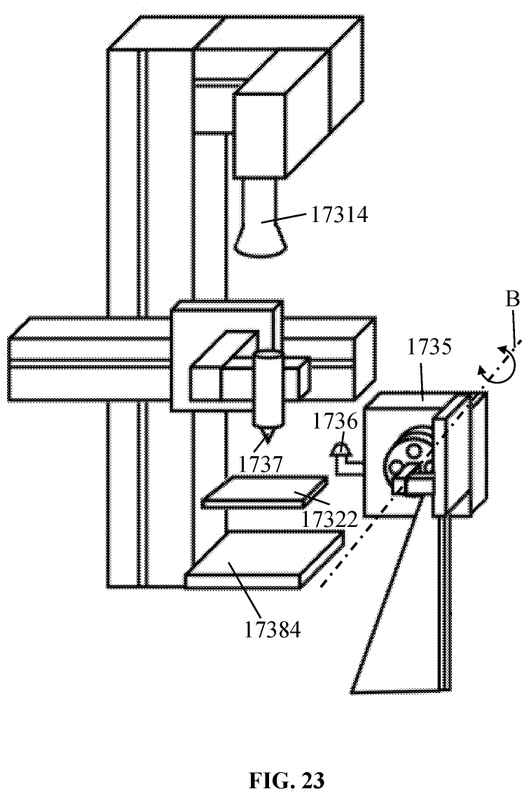

In some embodiments, as shown in FIG. 21 and FIG. 23, the at least one defect measuring stage 1732 further includes a second defect measuring stage 17322, and the back image acquisition device 17314 is disposed above the second defect measuring stage 17322. The second detection assembly 1730 further includes a second driving member (not shown in FIG. 23), a flipping member 1735, a third picking member 1736, and a fourth picking member 1737, and the third picking member 1736 is disposed on the flipping member 1735. The third picking member 1736 may pick up the initial crystal on the first defect measuring stage 17321. After the third picking member 1736 picks up the initial crystal on the first defect measuring stage 17321, the second driving member may drive the flipping member 1735 to rotate around a second rotation axis B, thereby driving the third picking member 1736 to rotate around the second rotation axis B, wherein the second rotation axis B is parallel to a width direction.

The second driving member may be a rotating motor, and the flipping member 1735 may be a structure connected to the rotating motor. Similar to the first picking member 1712, the third picking member 1736 and the fourth picking member 1737 may also be various structures capable of picking up the initial crystal. For example, the third picking member 1736 and/or the fourth picking member 1737 may include a mechanical clamping jaw. As another example, the third picking member 1736 and/or the fourth picking member 1737 may include the air pump and the suction cup. Correspondingly, the third picking member 1736 and/or the fourth picking member 1737 may pick up the initial crystal by inflation and deflation.

In some embodiments, after the flipping member 1735 drives the third picking member 1736 to rotate around the second rotation axis B by a preset angle, the fourth picking member 1737 may pick up the initial crystal on the third picking member 1736 and place the initial crystal on the second defect measuring stage 17322, such that the back image acquisition device 17314 may photograph the initial crystal. It may be understood that, after the initial crystal rotates around the second rotation axis B with the flipping member 1735 by the preset angle, the top surface and the bottom surface of the initial crystal may change. For example, the bottom surface of the initial crystal on the first defect measuring stage 17321 becomes the top surface of the initial crystal on the second defect measuring stage 17322, such that the back image acquisition device 17314 disposed above the second defect measuring stage 17322 may photograph the bottom surface of the initial crystal to obtain the second image reflecting related defects of the bottom surface of the initial crystal.

In some embodiments, the preset angle by which the flipping member 1735 drives the third picking member 1736 to rotate around the second rotation axis B may be determined based on a shape of the initial crystal. For example, when the initial crystal is rectangular, the flipping member 1735 may drive the third picking member 1736 to rotate by 180° around the second rotation axis B, such that the bottom surface of the initial crystal on the first defect measuring stage 17321 becomes the top surface of the initial crystal on the second defect measuring stage 17322.

In some embodiments, the fourth picking member 1737 and the second defect measuring stage 17322 may move relative to each other, such that after the fourth picking member 1737 places the initial crystal on the second defect measuring stage 17322, the fourth picking member 1737 may leave, thereby facilitating photographing of the initial crystal on the second defect measuring stage 17322 by the back image acquisition device 17314 and avoiding shielding. For example, the second defect measuring stage 17322 may be fixedly disposed, and the fourth picking member 1737 may be disposed on one or more rails and may move along an extending direction of the one or more rails. More descriptions regarding the fourth picking member 1737 being disposed on the one or more rails may be found in the related descriptions of the first image acquisition device 1721 and/or the dimension measuring stage 1722 being disposed on the one or more rails.

In some embodiments, the back image acquisition device 17314 and the second defect measuring stage 17322 may move relative to each other, so as to facilitate photographing of the initial crystal on the second defect measuring stage 17322, by the back image acquisition device 17314. For example, the back image acquisition device 17314 and/or the second defect measuring stage 17322 may be disposed on one or more rails and may move along an extending direction of the one or more rails. More descriptions regarding the back image acquisition device 17314 and/or the second defect measuring stage 17322 being disposed on the one or more rails may be found in the related descriptions of the first image acquisition device 1721 and/or the dimension measuring stage 1722 being disposed on the one or more rails.

It should be noted that, when defects of the initial crystal are photographed, a relatively large number of components are provided. If a state (e.g., a placement angle) of the initial crystal on the defect measuring stage 1732 is adjusted by the movement assembly 1710, a relatively large movement space needs to be reserved for the movement assembly 1710, which may also easily damage other components. In some embodiments of the present disclosure, through the foregoing arrangement, interchange between the top surface and the bottom surface of the initial crystal may be achieved within a relatively small space, so as to photograph defects in different directions of the initial crystal, thereby reducing the volume of the apparatus for crystal inspection 1700 and enabling more comprehensive evaluation of the defect data of the initial crystal.

In some embodiments, the second detection assembly 1730 further includes a plurality of light sources. For each second image acquisition device 1731, the light source is disposed in a photographing direction of the second image acquisition device 1731, and a distance between the light source and the second image acquisition device 1731 is greater than a distance between the initial crystal and the second image acquisition device 1731, such that different directions of the initial crystal may be illuminated based on the light sources, a contrast between surface defects of the initial crystal and surrounding regions may be enhanced, and the defects of the initial crystal may be captured more clearly.

For example, as shown in FIG. 20, a first light source 17381 is arranged in a photographing direction of the front image acquisition device 17311. The first light source 17381 is arranged below the first defect measuring stage 17321. When the front image acquisition device 17311 captures an image of the initial crystal on the first defect measuring stage 17321, the first light source 17381 may illuminate the initial crystal on the first defect measuring stage 17321. This illumination can enhance the contrast between surface defects of the initial crystal and surrounding regions, allowing defects of the initial crystal to be captured more clearly. Similarly, a second light source 17382 may be arranged in a photographing direction of the long side image acquisition device 17312. A third light source 17383 may be arranged in a photographing direction of the short side image acquisition device 17313. A fourth light source 17384 may be arranged in a photographing direction of the back image acquisition device 17314.

In some embodiments, one or more of the plurality of light sources may move relative to the defect measuring stage 1732 to adjust an illumination region and an illumination intensity, thereby meeting different illumination requirements. For example, the light source and/or the defect measuring stage 1732 may be arranged on one or more rails and may move along an extension direction of the one or more rails. More descriptions regarding the light source and/or the defect measuring stage 1732 being arranged on rails may be found in the related content about the first image acquisition device 1721 and/or the dimension measuring stage 1722 being arranged on rails.

In some embodiments, the image to be recognized may include one or more of the first image, the second image, and the third image acquired by the apparatus for crystal inspection 1700. The crystal processing device may analyze and process one or more of the aforementioned first image, second image, and third image to determine the dimension data and the defect data of the initial crystal. More descriptions regarding the image to be recognized and how to determine the dimension data and the defect data of the initial crystal may be found in the related description above in the present disclosure.

The basic concepts have been described above. It is apparent to those skilled in the art that the foregoing detailed disclosure is merely illustrative and does not limit the present disclosure. Although not explicitly stated herein, those skilled in the art may make various modifications, improvements, and amendments to the present disclosure. Such modifications, improvements, and amendments are suggested in the present disclosure. Therefore, such modifications, improvements, and amendments still fall within the spirit and scope of the exemplary embodiments of the present disclosure.

Meanwhile, the present disclosure uses specific words to describe embodiments of the present disclosure. Terms such as “an embodiment,” “one embodiment,” and/or “some embodiments” mean that a certain feature, structure, or characteristic is related to at least one embodiment of the present disclosure. Therefore, it should be emphasized and noted that the terms “an embodiment,” “one embodiment,” or “an alternative embodiment” mentioned two or more times at different locations in the present disclosure do not necessarily refer to the same embodiment. Furthermore, certain features, structures, or characteristics in one or more embodiments of the present disclosure may be appropriately combined.

Furthermore, unless explicitly stated in the claims, the order of processing elements and sequences, the use of numbers and letters, or the use of other names in the present disclosure are not intended to limit the order of the processes and methods of the present disclosure. Although the foregoing disclosure discusses some embodiments of the invention currently considered useful through various examples, it should be understood that such details are for illustrative purposes only. The appended claims are not limited to the disclosed embodiments. On the contrary, the claims are intended to cover all modifications and equivalent combinations that conform to the essence and scope of the embodiments of the present disclosure. For example, although the implementation of various components described above may be embodied in a hardware device, it may also be implemented as a software only solution, e.g., an installation on an existing server or mobile device.

Similarly, it should be noted that, in order to simplify the expression disclosed in the present disclosure and thereby help understand one or more embodiments of the invention, sometimes multiple features are grouped into one embodiment, drawing, or description thereof in the foregoing description of the embodiments of the present disclosure. However, this disclosure method does not mean that the subject matter of the present disclosure requires more features than those mentioned in the claims. Rather, claimed subject matter may lie in less than all features of a single foregoing disclosed embodiment.

In some embodiments, numbers describing quantities of ingredients or properties are used. It should be understood that such numbers used in the description of the embodiments are modified by the modifiers “about,” “approximately,” or “substantially” in some examples. Unless otherwise stated, “about,” “approximately,” or “substantially” indicates that the stated number allows a variation of +20%. Accordingly, in some embodiments, the numerical parameters used in the specification and claims are approximate values. The approximate values may change according to the characteristics required by individual embodiments. In some embodiments, the numerical parameters should consider the prescribed number of significant digits and adopt the method of general digit retention. Although the numerical ranges and parameters used to confirm the breadth of the scope in some embodiments of the present disclosure are approximate values, such numerical values are set as precisely as possible within the feasible range in specific embodiments.

For each patent, patent application, patent application publication, and other material, such as articles, books, specifications, publications, documents, etc., cited in the present disclosure, the entire content thereof is hereby incorporated by reference into the present disclosure. Excluded are application history documents that are inconsistent with or conflict with the content of the present disclosure. Also excluded are documents (currently or subsequently attached to the present disclosure) that limit the broadest scope of the claims of the present disclosure. It should be noted that, if the description, definition, and/or use of terms in the attached materials of the present disclosure are inconsistent with or conflict with the content described in the present disclosure, the description, definition, and/or use of terms in the present disclosure shall prevail.

Finally, it should be understood that the embodiments described in the present disclosure are only used to illustrate the principles of the embodiments of the present disclosure. Other variations may also fall within the scope of the present disclosure. Therefore, by way of example and not limitation, alternative configurations of the embodiments of the present disclosure may be considered consistent with the teachings of the present disclosure. Accordingly, the embodiments of the present disclosure are not limited to the embodiments explicitly introduced and described in the present disclosure.

What is claimed is:

1. A scintillator crystal for a scintillator detector of a positron emission tomography (PET) apparatus, wherein a surface roughness of at least one outer surface of the scintillator crystal is within a range of 0.001 μm to 0.1 μm.

2. The scintillator crystal according to claim 1, wherein a surface roughness of each side surface of the scintillator crystal is within a range of 0.01 μm to 0.1 μm.

3. The scintillator crystal according to claim 1, wherein the at least one outer surface includes a grinding surface obtained by a grinding treatment, and a surface roughness of the grinding surface is within a range of 0.5 μm to 1.5 μm.

4. The scintillator crystal according to claim 3, wherein the surface roughness of the grinding surface is within a range of 0.5 μm to 1 μm.

5. The scintillator crystal according to claim 1, wherein the at least one outer surface includes a polishing surface obtained by a polishing treatment, and a surface roughness of the polishing surface is within a range of 0.001 μm to 0.08 μm.

6. The scintillator crystal according to claim 1, wherein a surface roughness of a light-exiting surface of the scintillator crystal is less than 0.02 μm.

7. A crystal array for a scintillator detector of a positron emission tomography (PET) apparatus, the crystal array being obtained by processing a plurality of scintillator crystals, wherein processing the plurality of scintillator crystals includes:
machining a surface roughness of at least one outer surface of the plurality of scintillator crystals to be within a range of 0.001 μm to 0.1 μm.

8. The crystal array according to claim 7, wherein a surface roughness of each side surface of the scintillator crystals is within a range of 0.01 μm to 0.1 μm.

9. The crystal array according to claim 7, wherein a difference in surface roughness between two surfaces of at least one scintillator crystal among the plurality of scintillator crystals is less than 0.99 μm.

10. The crystal array according to claim 7, wherein a difference in surface roughness between two surfaces of at least one scintillator crystal among the plurality of scintillator crystals is less than 0.15 μm.

11. The crystal array according to claim 7, wherein a reflective structure is provided between at least two adjacent scintillator crystals in the crystal array.

12. The crystal array according to claim 11, wherein the reflective structure includes at least one of a reflective filling material, a reflective film, or a grinding surface.

13. The crystal array according to claim 12, wherein a surface roughness of the reflective structure is less than 100 μm.

14. The crystal array according to claim 13, wherein the surface roughness of the reflective structure is less than 50 μm.

15. The crystal array according to claim 12, wherein the crystal array is obtained by processing an initial crystal array, and the initial crystal array is formed by bonding the plurality of scintillator crystals with the reflective filling material.

16. The crystal array according to claim 15, wherein processing the initial crystal array includes:
performing at least one of a grinding treatment or a polishing treatment on a first surface and a second surface of the initial crystal array, wherein at least one of the first surface or the second surface is a light-exiting surface, and the first surface and the second surface are opposite surfaces.

17. The crystal array according to claim 16, wherein a surface roughness of at least one of the first surface or the second surface after the polishing treatment is less than 0.1 μm.

18. The crystal array according to claim 7, wherein the crystal array comprises a light-exiting surface, and a surface roughness of the light-exiting surface is not greater than 0.08 μm.

19. The crystal array according to claim 18, wherein the surface roughness of the light-exiting surface is not greater than 0.02 μm.

20. The crystal array according to claim 7, wherein the crystal array comprises a light-exiting surface and a surface opposite to the light-exiting surface, and a surface roughness of the surface opposite to the light-exiting surface is not greater than 2 μm.
